(19) United States
(12) Patent Application Publication
(10) Pub. No.: US 2024/0113848 A1
(43) Pub. Date: Apr. 4, 2024

(54) HIGH FREQUENCY MODULE AND COMMUNICATION DEVICE

(71) Applicant: Murata Manufacturing Co., Ltd., Kyoto (JP)

(72) Inventors: Takanori ITO, Kyoto (JP); Terumichi KITA, Kyoto (JP); Shinichiro TAKAYANAGI, Kyoto (JP); Yuudai TANOUE, Kyoto (JP); Minoru IWANAGA, Kyoto (JP)

(21) Appl. No.: 18/538,304

(22) Filed: Dec. 13, 2023

Related U.S. Application Data
(63) Continuation of application No. PCT/JP2022/025263, filed on Jun. 24, 2022.

(30) Foreign Application Priority Data
Jun. 30, 2021 (JP) 2021-108706

(51) Int. Cl. H04L 5/14; H03H 9/145; H03H 9/25; H03H 9/64

(52) U.S. Cl. CPC H04L 5/14; H03H 9/145; H03H 9/25; H03H 9/6483

(57) ABSTRACT

In a high frequency module, a plurality of filters is connected to an antenna terminal with a switch interposed. The plurality of filters includes a first filter that has a pass band including a frequency band of a first communication band and a second filter that has a pass band including a frequency band of a second communication band that is capable of simultaneous communication with the first communication band. A first electronic component having the first filter and a second antenna end resonator of the second filter is disposed on a first principal surface of the mounting substrate. A second electronic component having at least one second acoustic wave resonator other than a second antenna end resonator of the second filter is disposed on the first principal surface of the mounting substrate.

### CROSS REFERENCE TO RELATED APPLICATION

This is a continuation of International Application No. PCT/JP2022/025263 filed on Jun. 24, 2022 which claims priority from Japanese Patent Application No. 2021-108706 filed on Jun. 30, 2021. The contents of these applications are incorporated herein by reference in their entireties.

### BACKGROUND OF THE DISCLOSURE

### Field of the Disclosure

The present disclosure generally relates to a high frequency module and a communication device, and more particularly, relates to a high frequency module including a mounting substrate and a communication device including the same.

### Description of the Related Art

Patent Document 1 discloses a high frequency module including a mounting substrate, an antenna terminal, a switch connected to the antenna terminal, and a plurality of filters.

The mounting substrate has a first principal surface and a second principal surface that face each other. The plurality of filters is disposed on the first principal surface of the mounting substrate. Each of the plurality of filters is a ladder filter and has a plurality of series arm resonators and a plurality of parallel arm resonators. Each of the plurality of filters is an acoustic wave filter, and each of the plurality of series arm resonators and the plurality of parallel arm resonators includes an acoustic wave resonator.
Patent Document 1: International Publication No. WO2021/044691

### BRIEF SUMMARY OF THE DISCLOSURE

When conventional high frequency modules include two filters utilized in simultaneous communication such as carrier aggregation, for example, it may be difficult to place the two filters utilized in simultaneous communication close to the switch, which sometimes leads to the degradation of the characteristics during simultaneous communication.

Accordingly, it is a possible benefit of the present disclosure to provide a high frequency module and a communication device that can suppress the degradation of the characteristics during simultaneous communication.

A high frequency module according to an embodiment of the present disclosure includes a mounting substrate, an antenna terminal, a switch, and a plurality of filters. The mounting substrate has a first principal surface and a second principal surface that face each other. The antenna terminal is disposed on or in the mounting substrate. The switch is mounted on or in the mounting substrate. The switch is connected to the antenna terminal. The plurality of filters is connected to the antenna terminal with the switch interposed. The plurality of filters includes a first filter that has a pass band including a frequency band of a first communication band and a second filter that has a pass band including a frequency band of a second communication band that is capable of simultaneous communication with the first communication band. The first filter has a plurality of first acoustic wave resonators. The second filter has a plurality of second acoustic wave resonators. The plurality of first acoustic wave resonators includes a first antenna end resonator. Among the plurality of first acoustic wave resonators, the first antenna end resonator is a first acoustic wave resonator that is provided on a first signal path connected to the switch and that is closest to the antenna terminal. The plurality of second acoustic wave resonators includes a second antenna end resonator. Among the plurality of second acoustic wave resonators, the second antenna end resonator is the second acoustic wave resonator that is provided on a second signal path connected to the switch and that is closest to the antenna terminal. A first electronic component having the first filter and the second antenna end resonator of the second filter is disposed on the first principal surface of the mounting substrate. A second electronic component having at least one second acoustic wave resonator other than the second antenna end resonator of the second filter is disposed on the first principal surface of the mounting substrate. A distance between the first electronic component and the switch is shorter than a distance between the second electronic component and the switch, in plan view in a thickness direction of the mounting substrate.

A high frequency module according to an embodiment of the present disclosure includes a mounting substrate, an antenna terminal, a switch, and a plurality of filters. The mounting substrate has a first principal surface and a second principal surface that face each other. The antenna terminal is disposed on or in the mounting substrate. The switch is mounted on or in the mounting substrate. The switch is connected to the antenna terminal. The plurality of filters is connected to the antenna terminal with the switch interposed. The plurality of filters includes a first filter that has a pass band including a frequency band of a first communication band and a second filter that has a pass band including a frequency band of a second communication band that is capable of simultaneous communication with the first communication band. The first filter has a plurality of first acoustic wave resonators. The second filter has a plurality of second acoustic wave resonators. The plurality of first acoustic wave resonators includes a first antenna end resonator. Among the plurality of first acoustic wave resonators, the first antenna end resonator is a first acoustic wave resonator that is provided on a first signal path connected to the switch and that is closest to the antenna terminal. The plurality of second acoustic wave resonators includes a second antenna end resonator. Among the plurality of second acoustic wave resonators, the second antenna end resonator is the second acoustic wave resonator that is provided on a second signal path connected to the switch and that is closest to the antenna terminal. A first electronic component having the second antenna end resonator of the second filter is disposed on the first principal surface of the mounting substrate. A second electronic component having at least one second acoustic wave resonator other than the second antenna end resonator among the plurality of second acoustic wave resonators of the second filter is disposed on the first principal surface of the mounting substrate. A third electronic component having the first filter is disposed on the first principal surface of the mounting substrate. The first electronic component and the third electronic component are adjacent to each other in plan view in the thickness direction of the mounting substrate. In plan view in the thickness direction of the mounting substrate, a distance between the first electronic component and the switch as well as a distance between the third electronic component and the switch are shorter than a distance between the second electronic component and the switch.

A high frequency module according to an embodiment of the present disclosure includes a mounting substrate, an antenna terminal, a switch, and a plurality of filters. The mounting substrate has a first principal surface and a second principal surface that face each other. The antenna terminal is disposed on or in the mounting substrate. The switch is mounted on or in the mounting substrate. The switch is connected to the antenna terminal. The plurality of filters is connected to the antenna terminal with the switch interposed. The plurality of filters includes a first filter that has a pass band including a frequency band of a first communication band and a second filter that has a pass band including a frequency band of a second communication band that is capable of simultaneous communication with the first communication band. The first filter has a plurality of first acoustic wave resonators. The second filter has a plurality of second acoustic wave resonators. The plurality of first acoustic wave resonators includes a first antenna end resonator. Among the plurality of first acoustic wave resonators, the first antenna end resonator is a first acoustic wave resonator that is provided on a first signal path connected to the switch and that is closest to the antenna terminal. The plurality of second acoustic wave resonators includes a second antenna end resonator. Among the plurality of second acoustic wave resonators, the second antenna end resonator is the second acoustic wave resonator that is provided on a second signal path connected to the switch and that is closest to the antenna terminal. A first electronic component having the first antenna end resonator of the first filter and the second antenna end resonator of the second filter is disposed on the first principal surface or the second principal surface of the mounting substrate. A second electronic component having at least one second acoustic wave resonator other than the second antenna end resonator among the plurality of second acoustic wave resonators of the second filter is disposed on the first principal surface of the mounting substrate. A distance between the first electronic component and the switch is shorter than a distance between the second electronic component and the switch in plan view in a thickness direction of the mounting substrate.

A communication device according to an embodiment of the present disclosure includes the high frequency module described above and a signal processing circuit. The signal processing circuit is connected to the high frequency module.

The high frequency module and the communication device according to the embodiments of the present disclosure described above can suppress the degradation of the characteristics during simultaneous communication.

### BRIEF DESCRIPTION OF THE SEVERAL VIEWS OF THE DRAWINGS

FIG. 1 is a plan view of a high frequency module according to Embodiment 1.

FIG. 2 is a plan view relating to the high frequency module according to Embodiment 1 and illustrating a first ground conductor part and a second ground conductor part in or on a mounting substrate.

FIG. 3 is a sectional view taken along X-X line of FIG. 1, illustrating the high frequency module according to Embodiment 1.

FIG. 4 is a sectional view of a first electronic component in the high frequency module according to Embodiment 1.

FIG. 5 is a sectional view of a second electronic component in the high frequency module according to Embodiment 1.

FIG. 6 is a circuit configuration diagram of a communication device including the high frequency module according to Embodiment 1.

FIG. 7 is a circuit diagram of an essential part of the high frequency module according to Embodiment 1.

FIG. 8 is a sectional view of the first electronic component in the high frequency module according to Embodiment 1.

FIG. 9 is a sectional view of the second electronic component in the high frequency module according to Embodiment 1.

FIG. 10 is a sectional view of the first electronic component in the high frequency module according to Embodiment 1.

FIG. 11 is a sectional view of the second electronic component in the high frequency module according to Embodiment 1.

FIG. 12 is a sectional view of the first electronic component in the high frequency module according to Embodiment 1.

FIG. 13 is a sectional view of the second electronic component in the high frequency module according to Embodiment 1.

FIG. 14 is a circuit diagram of an essential part illustrating another example of the high frequency module according to Embodiment 1.

FIG. 15 is a plan view of a high frequency module according to Embodiment 2.

FIG. 16 is a plan view of a high frequency module according to Embodiment 3.

FIG. 17 is a circuit diagram of an essential part in the high frequency module according to Embodiment 3.

FIG. 18 is a plan view of a high frequency module according to Embodiment 4.

FIG. 19 is a plan view of a high frequency module according to Embodiment 5.

FIG. 20 is a circuit diagram of a high frequency module according to Embodiment 6.

FIG. 21 is a plan view of the high frequency module according to Embodiment 6.

FIG. 22 is a plan view of a high frequency module according to Embodiment 7.

FIG. 23 is a circuit diagram of a high frequency module according to Embodiment 8.

FIG. 24 is a plan view of the high frequency module according to Embodiment 8.

FIG. 25 is a circuit configuration diagram of a communication device including a high frequency module according to Embodiment 9.

FIG. 26A is a circuit diagram of a first filter in the high frequency module according to Embodiment 9. FIG. 26B is a circuit diagram of a second filter in the high frequency module according to Embodiment 9.

FIG. 27 is a circuit diagram illustrating another first example of the first filter in the high frequency module according to Embodiment 9.

FIG. 28 is a circuit diagram illustrating another second example of the first filter in the high frequency module according to Embodiment 9.

FIG. 29 is a circuit diagram illustrating another third example of the first filter in the high frequency module according to Embodiment 9.

FIG. 30 is a circuit configuration diagram of a communication device including a high frequency module according to Embodiment 10.

FIG. 31 is a circuit diagram of the high frequency module according to Embodiment 10.

FIG. 32 is a characteristic explanatory diagram of each of a first filter and a third filter in the high frequency module according to Embodiment 10.

FIG. 33 is a circuit configuration diagram of a communication device including a high frequency module according to a modification example of Embodiment 10.

FIG. 34 is a circuit configuration diagram of a communication device including a high frequency module according to another modification example of Embodiment 10.

### DETAILED DESCRIPTION OF THE DISCLOSURE

The drawings referred below in Embodiments 1 to 10 or the like are schematic diagrams where a ratio of a size or a thickness of each component therein does not necessarily reflect an actual dimension ratio.

### Embodiment 1

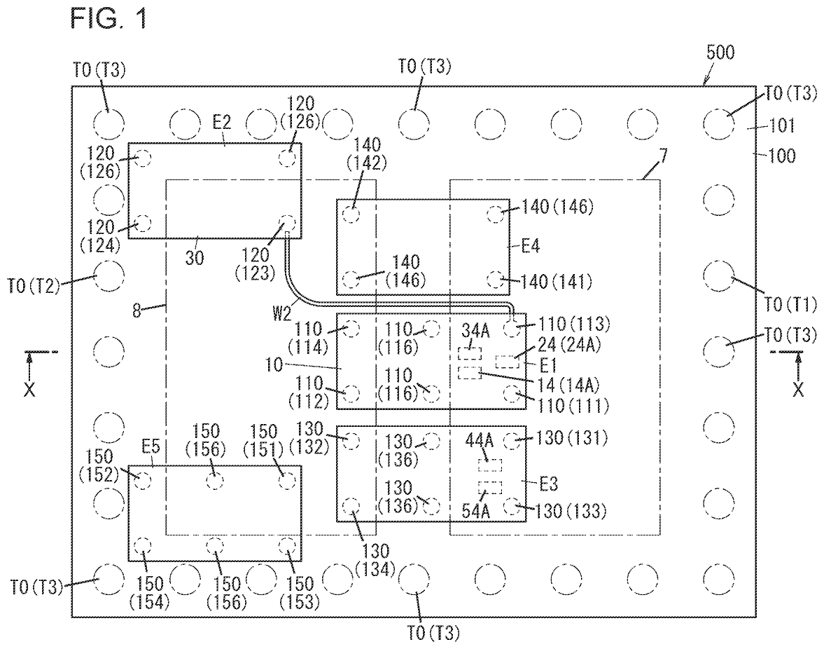

In the following, a description will be given of a high frequency module 500 according to Embodiment 1 based on FIGS. 1 to 7.

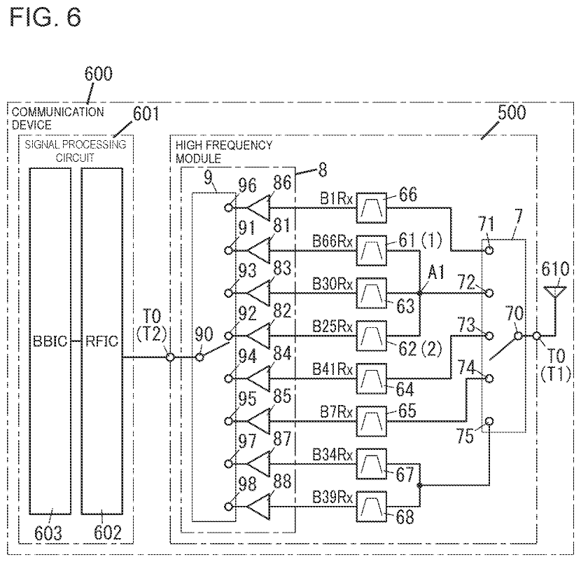

As illustrated in FIGS. 1 to 3, the high frequency module 500 according to Embodiment 1 includes, for example, a mounting substrate 100, an antenna terminal T1, a switch 7, and a plurality of (nine, for example) filters 61 to 68 (see FIG. 6). The mounting substrate 100 has a first principal surface 101 and a second principal surface 102 that face each other. The antenna terminal T1 is disposed on the mounting substrate 100. The switch 7 is disposed on the mounting substrate 100. The switch 7 is connected to the antenna terminal T1 (see FIG. 6). The plurality of filters 61 to 68 is connected to the antenna terminal T1 with the switch 7 interposed (see FIG. 6). As illustrated in FIG. 6, the plurality of filters 61 to 68 includes a first filter 1 (filter 61) and a second filter 2 (filter 62). The first filter 1 has a pass band including a frequency band of a first communication band. The second filter 2 has a pass band of a frequency band of a second communication band that is capable of simultaneous communication with the first communication band. The “capable of simultaneous communication” means that at least one of simultaneous reception, simultaneous transmission, or simultaneous transmission and reception is possible. In the high frequency module 500, a combination of the first communication band and the second communication band is a combination that performs simultaneous reception in the high frequency module 500.

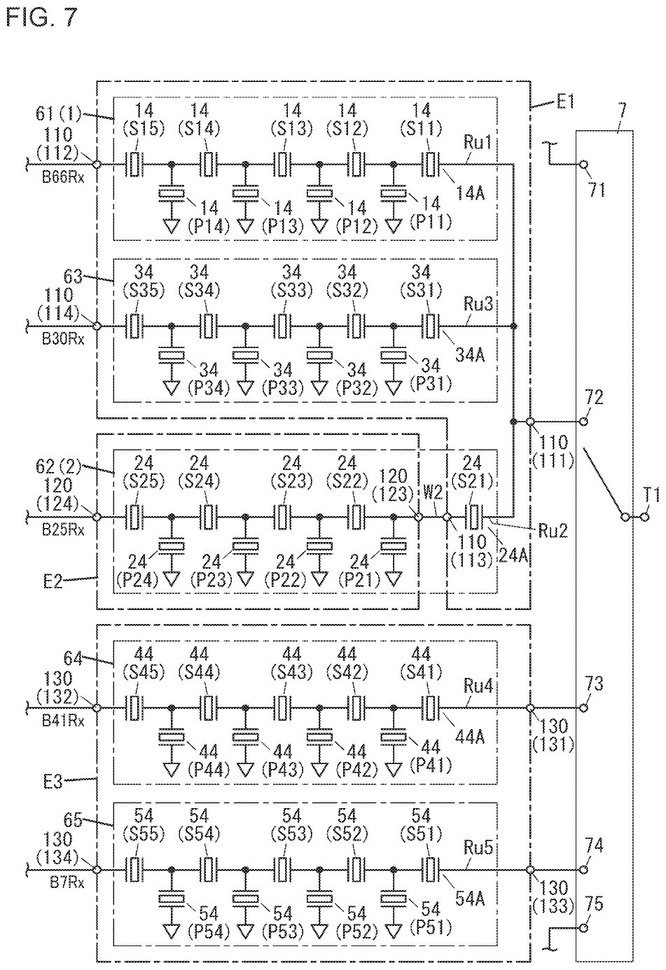

As illustrated in FIG. 7, the first filter 1 has a plurality of (nine, for example) acoustic wave resonators 14 (hereinafter also referred to as first acoustic wave resonators 14). In addition, as illustrated in FIG. 7, the second filter 2 has a plurality of (nine, for example) acoustic wave resonators 24 (hereinafter also referred to as second acoustic wave resonators 24). The plurality of first acoustic wave resonators 14 includes an antenna end resonator 14A (hereinafter also referred to a first antenna end resonator 14A). Among the plurality of first acoustic wave resonators 14, the first antenna end resonator 14A is a first acoustic wave resonator that is provided on a signal path Ru1 (hereinafter also referred to as a first signal path Ru1) connected to the switch 7 and that is closest to the antenna terminal T1. The “first acoustic wave resonator 14 that is closest to the antenna terminal T1” is a first acoustic wave resonator 14 that is connected to the antenna terminal T1 with no other first acoustic wave resonators 14 interposed. Therefore, the “first acoustic wave resonator 14 that is closest to the antenna terminal T1” is a first acoustic wave resonator 14 having the shortest physical distance between the first acoustic wave resonator 14 among the plurality of first acoustic wave resonators 14 and the antenna terminal T1. The plurality of second acoustic wave resonators 24 includes an antenna end resonator 24A (hereinafter also referred to as a second antenna end resonator 24A). Among the plurality of second acoustic wave resonators 24, the second antenna end resonator 24A is a second acoustic wave resonator 24 that is provided on a signal path Ru2 (hereinafter also referred to a second signal path Ru2) connected to the switch 7 and that is closest to the antenna terminal T1. The “second acoustic wave resonator 24 that is closest to the antenna terminal T1” is a second acoustic wave resonator 24 that is connected to the antenna terminal T1 with no other second acoustic wave resonators 24 interposed. Therefore, the “second acoustic wave resonator 24 that is closest to the antenna terminal T1” is a second acoustic wave resonator 24 having the shortest physical distance between the second acoustic wave resonator 24 among the plurality of second acoustic wave resonators 24 and the antenna terminal T1. In the high frequency module 500, a first electronic component E1 (see FIGS. 1 and 7) having the first filter 1 and the second antenna end resonator 24A of the second filter 2 is disposed on the first principal surface 101 of the mounting substrate 100. In addition, in the high frequency module 500, a second electronic component E2 (see FIGS. 1 and 7) having the second acoustic wave resonators 24 other than the second antenna end resonator 24A among the plurality of second acoustic wave resonators 24 of the second filter 2 is disposed on the first principal surface 101 of the mounting substrate 100. As described above, the first electronic component E1 has the first filter 1 and the second antenna end resonator 24A of the second filter 2. On the other hand, the second electronic component E2 has the second acoustic wave resonators 24 other than the second antenna end resonator 24A among the plurality of second acoustic wave resonator 24 of the second filter 2.

As illustrated in FIG. 6, the high frequency module 500 is used in a communication device 600, for example. The communication device 600 is, for example, a cellular phone (such as a smartphone), but is not limited thereto and may be, for example, a wearable terminal (such as a smartwatch), or the like. The high frequency module 500 is, for example, a module that can support a 4G (fourth-generation mobile communication) standard or a 5G (fifth-generation mobile communication) standard, or the like. The 4G standard is, for example, 3GPP (registered trademark, Third Generation Partnership Project) LTE (registered trademark, Long Term Evolution) standard. The 5G standard is, for example, 5G NR (New Radio). The high frequency module 500 is, for example, a module that supports carrier aggregation and dual connectivity. A combination of the first communication band and the second communication band that are capable of simultaneous communication is a combination of a plurality of frequency bands that partially overlap each other or that do not overlap at all, among the frequency bands of the communication bands defined by the 3GPP LTE standard and the frequency bands of the communication bands defined by the 5G NR standard. The frequency bands are downlink frequency bands or uplink frequency bands. The downlink frequency bands are reception bands. The uplink frequency bands are transmission bands.

In the following, a more detailed description of the high frequency module 500 and the communication device 600 according to Embodiment 1 will be given with reference to FIGS. 1 to 7.

### (1) High Frequency Module

### (1.1) Circuit Configuration of High Frequency Module

A description will be given of a circuit configuration of the high frequency module 500 according to Embodiment 1 with reference to FIG. 6.

For example, the high frequency module 500 is configured to amplify a reception signal inputted from an antenna 610 and output the signal to a signal processing circuit 601. The signal processing circuit 601 is not a component of the high frequency module 500 but a component of the communication device 600 including the high frequency module 500. The high frequency module 500 is controlled by, for example, the signal processing circuit 601 included in the communication device 600.

The high frequency module 500 includes the plurality of (eight in the illustrated example) filters 61 to 68, a switch 7 (hereinafter also referred to as a first switch 7), a plurality of (eight in the illustrated example) low noise amplifiers 81 to 88, and a second switch 9. In the high frequency module 500, the filter 61 constitutes the first filter 1 described above, and the filter 62 constitutes the second filter 2 described above.

In addition, the high frequency module 500 includes a plurality of external connection terminals TO. The plurality of external connection terminals TO includes the antenna terminal T1, a signal output terminal T2, and a plurality of external ground terminals T3 (see FIG. 1). Each of the plurality of external ground terminals T3 is, for example, a terminal that is electrically connected with a ground electrode of a circuit board included in the communication device 600 and that is supplied with a ground potential.

In the following, a more detailed description will be given of the circuit configuration of the high frequency module 500.

### (1.1.1) Filters

The plurality of filters 61 to 68 are receiving filters having, as pass bands, frequency bands (downlink frequency bands) of mutually different communication bands. The downlink frequency bands are hereinafter referred to as the reception bands.

The filter 61 is a filter having, for example, a pass band including the reception band of the first communication band. The filter 62 is a filter having, for example, a pass band including the reception band of the second communication band. The filter 63 is a filter having, for example, a pass band including the reception band of a third communication band. The filter 64 is a filter having, for example, a pass band including the reception band of a fourth communication band. The filter 65 is a filter having, for example, a pass band including the reception band of a fifth communication band. The filter 66 is a filter having, for example, a pass band including the reception band of a sixth communication band. The filter 67 is a filter having, for example, a pass band including the reception band of a seventh communication band. The filter 68 is a filter having, for example, a pass band including the reception band of an eighth communication band. Each of the first communication band, the second communication band, the third communication band, the fourth communication band, the fifth communication band, the sixth communication band, the seventh communication band, and the eighth communication band is, for example, a communication band of the 3GPP LTE standard or a communication band of the 5G NR standard. The first communication band is, for example, Band66 of the 3GPP LTE standard. The second communication band is, for example, Band25 of the 3GPP LTE standard. The third communication band is, for example, Band30 of the 3GPP LTE standard. The fourth communication band is, for example, Band41 of the 3GPP LTE standard. The fifth communication band is, for example, Band1 of the 3GPP LTE standard. The sixth communication band is, for example, Band1 of the 3GPP LTE standard. The seventh communication band is, for example, Band34 of the 3GPP LTE standard. The eighth communication band is, for example, Band39 of the 3GPP LTE standard. In FIG. 6, to make it easier to understand that the pass band of the filter 61 corresponds to the reception band of Band66 of the 3GPP LTE standard, “B66Rx” is written to the left of the figure symbol of the filter 61. Similarly, in FIG. 6, to make it easier to understand that the filter 62 corresponds to the reception band of Band25 of the 3GPP LTE standard, “B25Rx” is written to the left of the figure symbol of the filter 62. Similarly, in FIG. 6, to make it easier to understand that the filter 63 corresponds to the reception band of Band30 of the 3GPP LTE standard, “B30Rx” is written to the left of the figure symbol of the filter 63. Similarly, in FIG. 6, to make it easier to understand that the filter 64 corresponds to the reception band of Band41 of the 3GPP LTE standard, “B41Rx” is written to the left of the figure symbol of the filter 64. Similarly, in FIG. 6, to make it easier to understand that the filter 65 corresponds to the reception band of Band1 of the 3GPP LTE standard, “B7Rx” is written to the left of the figure symbol of the filter 65. Similarly, in FIG. 6, to make it easier to understand that the filter 66 corresponds to the reception band of Band1 of the 3GPP LTE standard, “B1Rx” is written to the left of the figure symbol of the filter 66. Similarly, in FIG. 6, to make it easier to understand that the filter 67 corresponds to the reception band of Band34 of the 3GPP LTE standard, “B34Rx” is written to the left of the figure symbol of the filter 67. Similarly, in FIG. 6, to make it easier to understand that the filter 68 corresponds to the reception band of Band39 of the 3GPP LTE standard, “B39Rx” is written to the left of the figure symbol of the filter 68.

Each of the plurality of filters 61 to 68 is an acoustic wave filter. In the following, a description will be given of an example of the circuit configuration of the filter 61 to 65 of the plurality of filters 61 to 68 based on FIG. 7. The circuit configurations of the filters 66 to 68 are similar to those of the filters 61 to 65, for example.

As described above, the filter 61 (first filter 1) has the plurality of first acoustic wave resonators 14. In addition, the plurality of first acoustic wave resonators 14 includes the first antenna end resonator 14A. The first filter 1 is a ladder filter, for example, and includes five series arm resonators S11 to S15 provided on the first signal path Ru1 and four parallel arm resonators P11 to P14 provided between the first signal path Ru1 and a ground. The five series arm resonators S11 to S15 are connected in series on the first signal path Ru1. In the first filter 1, the five series arm resonators S11 to S15 are arranged from the side of the first switch 7 on the first signal path Ru1, in the order of the series arm resonator S11, the series arm resonator S12, the series arm resonator S13, the series arm resonator S14, and the series arm resonator S15. The parallel arm resonator P11 is connected between the ground and a section between the two series arm resonators S11 and S12 in the first signal path Ru1. The parallel arm resonator P12 is connected between the ground and a section between the two series arm resonators S12 and S13 in the first signal path Ru1. The parallel arm resonator P13 is connected between the ground and a section between the two series arm resonators S13 and S14 in the first signal path Ru1. The parallel arm resonator P14 is connected between the ground and a section between the two series arm resonators S14 and S15 in the first signal path Ru1. In the first filter 1, the series arm resonator S11 that is closest to the first switch 7 among the five series arm resonators S11 to S15 constitutes the first antenna end resonator 14A described above.

As described above, the filter 62 (second filter 2) has the plurality of second acoustic wave resonators 24. In addition, the plurality of second acoustic wave resonators 24 includes the second antenna end resonator 24A. The second filter 2 is a ladder filter, for example, and includes five series arm resonators S21 to S25 provided on the second signal path Ru2 and four parallel arm resonators P21 to P24 provided between the second signal path Ru2 and a ground. The five series arm resonators S21 to S25 are connected in series on the second signal path Ru2. In the second filter 2, the five series arm resonators S21 to S25 are arranged from the side of the first switch 7 on the second signal path Ru2, in the order of the series arm resonator S21, the series arm resonator S22, the series arm resonator S23, the series arm resonator S24, and the series arm resonator S25. The parallel arm resonator P21 is connected between the ground and a section between the two series arm resonators S21 and S22 in the second signal path Ru2. The parallel arm resonator P22 is connected between the ground and a section between the two series arm resonators S22 and S23 in the second signal path Ru2. The parallel arm resonator P23 is connected between the ground and a section between the two series arm resonators S23 and S24 in the second signal path Ru2. The parallel arm resonator P24 is connected between the ground and a section between the two series arm resonators S24 and S25 in the second signal path Ru2. In the second filter 2, the series arm resonator S21 that is closest to the first switch 7 among the five series arm resonators S21 to S25 constitutes the second antenna end resonator 24A described above.

The filter 63 has a plurality of (nine, for example) acoustic wave resonators 34 (hereinafter also referred to as third acoustic wave resonators 34). The plurality of third acoustic wave resonator 34 includes an antenna end resonator 34A (hereinafter referred to as a third antenna end resonator 34A). Among the plurality of third acoustic wave resonators 34, the third antenna end resonator 34A is a third acoustic wave resonator 34 that is provided on a signal path Ru3 (hereinafter also referred to as a third signal path Ru3) connected to the first switch 7 and that is closest to the antenna terminal T1. The “third acoustic wave resonator 34 that is closest to the antenna terminal T1” is a third acoustic wave resonator 34 connected to the antenna terminal T1 with no other third acoustic wave resonators 34 interposed. Therefore, the “third acoustic wave resonator 34 that is closest to the antenna terminal T1” is a third acoustic wave resonator 34 having the shortest physical distance between the third acoustic wave resonator 34 among the plurality of third acoustic wave resonators 34 and the antenna terminal T1. The filter 63 is a ladder filter, for example, and includes five series arm resonators S31 to S35 provided on the third signal path Ru3 and four parallel arm resonators P31 to P34 provided between the third signal path Ru3 and a ground. The five series arm resonators S31 to S35 are connected in series on the third signal path Ru3. In the filter 63, the five series arm resonators S31 to S35 are arranged from the side of the first switch 7 on the third signal path Ru3, in the order of the series arm resonator S31, the series arm resonator S32, the series arm resonator S33, the series arm resonator S34, and the series arm resonator S35. The parallel arm resonator P31 is connected between the ground and a section between the two series arm resonators S31 and S32 in the third signal path Ru3. The parallel arm resonator P32 is connected between the ground and a section between the two series arm resonators S32 and S33 in the third signal path Ru3. The parallel arm resonator P33 is connected between the ground and a section between the two series arm resonators S33 and S34 in the third signal path Ru3. The parallel arm resonator P34 is connected between the ground and a section between the two series arm resonators S34 and S35 in the third signal path Ru3. In the filter 63, the series arm resonator S31 that is closest to the first switch 7 among the five series arm resonators S31 to S35 constitutes the third antenna end resonator 34A.

The filter 64 has a plurality of (nine, for example) acoustic wave resonators 44 (hereinafter also referred to as fourth acoustic wave resonators 44). The plurality of fourth acoustic wave resonator 44 includes an antenna end resonator 44A (hereinafter referred to as a fourth antenna end resonator 44A). Among the plurality of fourth acoustic wave resonators 44, the fourth antenna end resonator 44A includes a fourth antenna end resonator 44A that is a fourth acoustic wave resonator 44 that is provided on a signal path Ru4 (hereinafter also referred to as a fourth signal path Ru4) connected to the first switch 7 and that is closest to the antenna terminal T1. The “fourth acoustic wave resonator 44 that is closest to the antenna terminal T1” is a fourth acoustic wave resonator 44 connected to the antenna terminal T1 with no other fourth acoustic wave resonators 44 interposed. Therefore, the “fourth acoustic wave resonator 44 that is closest to the antenna terminal T1” is a fourth acoustic wave resonator 44 having the shortest physical distance between the fourth acoustic wave resonator 44 among the plurality of fourth acoustic wave resonators 44 and the antenna terminal T1. The filter 64 is a ladder filter, for example, and includes five series arm resonators S41 to S45 provided on the fourth signal path Ru4 and four parallel arm resonators P41 to P44 provided between the fourth signal path Ru4 and a ground. The five series arm resonators S41 to S45 are connected in series on the fourth signal path Ru4. In the filter 64, the five series arm resonators S41 to S45 are arranged from the side of the first switch 7 on the fourth signal path Ru4, in the order of the series arm resonator S41, the series arm resonator S42, the series arm resonator S43, the series arm resonator S44, and the series arm resonator S45. The parallel arm resonator P41 is connected between the ground and a section between the two series arm resonators S41 and S42 in the fourth signal path Ru4. The parallel arm resonator P42 is connected between the ground and a section between the two series arm resonators S42 and S43 in the fourth signal path Ru4. The parallel arm resonator P43 is connected between the ground and a section between the two series arm resonators S43 and S44 in the fourth signal path Ru4. The parallel arm resonator P44 is connected between the ground and a section between the two series arm resonators S44 and S45 in the fourth signal path Ru4. In the filter 64, the series arm resonator S41 that is closest to the first switch 7 among the five series arm resonators S41 to S45 constitutes the fourth antenna end resonator 44A.

The filter 65 has a plurality of (nine, for example) acoustic wave resonators 54 (hereinafter also referred to as fifth acoustic wave resonators 54). The plurality of fifth acoustic wave resonator 54 includes an antenna end resonator 54A (hereinafter referred to as a fifth antenna end resonator 54A). Among the plurality of fifth acoustic wave resonators 54, the fifth antenna end resonator 54A is a fifth acoustic wave resonator 54 that is provided on a signal path Ru5 (hereinafter also referred to as a fifth signal path Ru5) connected to the first switch 7 and that is closest to the antenna terminal T1. The “fifth acoustic wave resonator 54 that is closest to the antenna terminal T1” is a fifth acoustic wave resonator 54 connected to the antenna terminal T1 with no other fifth acoustic wave resonators 54 interposed. Therefore, the “fifth acoustic wave resonator 54 that is closest to the antenna terminal T1” is a fifth acoustic wave resonator 54 having the shortest physical distance between the fifth acoustic wave resonator 54 of the plurality of fifth acoustic wave resonators 54 and the antenna terminal T1. The filter 65 is a ladder filter, for example, and includes five series arm resonators S51 to S55 provided on the fifth signal path Ru5 and five parallel arm resonators P51 to P54 provided between the fifth signal path Ru5 and a ground. The five series arm resonators S51 to S55 are connected in series on the fifth signal path Ru5. In the filter 65, the five series arm resonators S51 to S55 are arranged from the side of the first switch 7 on the fifth signal path Ru5, in the order of the series arm resonator S51, the series arm resonator S52, the series arm resonator S53, the series arm resonator S54, and the series arm resonator S55. The parallel arm resonator P51 is connected between the ground and a section between the two series arm resonators S51 and S52 in the fifth signal path Ru5. The parallel arm resonator P52 is connected between the ground and a section between the two series arm resonators S52 and S53 in the fifth signal path Ru5. The parallel arm resonator P53 is connected between the ground and a section between the two series arm resonators S53 and S54 in the fifth signal path Ru5. The parallel arm resonator P54 is connected between the ground and a section between the two series arm resonators S54 and S55 in the fifth signal path Ru5. In the filter 65, the series arm resonator S51 that is closest to the first switch 7 among the five series arm resonators S51 to S55 constitutes the fifth antenna end resonator 54A.

### (1.1.2) First Switch

As illustrated in FIGS. 6 and 7, the first switch 7 has a common terminal 70 and a plurality of (five in the illustrated example) selection terminals 71 to 75. The common terminal 70 is connected to the antenna terminal T1. The selection terminal 71 is connected to the filter 66. The selection terminal 72 is connected to a connecting point A1 between the filter 61 (first filter 1), the filter 62 (second filter 2), and the filter 63. In addition, the selection terminal 73 is connected to the filter 64. The selection terminal 74 is connected to the filter 65. The selection terminal 75 is connected to a connecting point between the filter 67 and the filter 68. The first switch 7 is, for example, a switch capable of connecting one or more of the five selection terminals 71 to 75 to the common terminal 70. Here, the first switch 7 is, for example, a switch capable of one-to-one connection and one-to-many connection.

The first switch 7 is controlled by the signal processing circuit 601, for example. The first switch 7 switches a connection state between the common terminal 70 and the five selection terminals 71 to 75, according to a control signal from an RF signal processing circuit 602 of the signal processing circuit 601.

### (1.1.3) Low Noise Amplifier

Each of the plurality of (eight, for example) low noise amplifiers 81 to 88 has an input terminal and an output terminal. Each of the plurality of low noise amplifiers 81 to 88 amplifies a reception signal inputted to the input terminal and outputs the signal from the output terminal. The input terminal of the low noise amplifier 81 is connected to the filter 61 (first filter 1) and connected to the selection terminal 72 of the first switch 7 with the filter 61 interposed. The input terminal of the low noise amplifier 82 is connected to the filter 62 (second filter 2) and connected to the selection terminal 72 of the first switch 7 with the filter 62 interposed. The input terminal of the low noise amplifier 83 is connected to the filter 63 and connected to the selection terminal 72 of the first switch 7 with the filter 63 interposed. The input terminal of the low noise amplifier 84 is connected to the filter 64 and connected to the selection terminal 73 of the first switch 7 with the filter 64 interposed. The input terminal of the low noise amplifier 85 is connected to the filter 65 and connected to the selection terminal 74 of the first switch 7 with the filter 65 interposed. The input terminal of the low noise amplifier 86 is connected to the filter 66 and connected to the selection terminal 71 of the first switch 7 with the filter 66 interposed. The input terminal of the low noise amplifier 87 is connected to the filter 67 and connected to the selection terminal 75 of the first switch 7 with the filter 67 interposed. The input terminal of the low noise amplifier 88 is connected to the filter 68 and connected to the selection terminal 75 of the first switch 7 with the filter 68 interposed.

The output terminal of the plurality of low noise amplifiers 81 to 88 is connected to the signal output terminal T2 with the second switch 9 interposed. Therefore, the plurality of low noise amplifiers 81 to 88 is connected to the signal processing circuit 601 with the signal output terminal T2 interposed. The signal output terminal T2 is a terminal for outputting high frequency signals (reception signals) from the plurality of low noise amplifiers 81 to 88 to an external circuit (for example, the signal processing circuit 601).

### (1.1.4) Second Switch

The second switch 9 has a common terminal 90 and a plurality (eight in the illustrated example) of selection terminals 91 to 98. The common terminal 90 is connected to the signal output terminal T2. The eight selection terminals 91 to 98 are connected in a one-to-one manner to the output terminals of the eight low noise amplifiers 81 to 88. The second switch 9 is, for example, a switch capable of connecting the common terminal 90 and one or more of the eight selection terminals 91 to 98. Here, the second switch 9 is, for example, a switch capable of one-to-one and one-to-many connections.

The second switch 9 is controlled by the signal processing circuit 601, for example. The second switch 9 switches a connection state between the common terminal 90 and the eight selection terminals 91 to 98, according to a control signal from the RF signal processing circuit 602 of the signal processing circuit 601.

### (1.2) Structure of High Frequency Module

In the following, a description will be given of a structure of the high frequency module 500 based on FIGS. 1 to 7.

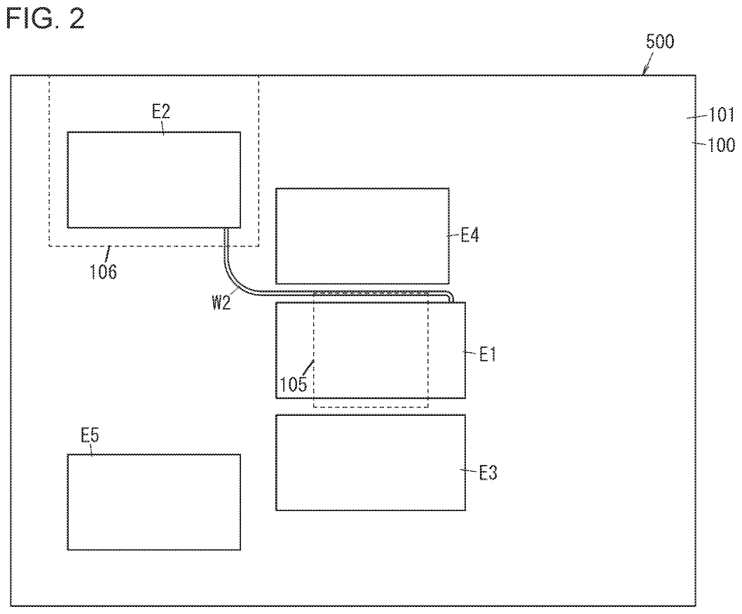

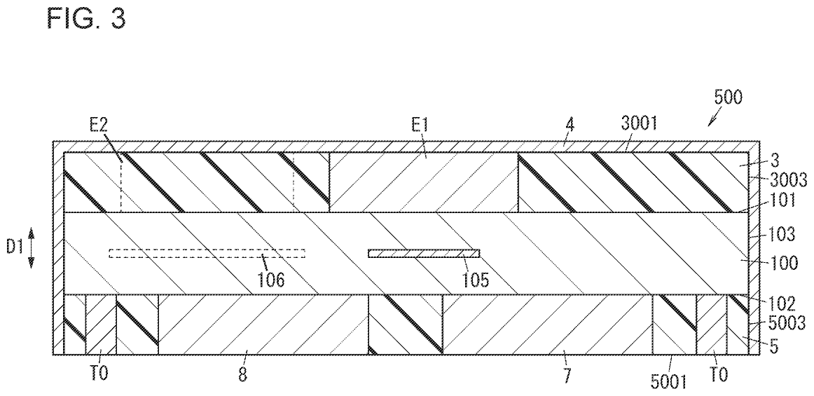

As illustrated in FIG. 1, the high frequency module 500 includes the mounting substrate 100, the plurality of (eight, for example) filters 61 to 68 (see FIG. 6), and the first switch 7. The high frequency module 500 also includes an IC chip 8. The IC chip 8 includes the plurality of (eight, for example) low noise amplifiers 81 to 88 (see FIG. 6) and the second switch 9 (see FIG. 6). In addition, the high frequency module 500 includes the plurality of external connection terminals TO, a first resin layer 3 (see FIG. 3), a second resin layer 5 (see FIG. 3), and a metal electrode layer 4 (see FIG. 3). Note that the illustration of the first resin layer 3, the second resin layer 5, and the metal electrode layer 4 is omitted in FIGS. 1 and 2.

### (1.2.1) Mounting Substrate

As illustrated in FIG. 3, the mounting substrate 100 has the first principal surface 101 and the second principal surface 102 that face each other in a thickness direction D1 of the mounting substrate 100. The mounting substrate 100 includes a plurality of dielectric layers, a plurality of conductive layers, and a plurality of via conductors. In the mounting substrate 100, the plurality of dielectric layers and the plurality of conductive layers are alternately laminated layer by layer in the thickness direction D1 of the mounting substrate 100. That is, the mounting substrate 100 is a multi-layer substrate including the plurality of dielectric layers and the plurality of conductive layers. The plurality of conductive layers is formed in a predetermined pattern that is defined for each layer. Each of the plurality of conductive layers includes one or more conductor parts. The mounting substrate 100 is, for example, a low temperature co-fired ceramics (LTCC) substrate. When the mounting substrate 100 is an LTCC substrate, a material of each of the dielectric layers is, for example, ceramic containing alumina and glass. In addition, a material of each of the conductive layer is copper, for example. The material of each of the conductive layers is not limited to copper and may be silver, for example. The mounting substrate 100 is not limited to the LTCC substrate and may be, for example, a printed wiring board, a high temperature co-fired ceramics (HTCC) substrate, or a resin multi-layer substrate.

The first principal surface 101 and the second principal surface 102 of the mounting substrate 100 are separated in the thickness direction D1 of the mounting substrate 100 and intersect the thickness direction D1 of the mounting substrate 100. The first principal surface 101 of the mounting substrate 100 includes a surface that is orthogonal to the thickness direction D1 of the mounting substrate 100 and a surface that is not orthogonal to the thickness direction D1. In addition, the second principal surface 102 of the mounting substrate 100 is, for example, orthogonal to the thickness direction D1 of the mounting substrate 100, but may include, for example, a side surface of the conductor part, or the like, as a surface that is not orthogonal to the thickness direction D1 of the mounting substrate 100.

In one of the plurality of conductive layers, a plurality of conductor parts includes a first ground conductor part 105 (see FIGS. 2 and 3) and a second ground conductor part 106 (see FIGS. 2 and 3). The first ground conductor part 105 and the second ground conductor part 106 may be included in mutually different conductive layers. As illustrated in FIG. 2, each of the first ground conductor part 105 and the second ground conductor part 106 has a rectangular shape in plan view from the thickness direction D1 of the mounting substrate 100, but is not limited thereto. The first ground conductor part 105 and the second ground conductor part 106 are circuit grounds of the high frequency module 500.

The first ground conductor part 105 is connected to the external ground terminal T3 (see FIG. 1) with the via conductor or the like interposed. The second ground conductor part 106 is connected to the external ground terminal T3 with the via conductor or the like interposed. In addition, the first ground conductor part 105 and the second ground conductor part 106 are electrically connected to the metal electrode layer 4 (see FIG. 3). The first ground conductor part 105 is in contact with the metal electrode layer 4.

### (1.2.2) Electronic Components

As illustrated in FIGS. 1 to 3, in the high frequency module 500, a plurality of (five, for example) electronic components (the first electronic component E1, the second electronic component E2, a third electronic component E3, a fourth electronic component E4, and a fifth electronic component E5) is mounted on the first principal surface 101 of the mounting substrate 100, and a plurality of (two, for example) electronic components (the first switch 7 and the IC chip 8) is mounted on the second principal surface 102 of the mounting substrate 100. “The electronic components are mounted on the first principal surface 101 of the mounting substrate 100” includes that the electronic components are disposed (mechanically connected) on the first principal surface 101 of the mounting substrate 100 and that the electronic components are electrically connected to (appropriate conductor parts of) the mounting substrate 100. “The electronic components are mounted on the second principal surface 102 of the mounting substrate 100” includes that the electronic components are disposed (mechanically connected) on the second principal surface 102 of the mounting substrate 100 and that the electronic components are electrically connected to (appropriate conductor parts of) the mounting substrate 100. As illustrated in FIG. 7, the first electronic component E1 includes the first filter 1 (filter 61), the second antenna end resonator 24A (series arm resonator S21) of the second filter 2 (filter 62), and the filter 63. As illustrated in FIG. 7, the second electronic component E2 includes the second acoustic wave resonators 24 (the series arm resonators S22 to S25 and the parallel arm resonators P21 to P24) other than the second antenna end resonator 24A among the plurality of the second acoustic wave resonators 24 of the second filter 2 (filter 62). The second filter 2 includes a wiring section W2 (see FIGS. 1 and 7) of the mounting substrate 100. The wiring section W2 is a conductor part that connects the second antenna end resonator 24A of the first electronic component E1 with the series arm resonator S22 of the second electronic component E2. As illustrated in FIG. 7, the third electronic component E3 includes the filter 64 and the filter 65. The fourth electronic component E4 (see FIGS. 1 and 2) includes the filter 66 (see FIG. 6). The fifth electronic component E5 (see FIGS. 1 and 2) includes the filter 67 (see FIG. 6) and the filter 68 (see FIG. 6).

As illustrated in FIG. 1, an outer edge of each of the first electronic component E1, the second electronic component E2, the third electronic component E3, the fourth electronic component E4, and the fifth electronic component E5 has a rectangular shape in plan view from the thickness direction D1 of the mounting substrate 100. An outer edge of each of the first switch 7 and the IC chip 8 has a rectangular shape in plan view from the thickness direction D1 of the mounting substrate 100.

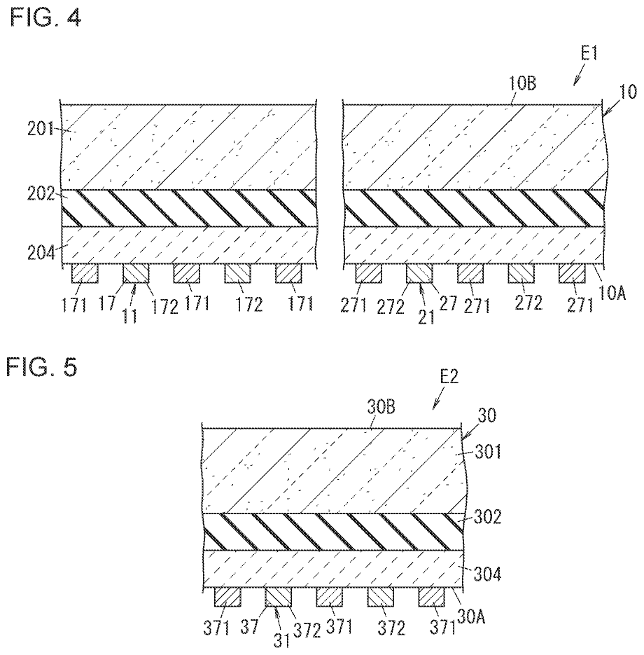

As described above, the first electronic component E1 includes the first filter 1, the second antenna end resonator 24A of the second filter 2, and the filter 63 (see FIG. 7), but is not limited thereto and may only include at least the first filter 1 and the second antenna end resonator 24A of the second filter 2. As illustrated in FIG. 4, the first filter 1 includes a first substrate (the substrate 10), and a plurality of first functional electrodes 11 that are provided on the first substrate and that constitute a part of each of the plurality of first acoustic wave resonators 14 (FIG. 4 illustrates only a part of one first functional electrode 11 of the plurality of first functional electrodes 11). In the high frequency module 500, the first filter 1 is an acoustic wave filter that utilizes surface acoustic waves, and each of the plurality of first functional electrodes 11 includes an interdigital transducer (IDT) electrode 17. The IDT electrode 17 has a plurality of first electrode fingers 171, a plurality of second electrode fingers 172, a first busbar (not illustrated) to which the plurality of first electrode fingers 171 is connected, and a second busbar (not illustrated) to which the plurality of second electrode fingers 172 is connected. In the first filter 1, each of the plurality of first acoustic wave resonators 14 includes the IDT electrode 17 and a part of the first substrate. The characteristics of the first filter 1 can be changed, for example, by appropriately changing a pitch of the electrode fingers of the IDT electrode 17 included in the first functional electrode 11, an intersecting width of the IDT electrode 17, the material of the first substrate, or the like. The pitch of the electrode fingers of the IDT electrode 17 is defined by a distance between the center lines of the two adjacent first electrode fingers 171 among the plurality of first electrode fingers 171 or a distance between the center lines of the two adjacent second electrode fingers 172 among the plurality of second electrode fingers 172.

The second filter 2 includes a second substrate (the substrate 10), a second functional electrode 21 (see FIG. 4) that is provided on the second substrate and that constitutes a part of the second antenna end resonator 24A, a third substrate 30 (see FIG. 5) that is separate from the second substrate, and at least one (eight, for example) third functional electrode 31 that is provided on the third substrate 30 and that constitutes a part of at least one (eight, for example) second acoustic wave resonator 24 other than the second antenna end resonator 24A (FIG. 5 illustrates only a part of the one third functional electrode 31 of the eight third functional electrodes 31). In the high frequency module 500, the second filter 2 is an acoustic wave filter that utilizes surface acoustic waves, and the second functional electrode 21 includes an IDT electrode 27, and the third functional electrode 31 includes an IDT electrode 37. The IDT electrode 27 has a plurality of first electrode fingers 271, a plurality of second electrode fingers 272, a first busbar (not illustrated) to which the plurality of first electrode fingers 271 is connected, a the second busbar (not illustrated) to which the plurality of second electrode fingers 272 is connected. The IDT electrode 37 has a plurality of first electrode fingers 371, a plurality of second electrode fingers 372, a first busbar (not illustrated) to which the plurality of first electrode fingers 371 is connected, and a second busbar (not illustrated) to which the plurality of second electrode fingers 372 is connected. The characteristics of the second filter 2 can be changed, for example, by appropriately changing a pitch of the electrode fingers of the IDT electrode 27 included in the second functional electrode 21, an intersecting width of the IDT electrode 27, the material of the second substrate, or the like. The characteristics of the second filter 2 can also be changed, for example, by appropriately changing a pitch of the electrode fingers of the IDT electrode 37 included in the third functional electrode 31, an intersecting width of the IDT electrode 37, the material of the third substrate 30, or the like.

In addition, the filter 63 includes a fourth substrate and a plurality of functional electrodes that are provided on the fourth substrate and that constitute a part of each of the plurality of third acoustic wave resonators 34. In the high frequency module 500, the filter 63 is an acoustic wave filter that utilizes surface acoustic waves, and each of the plurality of functional electrodes includes an IDT electrode. In addition, the filter 64 includes a fifth substrate and a plurality of functional electrodes that are provided on the fifth substrate and that constitute a part of each of the plurality of the fourth acoustic wave resonator 44. In the high frequency module 500, the filter 64 is the acoustic wave filter that utilizes surface acoustic waves, and each of the plurality of functional electrodes has an IDT electrode.

In the first electronic component E1, the first substrate, the second substrate, and the fourth substrate are common. In other words, in the first electronic component E1, the first substrate, the second substrate, and the fourth substrate are the identical substrate 10. The outer edge of the substrate 10 has a rectangular shape in plan view from the thickness direction D1 of the mounting substrate 100, but is not limited thereto. As described above, the first electronic component E1 includes the first filter 1, the second antenna end resonator 24A of the second filter 2, and the filter 63, but is not limited thereto and may only include at least the first filter 1 and the second antenna end resonator 24A of the second filter 2. In this case, in the first electronic component E1, the first substrate and the second substrate are the identical substrate 10.

As illustrated in FIG. 4, the second substrate (substrate 10) includes a piezoelectric layer 204 (hereinafter also referred to as a first piezoelectric layer 204) and a high acoustic velocity member 201 (hereinafter also referred to as a first high acoustic velocity member 201). The high acoustic velocity member 201 is a high acoustic velocity support substrate that is located on the side opposite from the second functional electrode 21 with the piezoelectric layer 204 in between. In the high acoustic velocity member 201, an acoustic velocity of a bulk wave propagating through the high acoustic velocity member 201 is higher than the acoustic velocity of an acoustic wave propagating through the piezoelectric layer 204. Here, the bulk wave propagating through the high acoustic velocity member 201 is a bulk wave with the lowest acoustic velocity, among a plurality of bulk waves propagating through the high acoustic velocity member 201. In addition, the second substrate further includes a low acoustic velocity film 202 that is disposed between the high acoustic velocity member 201 and the piezoelectric layer 204. The low acoustic velocity film 202 is a film in which the acoustic velocity of a bulk wave propagating through the low acoustic velocity film 202 is lower than the acoustic velocity of a bulk wave propagating through the piezoelectric layer 204.

As illustrated in FIG. 5, the third substrate 30 includes a piezoelectric layer 304 (hereinafter also referred to as a second piezoelectric layer 304) and a high acoustic velocity member 301 (hereinafter also referred to as a second high acoustic velocity member 301). The high acoustic velocity member 301 is a high acoustic velocity support substrate that is located on the side opposite from the third functional electrode 31 with the piezoelectric layer 304 in between. In the high acoustic velocity member 301, the acoustic velocity of a bulk wave propagating through the high acoustic velocity member 301 is higher than the acoustic velocity of an acoustic wave propagating through the piezoelectric layer 304. Here, the bulk wave propagating through the high acoustic velocity member 301 is a bulk wave with the lowest acoustic velocity, among a plurality of bulk waves propagating through the high acoustic velocity member 301. In addition, the third substrate 30 further includes a low acoustic velocity film 302 that is disposed between the high acoustic velocity member 301 and the piezoelectric layer 304. The low acoustic velocity film 302 is a film in which the acoustic velocity of a bulk wave propagating through the low acoustic velocity film 302 is lower than the acoustic velocity of a bulk wave propagating through the piezoelectric layer 304.

A material of each of the piezoelectric layer 204 and the piezoelectric layer 304 is, for example, lithium tantalate or lithium niobate.

A material of each of the high acoustic velocity member 201 and the high acoustic velocity member 301 is, for example, silicon. The material of each of the high acoustic velocity member 201 and the high acoustic velocity member 301 may only include at least one kind of materials selected from the group consisting of, for example, silicon, aluminum nitride, aluminum oxide, silicon carbide, silicon nitride, sapphire, lithium tantalate, lithium niobate, quartz, alumina, zirconia, cordierite, mullite, steatite, forsterite, magnesia, and diamond.

A material of each of the low acoustic velocity film 202 and the low acoustic velocity film 302 is silicon oxide, for example. The material of each of the low acoustic velocity film 202 and the low acoustic velocity film 302 is not limited to silicon oxide. The material of each of the low acoustic velocity film 202 and the low acoustic velocity film 302 may only be, for example, silicon oxide, glass, silicon oxynitride, tantalum oxide, a compound obtained by adding fluorine, carbon, or boron to silicon oxide, or a material having each of the above materials as a main component.

As illustrated in FIGS. 1 and 7, the first electronic component E1 has a plurality of (six, for example) first external terminals 110. The plurality of first external terminals 110 includes a common terminal 111, an input/output terminal 112, a connection terminal 113, an input/output terminal 114, and a plurality of (two, for example) ground terminals 116. The common terminal 111 is an input terminal to which the first antenna end resonator 14A of the first filter 1, the second antenna end resonator 24A, and the third antenna end resonator 34A of the filter 63 are connected. The input/output terminal 112 is an output terminal that is connected to the series arm resonator S15 of the first filter 1 and connected to the low noise amplifier 81 (see FIG. 6). The connection terminal 113 is a terminal that is connected to the second antenna end resonator 24A and connected to the wiring section W2. The input/output terminal 114 is an output terminal that is connected to the series arm resonator S35 of the filter 63 and connected to the low noise amplifier 83 (see FIG. 6).

As illustrated in FIGS. 1 and 7, the second electronic component E2 has a plurality of (four, for example) second external terminals 120. The plurality of second external terminals 120 includes a connection terminal 123, an input/output terminal 124, and a plurality of (two, for example) ground terminals 126. The connection terminal 123 is a terminal that is connected to the series arm resonator S22 and connected to the wiring section W2. The input/output terminal 124 is an output terminal that is connected to the series arm resonator S25 of the second filter 2 and connected to the low noise amplifier 82 (see FIG. 6).

Each of the first electronic component E1 and the second electronic component E2 is a chip (also referred to as a die), but is not limited thereto and may have a chip and a package structure provided on the chip. The package structure of the first electronic component E1 includes, for example, the first spacer layer being disposed on a first principal surface 10A of the substrate 10 (see FIG. 4) having the first principal surface 10A and a second principal surface 10B and the first cover member being disposed on the first spacer layer so as to face the substrate 10 in the thickness direction of the substrate 10. The package structure of the second electronic component E2 includes, for example, the second spacer layer being disposed on a first principal surface 30A of the third substrate 30 (see FIG. 5) having the first principal surface 30A and a second principal surface 30B, and the second cover member being disposed on the second spacer layer so as to face the third substrate 30 in the thickness direction of the third substrate 30. The first spacer layer and the second spacer layer have electrical insulating properties. Materials of the first spacer layer and the second spacer layer are epoxy resin, polyimide, or the like. The first cover member and the second cover member have a flat plate shape. The first cover member overlaps the plurality of first functional electrodes 11 and second functional electrodes 21 in the thickness direction of the substrate 10, and are separated from the plurality of first functional electrodes 11 and second functional electrodes 21 in the thickness direction of the substrate 10. The second cover member is separated from the plurality of third functional electrodes 31 in the thickness direction of the third substrate 30. The first cover member and the second cover member have electrical insulating properties. Materials of the first cover member and the second cover member are epoxy resin, polyimide, or the like. When the first electronic component E1 has the package structure, the plurality of first external terminals 110 is configured to be exposed from the first cover member. When the second electronic component E2 has the package structure, the plurality of second external terminals 120 is configured to be exposed from the second cover member. Each of the plurality of first external terminals 110 and the plurality of second external terminals 120 has a conductive bump. The material of the conductive bump is, for example, solder, gold, or copper.

As illustrated in FIGS. 1 and 7, the third electronic component E3 has a plurality of (six, for example) third external terminals 130. The plurality of third external terminals 130 includes an input/output terminal 131, an input/output terminal 132, an input/output terminal 133, an input/output terminal 134, and a plurality of (two, for example) ground terminals 136. The input/output terminal 131 is an input terminal that is connected to the series arm resonator S41 of the filter 64 and connected to the first switch 7. The input/output terminal 132 is an output terminal that is connected to the series arm resonator S45 of the filter 64 and connected to the low noise amplifier 84. The input/output terminal 133 is an input terminal that is connected to the series arm resonator S51 of the filter 65 and connected to the first switch 7. The input/output terminal 134 is an output terminal that is connected to the series arm resonator S55 of the filter 65 and connected to the low noise amplifier 85 (see FIG. 6).

As illustrated in FIG. 1, the fourth electronic component E4 has a plurality of (four, for example) fourth external terminals 140. The plurality of fourth external terminals 140 includes an input/output terminal 141, an input/output terminal 142, and a plurality of (two, for example) ground terminals 146. The input/output terminal 141 is an input terminal that is connected to the filter 66 (see FIG. 6) and connected to the first switch 7. The input/output terminal 142 is an output terminal that is connected to the filter 66 and connected to the low noise amplifier 86 (see FIG. 6).

As illustrated in FIG. 1, the fifth electronic component E5 has a plurality of (six, for example) fifth external terminals 150. The plurality of fifth external terminals 150 includes an input/output terminal 151, an input/output terminal 152, an input/output terminal 153, an input/output terminal 154, and a plurality of (two, for example) ground terminals 156. The input/output terminal 151 is an input terminal that is connected to the filter 67 (see FIG. 6) and connected to the first switch 7. The input/output terminal 152 is an output terminal that is connected to the filter 67 and connected to the low noise amplifier 87 (see FIG. 6). The input/output terminal 153 is an input terminal that is connected to the filter 68 (see FIG. 6) and connected to the first switch 7. The input/output terminal 154 is an output terminal that is connected to the filter 68 and connected to the low noise amplifier 88 (see FIG. 6).

Each of the third electronic component E3, the fourth electronic component E4, and the fifth electronic component E5 is a chip (also referred to as a die), but is not limited thereto and may have a chip and a package structure provided on the chip, as with the first electronic component E1 and the second electronic component E2.

The first switch 7 is, for example, an Si-based IC chip including a switch integrated circuit (IC).

The IC chip 8 is, for example, an Si-based IC chip including the plurality of low noise amplifiers 81 to 88 and the second switch 9.

### (1.2.3) External Connection Terminals

As illustrated in FIGS. 1 and 3, the plurality of external connection terminals TO are disposed on the second principal surface 102 of the mounting substrate 100. “The external connection terminals TO are disposed on the second principal surface 102 of the mounting substrate 100” includes that the external connection terminals TO are mechanically connected to the second principal surface 102 of the mounting substrate 100 and that the external connection terminals TO are electrically connected to (appropriate conductor parts) of the mounting substrate 100. A material of the plurality of external connection terminals T0 is, for example, metal (copper, a copper alloy, or the like). Each of the plurality of external connection terminals TO is a columnar electrode. The columnar electrode is a cylindrical electrode, for example. The plurality of external connection terminals TO is bonded to the conductor part of the mounting substrate 100 by soldering, for example, but is not limited thereto and may be bonded by using, for example, a conductive adhesive (such as a conductive paste) or may be directly bonded. Each of the plurality of external connection terminals TO is circular in plan view from the thickness direction D1 of the mounting substrate 100.

The plurality of external connection terminals TO includes the antenna terminal T1, the signal output terminal T2, and the plurality of external ground terminals T3. The plurality of external ground terminals T3 is electrically connected to at least one of the first ground conductor part 105 (see FIGS. 2 and 3) or the second ground conductor part 106 of the mounting substrate 100 (see FIGS. 2 and 3).

### (1.2.4) First Resin Layer

As illustrated in FIG. 3, the first resin layer 3 is disposed on the first principal surface 101 of the mounting substrate 100. The first resin layer 3 covers a plurality of (five, for example) electronic components mounted on the first principal surface 101 of the mounting substrate 100. As described above, the five electronic components include the first electronic component E1, the second electronic component E2, the third electronic component E3, the fourth electronic component E4, and the fifth electronic component E5. The first resin layer 3 includes a resin (such as an epoxy resin). The first resin layer 3 may include a filler in addition to the resin.

### (1.2.5) Second Resin Layer

As illustrated in FIG. 3, the second resin layer 5 is disposed on the second principal surface 102 of the mounting substrate 100. The second resin layer 5 covers an outer peripheral surface of each of a plurality of (two, for example) electronic components mounted on the second principal surface 102 of the mounting substrate 100 and an outer peripheral surface of each of the plurality of external connection terminals TO. The outer peripheral surface of each of the two electronic components includes four side surfaces of each of the electronic components. The second resin layer 5 does not cover the principal surface of each of the two electronic components on the side opposite from the mounting substrate 100. As described above, the two electronic components include the first switch 7 and the IC chip 8. The second resin layer 5 does not cover the principal surface of the first switch 7 on the side opposite from the mounting substrate 100. The second resin layer 5 includes a resin (such as an epoxy resin). The second resin layer 5 may include a filler in addition to the resin. A material of the second resin layer 5 may be same as the material of the first resin layer 3 or may be different from the material of the first resin layer 3.

### (1.2.6) Metal Electrode Layer

As illustrated in FIG. 3, the metal electrode layer 4 covers the first resin layer 3. The metal electrode layer 4 is connected to the external ground terminal T3 of the mounting substrate 100. The metal electrode layer 4 has electric conductivity. In the high frequency module 500, the metal electrode layer 4 is, for example, a shield layer provided for the purpose of electromagnetic shield inside and outside of the high frequency module 500. The metal electrode layer 4 has a multilayer structure in which a plurality of metal layers is laminated, but is not limited thereto and may be a single metal layer. The metal layer includes one or more kinds of metals. When the metal electrode layer 4 has the multilayer structure in which the plurality of metal layers is laminated, the metal electrode layer 4 includes a first stainless steel layer on the first resin layer 3, a Cu layer on the first stainless steel layer, and a second stainless steel layer on the Cu layer. A material of each of the first stainless steel layer and the second stainless steel layer is an alloy containing Fe, Ni, and Cr. In addition, when the metal electrode layer 4 is a single metal layer, the metal electrode layer 4 is a Cu layer, for example. The metal electrode layer 4 covers a principal surface 3001 of the first resin layer 3 on the side opposite from the mounting substrate 100, an outer peripheral surface 3003 of the first resin layer 3, an outer peripheral surface 103 of the mounting substrate 100, and an outer peripheral surface 5003 of the second resin layer 5. A principal surface 5001 of the second resin layer 5 on the side opposite from the mounting substrate 100 is exposed, and not covered with the metal electrode layer 4. The metal electrode layer 4 is electrically connected to the first ground conductor part 105, the second ground conductor part 106, and the plurality of external ground terminals T3 of the mounting substrate 100. This allows the high frequency module 500 to make a potential of the metal electrode layer 4 substantially the same as a potential of the first ground conductor part 105 and the second ground conductor part 106 of the mounting substrate 100.

### (1.3) Layout of High Frequency Module

As illustrated in FIG. 1, in the high frequency module 500, the first electronic component E1 and the third electronic component E3 are adjacent to each other in plan view from the thickness direction D1 (see FIG. 3) of the mounting substrate 100. “The first electronic component E1 and the third electronic component E3 are adjacent to each other” means that in plan view from the thickness direction D1 of the mounting substrate 100, between the first electronic component E1 and the third electronic component E3, there is no other electronic component disposed on the first principal surface 101 of the mounting substrate 100 and that the first electronic component E1 and the third electronic component E3 are adjacent to each other.

In addition, in the high frequency module 500, in plan view from the thickness direction D1 of the mounting substrate 100, the first electronic component E1 and the fourth electronic component E4 are adjacent to each other. “The first electronic component E1 and the fourth electronic component E4 are adjacent to each other” means that in plan view from the thickness direction D1 of the mounting substrate 100, between the first electronic component E1 and the fourth electronic component E4, there is no other electronic component disposed on the first principal surface 101 of the mounting substrate 100 and that the first electronic component E1 and the fourth electronic component E4 are adjacent to each other.

In addition, in the high frequency module 500, the switch 7 disposed on the second principal surface 102 of the mounting substrate 100 overlaps a part of each of the first electronic component E1, the third electronic component E3, and the fourth electronic component E4 in plan view from the thickness direction D1 of the mounting substrate 100. In plan view from the thickness direction D1 of the mounting substrate 100, the switch 7 overlaps the common terminal 111 of the first electronic component E1. In addition, in plan view from the thickness direction D1 of the mounting substrate 100, the switch 7 overlaps the input/output terminal 131 of the third electronic component E3. In addition, in plan view from the thickness direction D1 of the mounting substrate 100, the switch 7 overlaps the input/output terminal 141 of the fourth electronic component E4.

In addition, in the high frequency module 500, the IC chip 8 disposed on the second principal surface 102 of the mounting substrate 100 overlaps a part of each of the first electronic component E1, the second electronic component E2, the third electronic component E3, and the fourth electronic component E4 in plan view from the thickness direction D1 of the mounting substrate 100. In plan view from the thickness direction D1 of the mounting substrate 100, the IC chip 8 overlaps the input/output terminal 112 and the input/output terminal 114 of the first electronic component E1. In addition, in plan view from the thickness direction D1 of the mounting substrate 100, the IC chip 8 overlaps the input/output terminal 132 and the input/output terminal 134 of the third electronic component E3. In addition, in plan view from the thickness direction D1 of the mounting substrate 100, the IC chip 8 overlaps the input/output terminal 142 of the fourth electronic component E4.

In addition, in the high frequency module 500, the plurality of external connection terminals TO is arranged in a direction along the outer edge of the mounting substrate 100 in the second principal surface 102 of the mounting substrate 100. In the high frequency module 500, in plan view of the thickness direction D1 of the mounting substrate 100, the antenna terminal T1 and the switch 7 are adjacent to each other. “The antenna terminal T1 and the switch 7 are adjacent to each other” means that in plan view from the thickness direction D1 of the mounting substrate 100, between the antenna terminal T1 and the switch 7, there are neither other electronic component (IC chip 8) nor other external connection terminals TO that are disposed on the second principal surface 102 of the mounting substrate 100 and that the antenna terminal T1 and the switch 7 are adjacent to each other.

In the high frequency module 500, in plan view from the thickness direction D1 of the mounting substrate 100, the second electronic component E2 is separated from the first electronic component E1. In plan view from the thickness direction D1 of the mounting substrate 100, a distance between the first electronic component E1 and the switch 7 is shorter than a distance between the second electronic component E2 and the switch 7. In plan view from the thickness direction D1 of the mounting substrate 100, the distance between the first electronic component E1 and the switch 7 means the shortest distance between the first electronic component E1 and the switch 7, and the distance when the first electronic component E1 and the switch 7 overlap in plan view from the thickness direction D1 of the mounting substrate 100 is zero. In plan view from the thickness direction D1 of the mounting substrate 100, the distance between the second electronic component E2 and the switch 7 means the shortest distance between the second electronic component E2 and the switch 7 in plan view.

As illustrated in FIG. 2, in the high frequency module 500, the first ground conductor part 105 at least partially overlaps the first electronic component E1 in plan view from the thickness direction D1 of the mounting substrate 100. The second ground conductor part 106 at least partially overlaps the second electronic component E2 in plan view from the thickness direction D1 of the mounting substrate 100. In plan view from the thickness direction D1 of the mounting substrate 100, a ratio of the area of the part overlapping the second ground conductor part 106 to the area of the second electronic component E2 is higher than a ratio of the area of the part overlapping the first ground conductor part 105 to the area of the first electronic component E1. In addition, in the high frequency module 500, in plan view from the thickness direction D1 of the mounting substrate 100, the area of the part of the second ground conductor part 106 that overlaps the second electronic component E2 is larger than the area of the part of the first ground conductor part 105 that overlaps the first electronic component E1.

In addition, in the high frequency module 500, in plan view from the thickness direction D1 of the mounting substrate 100, the first ground conductor part 105 in part or in whole may overlap the entire first electronic component E1. In addition, in the high frequency module 500, in plan view from the thickness direction D1 of the mounting substrate 100, the second ground conductor part 106 in part or in whole may overlap the entire second electronic component E2.

### (2) Effects

The high frequency module 500 according to Embodiment 1 includes the mounting substrate 100, the antenna terminal T1, the switch 7, and the plurality of filters 61 to 68. The mounting substrate 100 has the first principal surface 101 and the second principal surface 102 that face each other. The antenna terminal T1 is disposed on the mounting substrate 100. The switch 7 is disposed on the mounting substrate 100. The switch 7 is connected to the antenna terminal T1. The plurality of filters 61 to 68 is connected to the antenna terminal T1 with the switch 7 interposed. The plurality of filters 61 to 68 includes the first filter 1 (filter 61) that has the pass band including the frequency band of the first communication band (Band66 of the 3GPP LTE standard, for example) and the second filter 2 (filter 62) that has the pass band including the frequency band of the second communication band (Band25 of the 3GPP LTE standard, for example) that is capable of simultaneous communication with the first communication band. The first filter 1 has the plurality of first acoustic wave resonators 14. The second filter 2 has the plurality of second acoustic wave resonators 24. The plurality of first acoustic wave resonators 14 includes the first antenna end resonator 14A. Among the plurality of first acoustic wave resonators 14, the first antenna end resonator 14A is the first acoustic wave resonator 14 that is provided on the first signal path Ru1 connected to the switch 7 and that is closest to the antenna terminal T1. The plurality of second acoustic wave resonators 24 includes the second antenna end resonator 24A. Among the plurality of second acoustic wave resonators 24, the second antenna end resonator 24A is the second acoustic wave resonator 24 that is provided on the second signal path Ru2 connected to the switch 7 and that is closest to the antenna terminal T1. The first electronic component E1 having the first filter 1 and the second antenna end resonator 24A of the second filter 2 is disposed on the first principal surface 101 of the mounting substrate 100. The second electronic component E2 having at least one of the above-described second acoustic wave resonators 24 of the second filter 2 is disposed on the first principal surface 101 of the mounting substrate 100. In plan view of the thickness direction D1 of the mounting substrate 100, the distance between the first electronic component E1 and the switch 7 is shorter than the distance of the second electronic component E2 and the switch 7.

The high frequency module 500 according to Embodiment 1 can suppress the degradation of the characteristics during simultaneous communication. More particularly, the high frequency module 500 includes the plurality of filters 61 to 68, but with respect to the first filter 1 (filter 61) and the second filter 2 (filter 62) utilized in simultaneous communication, the second electronic component E2 having the second acoustic wave resonators 24 other than the second antenna end resonator 24A among the plurality of second acoustic wave resonators 24 of the second filter 2 is disposed at a position on the first principal surface 101 of the mounting substrate 100, the position being separated from the first electronic component E1. The second acoustic wave resonators 24 other than the second antenna end resonator 24A among the plurality of second acoustic wave resonators 24 are less likely to affect the impedance of the frequency band of the first filter 1 than the second antenna end resonator 24A. In the high frequency module 500, the first antenna end resonator 14A of the first filter 1 and the second antenna end resonator 24A of the second filter 2 can be disposed close to the switch 7. Therefore, in the high frequency module 500, it is possible to reduce loss or parasitic capacitance that occurs in the wiring section between the second antenna end resonator 24A of the second filter 2 and the switch 7. Therefore, the high frequency module 500 can suppress the impedance of the first filter 1 from decreasing in the frequency band of the second communication band. In a Smith chart, for example, the impedance of the first filter 1 can be set close to open (infinite) in the frequency band of the second communication band. As a result, in the high frequency module 500, even if the first antenna end resonator 14A of the first filter 1 and the second antenna end resonator 24A of the second filter 2 are connected, the impedance of the first filter 1 hardly changes. Consequently, the high frequency module 500 can suppress the degradation of the characteristics during simultaneous communication.

In addition, in the high frequency module 500 according to Embodiment 1, as the first electronic component E1 includes only the second antenna end resonator 24A of the plurality of the second acoustic wave resonators 24 with respect to the second filter 2, it is possible to include, in the first electronic component E1, the third antenna end resonator 34A of the filter 63 that has the pass band including the frequency band of the third communication band (Band30, for example) that is capable of simultaneous communication with the second communication band (Band25), while suppressing an increase in size of the first electronic component E1. This allows the high frequency module 500 to make the distance between the first electronic component E1, which includes the first antenna end resonator 14A of the first filter 1, the second antenna end resonator 24A of the second filter 2, and the third antenna end resonator 34A of the filter 63, and the switch 7 shorter than the distance between the second electronic component E2 and the switch 7. The high frequency module 500 according to Embodiment 1 can also make the distance between the fourth antenna end resonator 44A of the filter 64, which has the pass band including the frequency band of the fourth communication band (Band41, for example) capable of simultaneous communication with the second communication band (Band25, for example), and the switch 7 shorter than the distance between the second electronic component E2 and the switch 7.

In addition, the high frequency module 500 according to Embodiment 1 has a high degree of freedom in arrangement of the second electronic component E2 on the first principal surface 101 of the mounting substrate 100, which thus makes it possible to dispose the second electronic component E2 in, for example, an area in the mounting substrate 100 with high heat dissipation. In the high frequency module 500 according to Embodiment 1, this makes it easier to dispose the second electronic component E2, for example, so that the ratio of the area of the part overlapping the second ground conductor part 106 to the area of the second electronic component E2 is higher than the ratio of the area of the part overlapping the first ground conductor part 105 to the area of the first electronic component E1, in plan view from the thickness direction D1 of the mounting substrate 100. In addition, in the high frequency module 500, it becomes easier to dispose the second electronic component E2, for example, so that the area of the part of the second ground conductor part 106 that overlaps the second electronic component E2 is larger than the area of the part of the first ground conductor part 105 that overlaps the first electronic component E1, in plan view from the thickness direction D1 of the mounting substrate 100. As a result, the high frequency module 500 can improve heat dissipation, improve electric power handling capability, and suppress characteristic fluctuations due to a temperature rise.

In addition, in the high frequency module 500 according to Embodiment 1, it is easier to dispose the second electronic component E2 so that the second electronic component E2 overlaps the IC chip 8 in plan view from the thickness direction D1 of the mounting substrate 100, which makes it possible to shorten a wiring length between the second filter 2 and the low noise amplifier 82.

In addition, in the high frequency module 500 according to Embodiment 1, the antenna terminal T1 and the switch 7 are disposed on the second principal surface 102 of the mounting substrate 100. In addition, the first electronic component E1 and the switch 7 overlap in plan view from the thickness direction D1 of the mounting substrate 100. This allows the high frequency module 500 according to Embodiment 1 to reduce the loss due to the wiring section between the first antenna end resonator 14A and the switch 7 and the loss due to the wiring section between the second antenna end resonator 24A and the switch 7, respectively.

### (3) Communication Device

As illustrated in FIG. 6, the communication device 600 according to Embodiment 1 includes the signal processing circuit 601 and the high frequency module 500. The signal processing circuit 601 is connected to the high frequency module 500.

The communication device 600 further includes the antenna 610. The communication device 600 further includes a circuit board in or on which the high frequency module 500 is mounted. The circuit board is a printed wiring board, for example. The circuit board has a ground electrode supplied with a ground potential.

The signal processing circuit 601 includes, for example, the RF signal processing circuit 602 and a baseband signal processing circuit 603. The RF signal processing circuit 602 is, for example, a radio frequency integrated circuit (RFIC) and performs signal processing for high frequency signals. The RF signal processing circuit 602 performs, for example, signal processing such as up-conversion on high frequency signals (transmission signals) outputted from the baseband signal processing circuit 603 and outputs the signal-processed high frequency signals. The RF signal processing circuit 602 also performs, for example, signal processing such as down-conversion on high frequency signals (reception signals) outputted from the high frequency module 500 and outputs the signal-processed high frequency signals to the baseband signal processing circuit 603. The baseband signal processing circuit 603 is, for example, a baseband integrated circuit (BBIC). The baseband signal processing circuit 603 generates an I-phase signal and a Q-phase signal from a baseband signal. The baseband signal is, for example, an audio signal, an image signal, or the like, inputted from outside. The baseband signal processing circuit 603 performs IQ modulation processing by synthesizing the I-phase signal and the Q-phase signal and outputs a transmission signal. At this time, the transmission signal is generated as a modulated signal (IQ signal) obtained by subjecting a carrier wave signal with a predetermined frequency to amplitude modulation in a period longer than a period of the carrier wave signal. The reception signal processed by the baseband signal processing circuit 603 is used as an image signal for displaying an image or as an audio signal for a call by a user of the communication device 600. The high frequency module 500 transmits the high frequency signals (reception signals and transmission signals) between the antenna 610 and the RF signal processing circuit 602 of the signal processing circuit 601.

As the communication device 600 according to Embodiment 1 includes the high frequency module 500 and the signal processing circuit 601, the communication device 600 can suppress the degradation of the characteristics during simultaneous communication.

### (4) Other Examples of First Electronic Component and Second Electronic Component

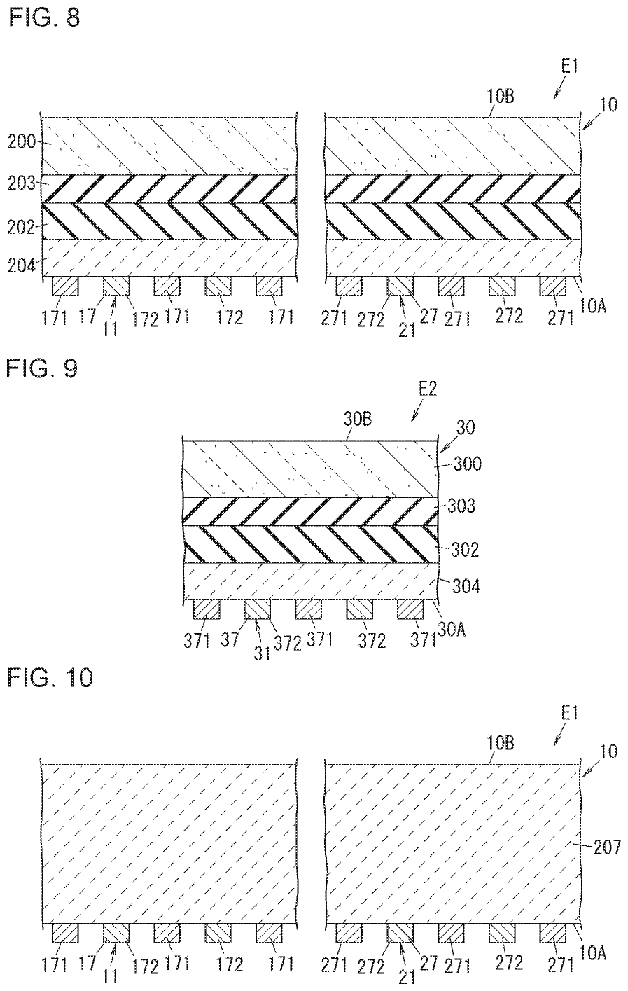

As illustrated in FIG. 8, for example, the substrate 10 in the first electronic component E1 may be configured to have a support substrate 200 and a high acoustic velocity film 203 that is disposed between the support substrate 200 and the low acoustic velocity film 202, instead of the high acoustic velocity member 201 (see FIG. 4). The high acoustic velocity film 203 is a film in which the acoustic velocity of bulk waves propagating through the high acoustic velocity film 203 is higher than the acoustic velocity of acoustic waves propagating through the piezoelectric layer 204. The high acoustic velocity film 203 constitutes a high acoustic velocity member. In addition, as illustrated in FIG. 9, for example, the third substrate 30 in the second electronic component E2 may be configured to have a support substrate 300 and a high acoustic velocity film 303 that is disposed between the support substrate 300 and the low acoustic velocity film 302, instead of the high acoustic velocity member 301 (see FIG. 5). The high acoustic velocity film 303 is a film in which the acoustic velocity of bulk waves propagating through the high acoustic velocity film 303 is higher than the acoustic velocity of acoustic waves propagating through the piezoelectric layer 304. The high acoustic velocity film 303 constitutes a high acoustic velocity member. The materials of the high acoustic velocity film 203 and the high acoustic velocity film 303 are, for example, silicon nitride, but may only be at least one kind of materials selected from the group consisting of, for example, diamond like carbon, aluminum nitride, silicon carbide, silicon nitride, silicon oxynitride, silicon, sapphire, lithium tantalate, lithium niobate, quartz, zirconia, cordierite, mullite, steatite, forsterite, magnesia, and diamond.

In addition, the first electronic component E1 may include a first close contact layer that is disposed between, for example, the low acoustic velocity film 202 and the piezoelectric layer 204. The first close contact layer includes, for example, a resin (epoxy resin and polyimide resin). The first electronic component E1 may also include a first dielectric film either between the low acoustic velocity film 202 and the piezoelectric layer 204, on the piezoelectric layer 204, or under the low acoustic velocity film 202. In addition, the second electronic component E2 may include, for example, a second close contact layer that is disposed between the low acoustic velocity film 302 and the piezoelectric layer 304. The second close contact layer includes, for example, a resin (epoxy resin and polyimide resin). The second electronic component E2 may also include a second dielectric film either between the low acoustic velocity film 302 and the piezoelectric layer 304, on the piezoelectric layer 304, or under the low acoustic velocity film 302. In addition, the first electronic component E1 may further include a first protective film that is provided on the piezoelectric layer 204 and that covers the plurality of first functional electrodes 11 and second functional electrodes 21. A material of the first protective film is, for example, silicon oxide. In addition, the second electronic component E2 may further include a second protective film that is provided on the piezoelectric layer 304 and covers the plurality of third functional electrodes 31. A material of the second protective film is silicon oxide, for example.

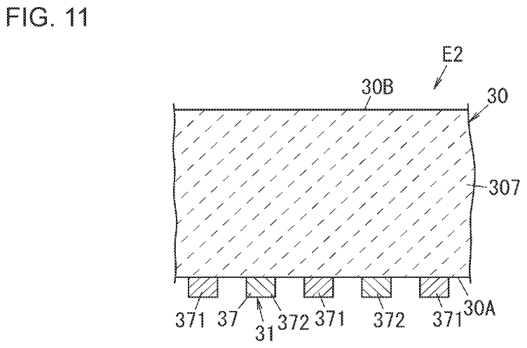

In addition, in the first electronic component E1, the first acoustic wave resonators 14 and the second antenna end resonator 24A may be, for example, surface acoustic wave (SAW) resonators as illustrated in FIG. 10. In this case, in the first electronic component E1, the substrate 10 may include a piezoelectric substrate 207 instead of the high acoustic velocity member 201 (see FIG. 4), the low acoustic velocity film 202 (see FIG. 4), and the piezoelectric layer 204 (see FIG. 4), as illustrated in FIG. 10. The piezoelectric substrate 207 is, for example, a lithium tantalate substrate or a lithium niobate substrate. In addition, in the second electronic component E2, the second acoustic wave resonators 24 may be, for example, SAW resonators as illustrated in FIG. 11. In this case, in the second electronic component E2, as illustrated in FIG. 11, the third substrate 30 may include a piezoelectric substrate 307, instead of the high acoustic velocity member 301 (see FIG. 5), the low acoustic velocity film 302 (see FIG. 5), and the piezoelectric layer 304 (see FIG. 5). The piezoelectric substrate 307 is, for example, a lithium tantalate substrate or a lithium niobate substrate.

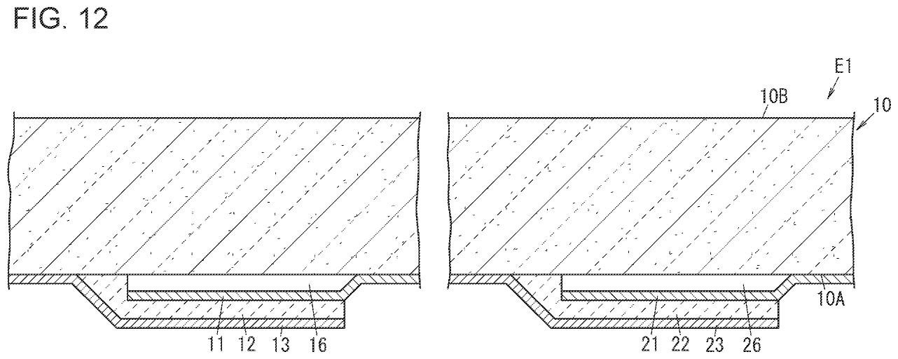

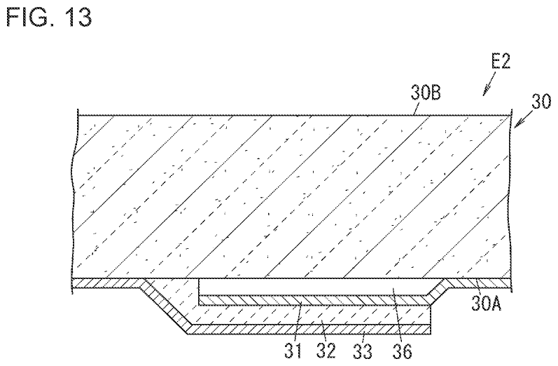

In addition, in the first electronic component E1, the first acoustic wave resonators 14 may be, for example, bulk acoustic wave (BAW) resonators as illustrated in FIG. 12. In this case, in the first electronic component E1, the first substrate (substrate 10) is a silicon substrate or a spinel substrate, and the BAW resonators that constitute the first acoustic wave resonators 14 include a lower electrode, which is the first functional electrode 11 provided on the side of the first principal surface 10A of the substrate 10, a piezoelectric film 12 on the lower electrode, and an upper electrode 13 on the piezoelectric film 12. A material of the piezoelectric film 22 is, for example, AlN, ScAlN, or lead zirconate titanate (PZT). The BAW resonators that constitute the first acoustic wave resonators 14 have a cavity 16 on the side opposite from the piezoelectric film 12 in the first functional electrode 11. The BAW resonators that constitute the first acoustic wave resonators 14 are film bulk acoustic resonators (FBARs), but are not limited thereto and may be solidly mounted resonators (SMRs). In addition, in the first electronic component E1, the second antenna end resonator 24A may be, for example, the BAW resonator as illustrated in FIG. 12. In this case, in the first electronic component E1, the second substrate (substrate 10) is a silicon substrate or a spinel substrate, and the BAW resonators that constitute the second antenna end resonator 24A include a lower electrode, which is the second functional electrode 21 provided on the side of the first principal surface 10A of the substrate 10, a piezoelectric film 22 on the lower electrode, and an upper electrode 23 on the piezoelectric film 22. A material of the piezoelectric film 12 is, for example, AlN, ScAlN, or PZT. The BAW resonators that constitute the second acoustic wave resonators 24 have a cavity 26 on the side opposite from the piezoelectric film 22 in the second functional electrode 21. In addition, in the second electronic component E2, the second acoustic wave resonators 24 may be, for example, the BAW resonator as illustrated in FIG. 13. In this case, in the second electronic component E2, the third substrate 30 is a silicon substrate or a spinel substrate, and the BAW resonators that constitute the second acoustic wave resonators 24 include a lower electrode, which is the third functional electrode 31 provided on the side of the first principal surface 30A of the third substrate 30, a piezoelectric film 32 on the lower electrode, and an upper electrode 33 on the piezoelectric film 32. A material of the piezoelectric film 32 is, for example, AlN, ScAlN, or PZT. The BAW resonators that constitute the third acoustic wave resonators 34 have a cavity 36 on the side opposite from the piezoelectric film 32 in the third functional electrode 31.

In the high frequency module 500, a combination of the first electronic component E1 and the second electronic component E2 can be changed appropriately. For example, The combination is not limited to the combination of the first electronic component E1 as illustrated in FIG. 4 and the second electronic component E2 as illustrated in FIG. 5, and may be a combination of the first electronic component E1 as illustrated in FIG. 4 and the second electronic component E2 in any one of the second electronic component E2 as illustrated in FIG. 9, the second electronic component E2 as illustrated in FIG. 11, and the second electronic component E2 as illustrated in FIG. 13.

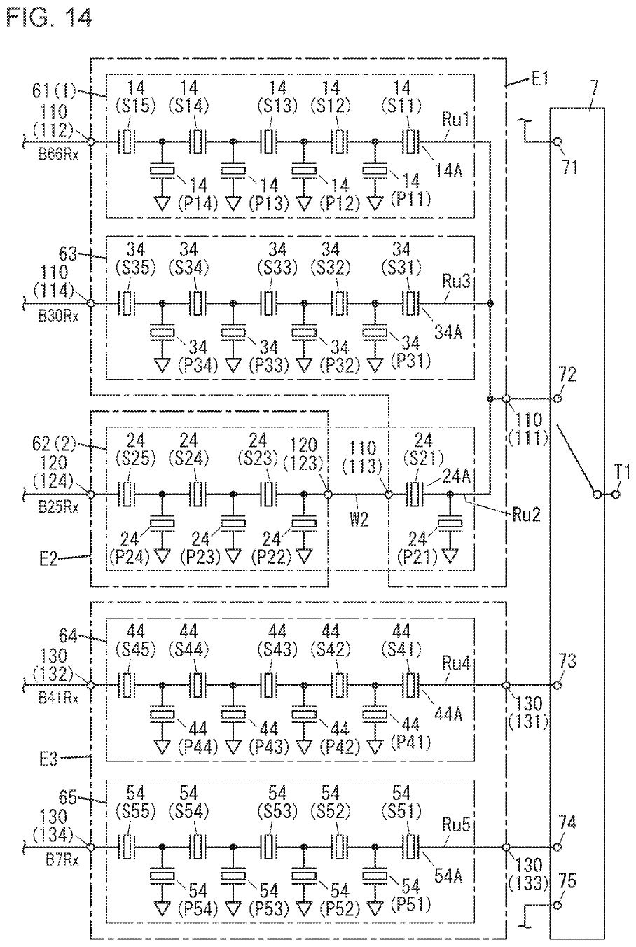

In addition, the second filter 2 may be a ladder filter in which the plurality of (eight, for example) second acoustic wave resonators 24 is connected as illustrated in FIG. 14. In the example of FIG. 14, the second antenna end resonator 24A (series arm resonator S21) and the parallel arm resonator P21 are connected to the switch 7 with no other second acoustic wave resonators 24 interposed. In addition, the first electronic component E1 includes the second antenna end resonator 24A (series arm resonator S21) of the plurality of second acoustic wave resonators 24 of the second filter 2 and the parallel arm resonator P21. In addition, the second electronic component E2 includes the three series arm resonators S23 to S25 and the three parallel arm resonator P22 to P24 among the plurality of the second acoustic wave resonators 24 of the second filter 2. In the second filter 2, the series arm resonator S21 and the series arm resonator S23 are connected with the wiring section W2 interposed.

### Embodiment 2

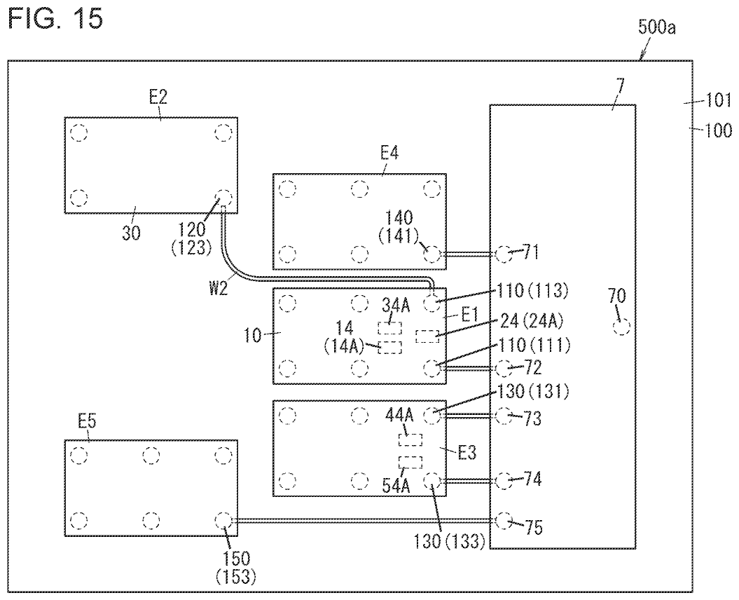

A description of a high frequency module 500a according to Embodiment 2 will be given with reference to FIG. 15. With respect to the high frequency module 500a according to Embodiment 2, components similar to those of the high frequency module 500 according to Embodiment 1 are denoted by the same reference numerals, and a description thereof will be omitted.

The high frequency module 500a according to Embodiment 2 differs from the high frequency module 500 according to Embodiment 1 in that the switch 7 is disposed on the first principal surface 101 of the mounting substrate 100.

As the switch 7 is disposed on the first principal surface 101 of the mounting substrate 100, the high frequency module 500a according to Embodiment 2 can further shorten the wiring length between the first electronic component E1 and the switch 7 as well as the wiring length between the second electronic component E2 and the switch 7. This allows the high frequency module 500a to further suppress the degradation of the characteristics.

### Embodiment 3

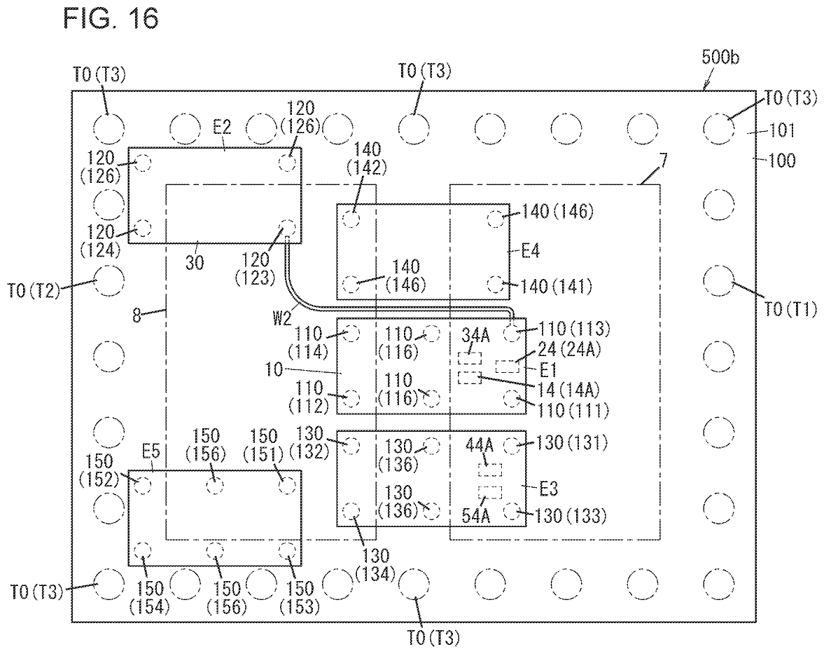

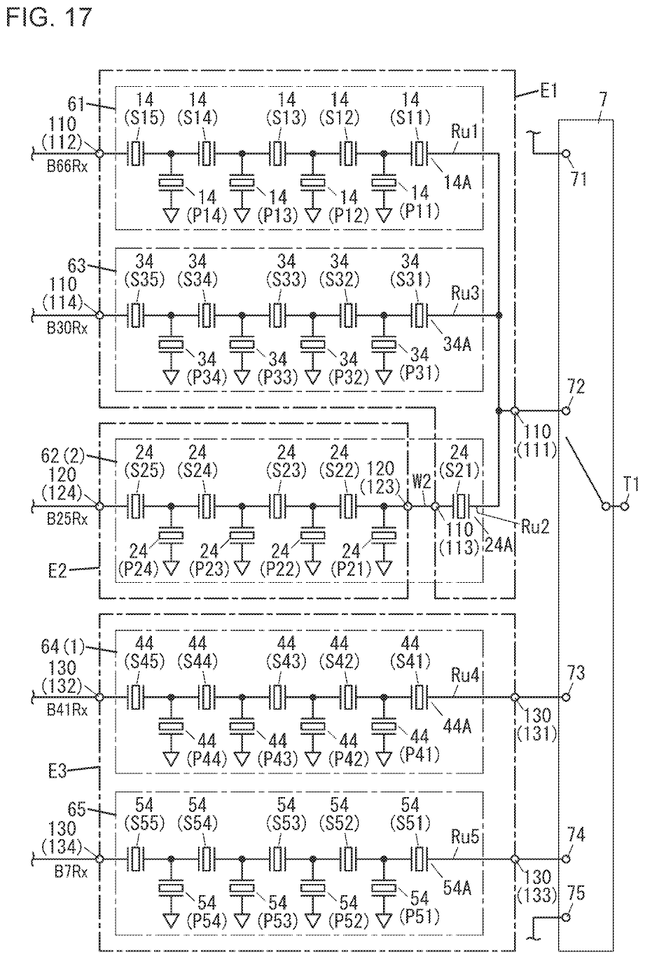

A description will be given of a high frequency module 500b according to Embodiment 3 with reference to FIGS. 16 and 17. With respect to the high frequency module 500b according to Embodiment 3, components similar to those of the high frequency module 500 according to Embodiment 1 are denoted by the same reference numerals, and a description thereof will be omitted.

The high frequency module 500b according to Embodiment 3 differs from the high frequency module 500 according to Embodiment 1 in that, as illustrated in FIG. 17, the filter 64 constitutes the first filter 1, the filter 62 constitutes the second filter 2, and the third electronic component E3 includes the first filter 1. In the high frequency module 500b according to Embodiment 3, the signal path Ru4 constitutes the first signal path Ru4, the plurality of acoustic wave resonators 44 of the filter 64 constitutes the plurality of first acoustic wave resonators 44, and the antenna end resonator 44A constitutes the first antenna end resonator 44A. In addition, in the high frequency module 500b according to Embodiment 3, the signal path Ru1 constitutes a fourth signal path Ru1, the plurality of acoustic wave resonators 14 of the filter 61 constitutes a plurality of fourth acoustic wave resonators 14, and the antenna end resonator 14A constitutes a fourth antenna end resonator 14A.

As illustrated in FIG. 16, in the high frequency module 500b, the first electronic component E1 including the second antenna end resonator 24A of the second filter 2 and the third electronic component E3 including the first filter 1 (filter 64) are adjacent to each other in plan view of the thickness direction D1 of the mounting substrate 100 (see FIG. 3). “The first electronic component E1 and the third electronic component E3 are adjacent to each other” means that in plan view from the thickness direction D1 of the mounting substrate 100, between the first electronic component E1 and the third electronic component E3, there is no other electronic component disposed on the first principal surface 101 of the mounting substrate 100 and that the first electronic component E1 and the third electronic component E3 are adjacent to each other.

The high frequency module 500b according to the third embodiment 3 includes the mounting substrate 100, the antenna terminal T1, the switch 7, and the plurality of filters 61 to 68 (see FIGS. 6 and 17). The mounting substrate 100 has the first principal surface 101 and the second principal surface 102 (see FIG. 3) that face each other. The antenna terminal T1 is disposed on the mounting substrate 100. The switch 7 is disposed on the mounting substrate 100. The switch 7 is connected to the antenna terminal T1. The plurality of filters 61 to 68 is connected to the antenna terminal T1 with the switch 7 interposed. The plurality of filters 61 to 68 includes the first filter 1 (filter 64) having the pass band of the first communication band (Band41, for example) and the second filter 2 (filter 62) having the pass band of the second communication band (Band25, for example) that is capable of simultaneous communication with the first communication band. The first filter 1 has the plurality of first acoustic wave resonators 44. The second filter 2 has the plurality of second acoustic wave resonators 24. The plurality of first acoustic wave resonators 44 includes the first antenna end resonator 44A. Among the plurality of first acoustic wave resonators 44, the first antenna end resonator 44A is a first acoustic wave resonator 44 that is provided on the first signal path Ru4 connected to the switch 7 and that is closest to the antenna terminal T1. The plurality of second acoustic wave resonators 24 includes the second antenna end resonator 24A. Among the plurality of second acoustic wave resonators 24, the second antenna end resonator 24A is the second acoustic wave resonator 24 that is provided on the second signal path Ru2 connected to the switch 7 and that is closest to the antenna terminal T1. The first electronic component E1 having the second antenna end resonator 24A of the second filter 2 is disposed on the first principal surface 101 of the mounting substrate 100. The second electronic component E2, which has at least one (eight, for example) second acoustic wave resonator 24 other than the second antenna end resonator 24A among the plurality of second acoustic wave resonators 24 of the second filter 2, is disposed on the first principal surface 101 of the mounting substrate 100. The third electronic component E3 having the first filter 1 is disposed on the first principal surface 101 of the mounting substrate 100. The first electronic component E1 and the third electronic component E3 are adjacent to each other in plan view from the thickness direction D1 of the mounting substrate 100. In plan view from the thickness direction D1 of the mounting substrate 100, the distance between the first electronic component E1 and the switch 7 as well as the distance between the third electronic component E3 and the switch 7 are shorter than the distance between the second electronic component E2 and the switch 7.

The high frequency module 500b according to Embodiment 3 can suppress the degradation of the characteristics during simultaneous communication. More particularly, the high frequency module 500b includes the plurality of filters 61 to 68, and with respect to the first filter 1 (filter 64) and the second filter 2 (filter 62) utilized in simultaneous communication, the second electronic component E2 having the second acoustic wave resonators 24 other than the second antenna end resonator 24A among the plurality of second acoustic wave resonators 24 of the second filter 2 is disposed at a position on the first principal surface 101 of the mounting substrate 100, the position being separated away from the first electronic component E1. The second acoustic wave resonators 24 other than the second antenna end resonator 24A among the plurality of second acoustic wave resonators 24 are less likely to affect the impedance of the frequency band of the first filter 1 than the second antenna end resonator 24A. In the high frequency module 500b, the first antenna end resonator 44A of the first filter 1 and the second antenna end resonator 24A of the second filter 2 can be disposed close to the switch 7. Therefore, in the high frequency module 500b, it is possible to reduce the loss or parasitic capacitance that occurs in the wiring section between the second antenna end resonator 24A of the second filter 2 and the switch 7. Therefore, the high frequency module 500b can suppress the impedance of the first filter 1 from decreasing in the frequency band of the second communication band. In a Smith chart, for example, the impedance of the first filter 1 can be set close to open (infinite) in the frequency band of the second communication band. As a result, in the high frequency module 500b, even if the first antenna end resonator 44A of the first filter 1 and the second antenna end resonator 24A of the second filter 2 are connected, the impedance of the first filter 1 hardly changes. Consequently, the high frequency module 500b can suppress the degradation of the characteristics during simultaneous communication.

### Embodiment 4

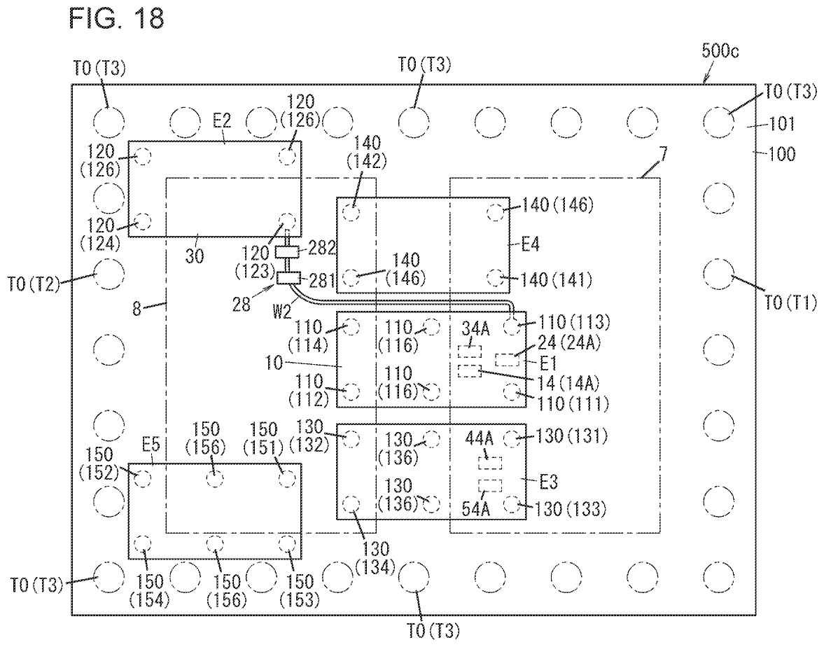

A description will be given of a high frequency module 500c according to Embodiment 4 with reference to FIG. 18. With respect to the high frequency module 500c according to Embodiment 4, components similar to those of the high frequency module 500 according to Embodiment 1 are denoted by the same reference numerals, and a description thereof will be omitted.

The high frequency module 500c according to Embodiment 4 differs from the high frequency module 500 according to Embodiment 1 in that the second filter 2 further includes a resonator 28. The resonator 28 is disposed in or on the mounting substrate 100. The resonator 28 is provided in the middle of the wiring section W2 that connects the connection terminal 113 of the first electronic component E1 with the connection terminal 123 of the second electronic component E2. In the second signal path Ru2 (see FIG. 7), the resonator 28 is connected between the second antenna end resonator 24A and the series arm resonator S22 (at least one second acoustic wave resonator 24 other than the second antenna end resonator 24A among the plurality of second acoustic wave resonators 24).

The resonator 28 is a series LC resonant circuit including an inductor 281 and a capacitor 282 connected in series to the inductor 281, but is not limited thereto and may be a parallel LC resonant circuit, for example. The inductor 281 is a chip inductor mounted on the first principal surface 101 of the mounting substrate 100, but is not limited thereto and may be, for example, an inner layer inductor including a conductor pattern part formed in or on the mounting substrate 100. The capacitor 282 is a chip capacitor mounted on the first principal surface 101 of the mounting substrate 100, but is not limited thereto and may be, for example, a capacitor that includes two conductor pattern parts formed in or on the mounting substrate 100. The resonator 28 may also be an integrated passive device (IPD) including an inductor and a capacitor.

As the second filter 2 further includes the resonator 28, the high frequency module 500c according to Embodiment 4 can improve the characteristics (for example, attenuation near the pass band) of the second filter 2 (see FIGS. 6 and 7).

### Embodiment 5

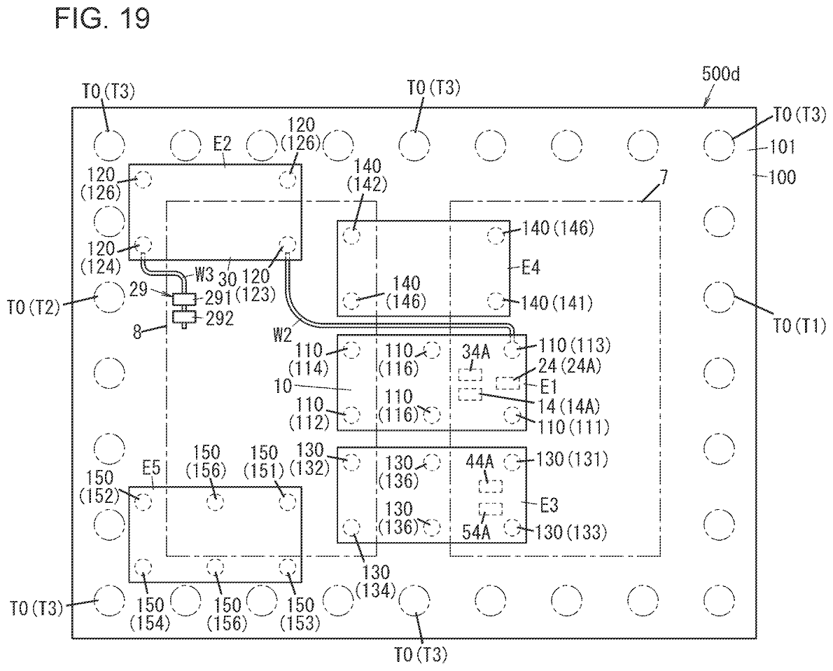

A description will be given of a high frequency module 500d according to Embodiment 5 with reference to FIG. 19. With respect to the high frequency module 500d according to Embodiment 5, components similar to those of the high frequency module 500 according to Embodiment 1 are denoted by the same reference numerals, and a description thereof will be omitted.

The high frequency module 500d according to Embodiment 5 differs from the high frequency module 500 according to Embodiment 1 in that the second filter 2 further includes a resonator 29. The resonator 29 is disposed in or on the mounting substrate 100. In the second signal path Ru2 (see FIG. 7), the resonator 29 is connected to the second acoustic wave resonator 24 that is farthest from the antenna terminal T1 among the plurality of second acoustic wave resonators 24. The resonator 29 is provided in the middle in a wiring section W3 (see FIG. 19) between the input/output terminal 124 and the low noise amplifier 82 (see FIG. 6).

The resonator 29 is a series LC resonant circuit including an inductor 291 and a capacitor 292 connected in series to the inductor 291, but is not limited thereto and may be a parallel LC resonant circuit, for example. The inductor 291 is a chip inductor mounted on the first principal surface 101 of the mounting substrate 100, but is not limited thereto and may be, for example, an inner layer inductor including the conductor pattern part formed in or on the mounting substrate 100. The capacitor 292 is a chip capacitor mounted on the first principal surface 101 of the mounting substrate 100, but is not limited thereto and may be, for example, a capacitor that includes two conductor pattern parts formed in or on the mounting substrate 100. The resonator 29 may also be an integrated passive device (IPD) including an inductor and a capacitor.

As the second filter 2 further includes the resonator 29, the high frequency module 500d according to Embodiment 5 can improve the characteristics (for example, attenuation near the pass band) of the second filter 2 (see FIGS. 6 and 7).

### Embodiment 6

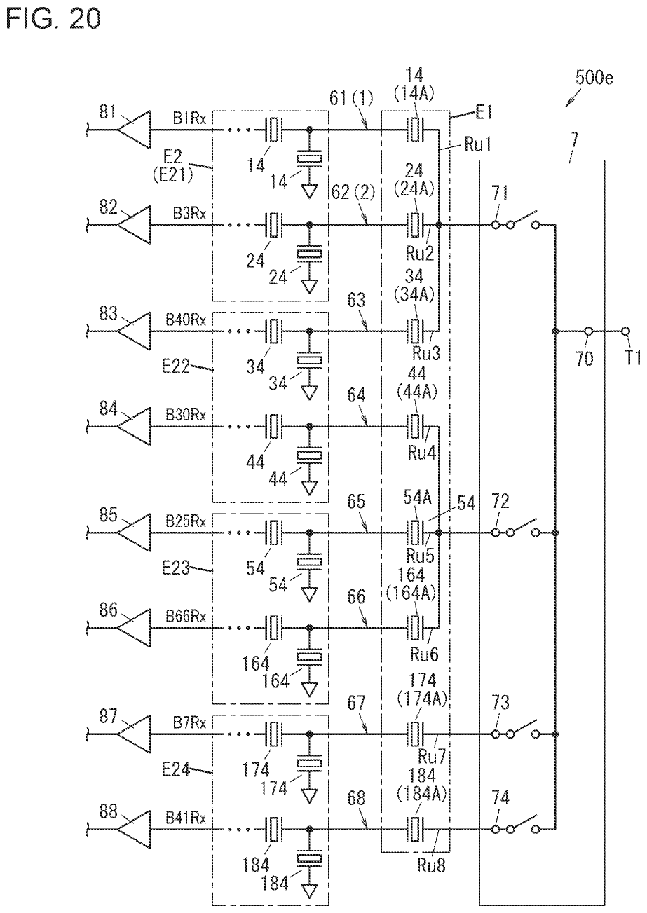

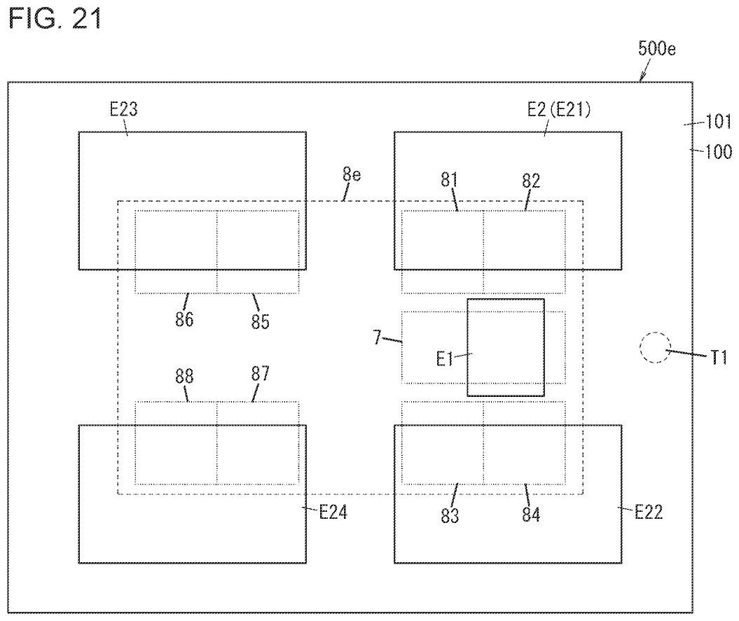

A description will be given of a high frequency module 500e according to Embodiment 6 with reference to FIGS. 20 and 21. With respect to the high frequency module 500e according to Embodiment 6, components similar to those of the high frequency module 500 according to Embodiment 1 are denoted by the same reference numerals, and a description thereof will be omitted.

In FIG. 20, to make it easier to understand that the pass band of the filter 61 corresponds to the reception band of Band1 of the 3GPP LTE standard, “B1Rx” is written to the left of the filter 61. Similarly, in FIG. 20, to make it easier to understand that the filter 62 corresponds to the reception band of Band3 of the 3GPP LTE standard, “B3Rx” is written to the left of the filter 62. Similarly, in FIG. 20, to make it easier to understand that the filter 63 corresponds to the reception band of Band40 of the 3GPP LTE standard, “B40Rx” is written to the left of the filter 63. Similarly, in FIG. 20, to make it easier to understand that the filter 64 corresponds to the reception band of Band30 of the 3GPP LTE standard, “B30Rx” is written to the left of the filter 64. Similarly, in FIG. 20, to make it easier to understand that the filter 65 corresponds to the reception band of Band25 of the 3GPP LTE standard, “B25Rx” is written to the left of the filter 65. Similarly, in FIG. 20, to make it easier to understand that the filter 66 corresponds to the reception band of Band66 of the 3GPP LTE standard, “B66Rx” is written to the left of the filter 66. Similarly, in FIG. 20, to make it easier to understand that the filter 67 corresponds to the reception band of Band1 of the 3GPP LTE standard, “B7Rx” is written to the left of the filter 67. Similarly, in FIG. 20, to make it easier to understand that the filter 68 corresponds to the reception band of Band41 of the 3GPP LTE standard, “B41Rx” is written to the left of the filter 68.

The filter 66 has a plurality of acoustic wave resonators 164 (hereinafter also referred to as sixth acoustic wave resonators 164). The plurality of sixth acoustic wave resonators 164 includes an antenna end resonator 164A (hereinafter also referred to as a sixth antenna end resonator 164A). Among the plurality of sixth acoustic wave resonators 164, the sixth antenna end resonator 164A is a sixth acoustic wave resonator 164 that is provided on a signal path Ru6 (hereinafter also referred to as a sixth signal path Ru6) connected to the switch 7 and that is closest to the antenna terminal T1. “The sixth acoustic wave resonator 164 that is closest to the antenna terminal T1” is the sixth acoustic wave resonator 164 connected to the antenna terminal T1 with no other sixth acoustic wave resonators 164 interposed. Therefore, “the sixth acoustic wave resonator 164 that is closest to the antenna terminal T1” is the sixth acoustic wave resonator 164 having the shortest physical distance between the sixth acoustic wave resonator 164 among the plurality of the sixth acoustic wave resonators 164 and the antenna terminal T1. The filter 66 is a ladder filter, for example.

The filter 67 has a plurality of acoustic wave resonators 174 (hereinafter also referred to as seventh acoustic wave resonators 174). The plurality of seventh acoustic wave resonators 174 includes an antenna end resonator 174A (hereinafter also referred to as a seventh antenna end resonator 174A). Among the plurality of seventh acoustic wave resonators 174, the seventh antenna end resonator 174A is a seventh acoustic wave resonator 174 that is provided on a signal path Ru7 (hereinafter also referred to as a seventh signal path Ru7) connected to the switch 7 and that is closest to the antenna terminal T1. “The seventh acoustic wave resonator 174 that is closest to the antenna terminal T1” is the seventh acoustic wave resonator 174 connected to the antenna terminal T1 with no other seventh acoustic wave resonators 174 interposed. Therefore, “the seventh acoustic wave resonator 174 that is closest to the antenna terminal T1” is the seventh acoustic wave resonator 174 having the shortest physical distance between the seventh acoustic wave resonator 174 among the plurality of the seventh acoustic wave resonators 174 and the antenna terminal T1. The filter 67 is a ladder filter, for example.

The filter 68 has a plurality of acoustic wave resonators 184 (hereinafter also referred to as eighth acoustic wave resonators 184). The plurality of eighth acoustic wave resonators 184 includes an antenna end resonator 184A (hereinafter also referred to as an eighth antenna end resonator 184A). Among the plurality of eighth acoustic wave resonators 184, the eighth antenna end resonator 184A is an eighth acoustic wave resonator 184 that is provided on a signal path Ru8 (hereinafter also referred to as an eighth signal path Ru8) connected to the switch 7 and that is closest to the antenna terminal T1. “The eighth acoustic wave resonator 184 that is closest to the antenna terminal T1” is the eighth acoustic wave resonator 184 connected to the antenna terminal T1 with no other eighth acoustic wave resonators 184 interposed. Therefore, “the eighth acoustic wave resonator 184 that is closest to the antenna terminal T1” is the eighth acoustic wave resonator 184 having the shortest physical distance between the eighth acoustic wave resonator 184 among the plurality of the eighth acoustic wave resonators 184 and the antenna terminal T1. The filter 68 is a ladder filter, for example. In the high frequency module 500e, a connecting point between the filter 61 (first filter 1), the filter 62 (second filter 2), and the filter 63 is connected to the selection terminal 71 of the switch 7. In addition, in the high frequency module 500e, a connecting point between the filter 64, the filter 65, and the filter 66 is connected to the selection terminal 72 of the switch 7. In addition, in the high frequency module 500e, the filter 67 is connected to the selection terminal 73 of the switch 7. In addition, in the high frequency module 500e, the filter 68 is connected to the selection terminal 74 of the switch 7.

In the high frequency module 500e, the first electronic component E1 includes the first antenna end resonator 14A, the second antenna end resonator 24A, the third antenna end resonator 34A, the fourth antenna end resonator 44A, the fifth antenna end resonator 54A, the sixth antenna end resonator 164A, the seventh antenna end resonator 174A, and the eighth antenna end resonator 184A.

In the high frequency module 500e, the second electronic component E2 (electronic component E21) includes the first acoustic wave resonator 14 other than the first antenna end resonator 14A among the plurality of first acoustic wave resonators 14 of the filter 61 (first filter) and the second acoustic wave resonator 24 other than the second antenna end resonator 24A of the plurality of second acoustic wave resonators 24 of the filter 62 (second filter 2). In addition, the high frequency module 500e further includes an electronic component E22, an electronic component E23, and an electronic component E24. The electronic component E22 includes the third acoustic wave resonators 34 other than the third antenna end resonator 34A among the plurality of third acoustic wave resonators 34 of the filter 63 and the fourth acoustic wave resonators 44 other than the fourth antenna end resonator 44A among the plurality of the fourth acoustic wave resonators 44 of the filter 64. The electronic component E23 includes the fifth acoustic wave resonators 54 other than the fifth antenna end resonator 54A among the plurality of fifth acoustic wave resonators 54 of the filter 65 and the sixth acoustic wave resonators 164 other than the sixth antenna end resonator 164A among the plurality of the sixth acoustic wave resonators 164 of the filter 66. The electronic component E24 includes the seventh acoustic wave resonators 174 other than the seventh antenna end resonator 174A among the plurality of seventh acoustic wave resonators 174 of the filter 67 and the eighth acoustic wave resonators 184 other than the eighth antenna end resonator 184A among the plurality of the eighth acoustic wave resonators 184 of the filter 68. To the electronic component E21 are connected the two low noise amplifiers 81 and 82 that correspond one-to-one to the two filters 61 and 62. To the electronic component E22 are connected the two low noise amplifiers 83 and 84 that correspond one-to-one to the two filters 63 and 64. To the electronic component E23 are connected the two low noise amplifiers 85 and 86 that correspond one-to-one to the two filters 65 and 66. To the electronic component E24 are connected the two low noise amplifiers 87 and 88 that correspond one-to-one to the two filters 67 and 68.

As illustrated in FIG. 21, the first electronic component E1, the second electronic component E2, and the three electronic components E22 to E24 are mounted on the first principal surface 101 of the mounting substrate 100.

In addition, the high frequency module 500e according to Embodiment 6 includes an IC chip 8e mounted on the second principal surface 102 (see FIG. 3) of the mounting substrate 100. The IC chip 8e includes the switch 7, the plurality of low noise amplifiers 81 to 88, and the second switch 9 (see FIG. 6).

In the high frequency module 500e, the first electronic component E1 and the switch 7 overlap in plan view from the thickness direction D1 (see FIG. 3) of the mounting substrate 100. Here, in the high frequency module 500e, a part of the first electronic component E1 overlaps a part of the switch 7, but the embodiment is not limited thereto, and, for example, the entire first electronic component E1 may overlap the part of the switch 7, or the entire first electronic component E1 may overlap the entire switch 7, or a part of the first electronic component E1 may overlap the entire switch 7.

In addition, in the high frequency module 500e, the second electronic component E2 and the two low noise amplifiers 81 and 82 overlap in plan view from the thickness direction D1 (see FIG. 3) of the mounting substrate 100. Here, in the high frequency module 500e, a part of the second electronic component E2 overlaps a part of each of the two low noise amplifiers 81 and 82, but the embodiment is not limited thereto, and, for example, the part of the second electronic component E2 may overlap all of each of the two low noise amplifiers 81 and 82. In addition, in the high frequency module 500e, the electronic component E22 and the two low noise amplifiers 83 and 84 overlap in plan view from the thickness direction D1 of the mounting substrate 100. Here, in the high frequency module 500e, a part of the electronic component E22 overlaps a part of each of the two low noise amplifiers 83 and 84, but the embodiment is not limited thereto and, for example, the part of the electronic component E22 may overlap all of each of the two low noise amplifiers 83 and 84. In addition, in the high frequency module 500e, the electronic component E23 and the two low noise amplifiers 85 and 86 overlap in plan view from the thickness direction D1 of the mounting substrate 100. Here, in the high frequency module 500e, a part of the electronic component E23 overlaps a part of each of the two low noise amplifiers 85 and 86, but the embodiment is not limited thereto and, for example, the part of the electronic component E23 may overlap all of each of the two low noise amplifiers 85 and 86. In addition, in the high frequency module 500e, the electronic component E24 and the two low noise amplifiers 87 and 88 overlap in plan view from the thickness direction D1 of the mounting substrate 100. Here, in the high frequency module 500e, a part of the electronic component E24 overlaps a part of each of the two low noise amplifiers 87 and 88, but the embodiment is not limited thereto and, for example, the part of the electronic component E24 may overlap all of each of the two low noise amplifiers 87 and 88.

The high frequency module 500e according to Embodiment 6 includes the mounting substrate 100, the antenna terminal T1, the switch 7, and the plurality of filters 61 to 68. The mounting substrate 100 has the first principal surface 101 and the second principal surface 102 that face each other. The antenna terminal T1 is disposed on the mounting substrate 100. The switch 7 is disposed on the mounting substrate 100. The switch 7 is connected to the antenna terminal T1. The plurality of filters 61 to 68 is connected to the antenna terminal T1 with the switch 7 interposed. The plurality of filters 61 to 68 includes the first filter 1 that has the pass band including the frequency band of the first communication band and the second filter 2 that has the pass band including the frequency band of the second communication band that is capable of simultaneous communication with the first communication band. The first filter 1 has the plurality of first acoustic wave resonators 14. The second filter 2 has the plurality of second acoustic wave resonators 24. The plurality of first acoustic wave resonators 14 includes the first antenna end resonator 14A. Among the plurality of first acoustic wave resonators 14, the first antenna end resonator 14A is the first acoustic wave resonator 14 that is provided on the first signal path Ru1 connected to the switch 7 and that is closest to the antenna terminal T1. The plurality of second acoustic wave resonators 24 includes the second antenna end resonator 24A. Among the plurality of second acoustic wave resonators 24, the second antenna end resonator 24A is the second acoustic wave resonator 24 that is provided on the second signal path Ru2 connected to the switch 7 and that is closest to the antenna terminal T1. The first electronic component E1 having the first antenna end resonator 14A of the first filter 1 and the second antenna end resonator 24A of the second filter 2 is disposed on the first principal surface 101 of the mounting substrate 100. The second electronic component E2 having at least one second acoustic wave resonator 24 other than the second antenna end resonator 24A among the plurality of second acoustic wave resonator 24 of the second filter 2 is disposed on the first principal surface 101 of the mounting substrate 100. In plan view of the thickness direction D1 of the mounting substrate 100, the distance between the first electronic component E1 and the switch 7 is shorter than the distance between the second electronic component E2 and the switch 7.

The high frequency module 500e according to Embodiment 6 can suppress the degradation of the characteristics during simultaneous communication. More particularly, the high frequency module 500e includes the plurality of filters 61 to 68, but with respect to the first filter 1 (filter 61) and the second filter 2 (filter 62) utilized in simultaneous communication, the first electronic component E1 having the first antenna end resonator 14A of the first filter 1 and the second antenna end resonator 24A of the second filter 2 is disposed on the first principal surface 101 of the mounting substrate 100. The second electronic component E2 including the at least one second acoustic wave resonators 24 other than the second antenna end resonator 24A among the plurality of second acoustic wave resonators 24 of the second filter 2 is disposed on the first principal surface 101 of the mounting substrate 100. The second acoustic wave resonators 24 other than the second antenna end resonator 24A among the plurality of second acoustic wave resonators 24 are less likely to affect the impedance of the frequency band of the first filter 1 than the second antenna end resonator 24A. In the high frequency module 500e, the first antenna end resonator 14A of the first filter 1 and the second antenna end resonator 24A of the second filter 2 can be disposed close to the switch 7. Therefore, in the high frequency module 500e, it is possible to reduce the loss or parasitic capacitance that occurs in the wiring section between the second antenna end resonator 24A of the second filter 2 and the switch 7. Therefore, the high frequency module 500e can suppress the impedance of the first filter 1 from decreasing in the frequency band of the second communication band. In a Smith chart, for example, the impedance of the first filter 1 can be set close to open (infinite) in the frequency band of the second communication band. As a result, in the high frequency module 500e, even if the first antenna end resonator 14A of the first filter 1 and the second antenna end resonator 24A of the second filter 2 are connected, the impedance of the first filter 1 hardly changes. Consequently, the high frequency module 500e can suppress the degradation of the characteristics during simultaneous communication.

### Embodiment 7

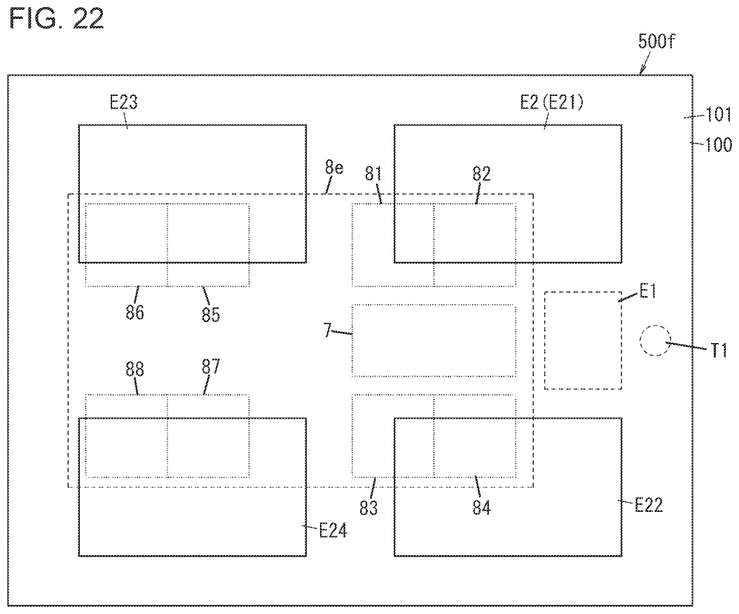

A description will be given of a high frequency module 500f according to Embodiment 7 with reference to FIG. 22. With respect to the high frequency module 500f according to Embodiment 7, components similar to those of the high frequency module 500e according to Embodiment 6 are denoted by the same reference numerals, and a description thereof will be omitted.

The high frequency module 500f according to Embodiment 7 differs from the high frequency module 500e according to Embodiment 6 in that the first electronic component E1 is disposed on the second principal surface 102 (see FIG. 3) of the mounting substrate 100.

In the high frequency module 500f, in plan view from the thickness direction D1 (see FIG. 3) of the mounting substrate 100, the first electronic component E1 and the switch 7 are adjacent to each other. “The first electronic component E1 and the switch 7 are adjacent to each other” means that in plan view from the thickness direction D1 of the mounting substrate 100, between the first electronic component E1 and the switch 7, there is no other electronic component disposed on the second principal surface 102 of the mounting substrate 100 and that the first electronic component E1 and the switch 7 are adjacent to each other. As the first electronic component E1 and the switch 7 are adjacent to each other, the high frequency module 500f according to Embodiment 7 can shorten the distance between the first electronic component E1 and the switch 7. This allows the high frequency module 500f according to Embodiment 7 to further suppress the degradation of the characteristics during simultaneous communication.

### Embodiment 8

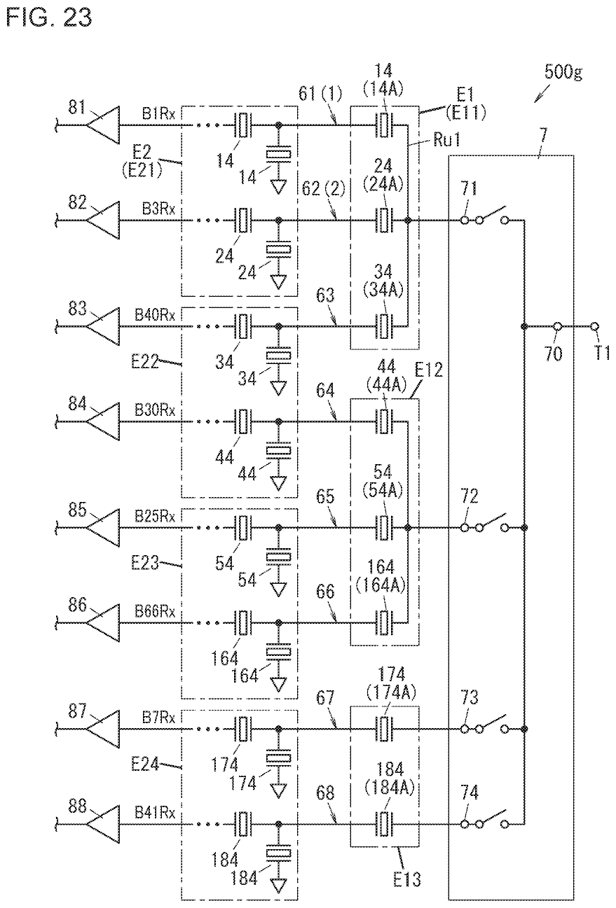

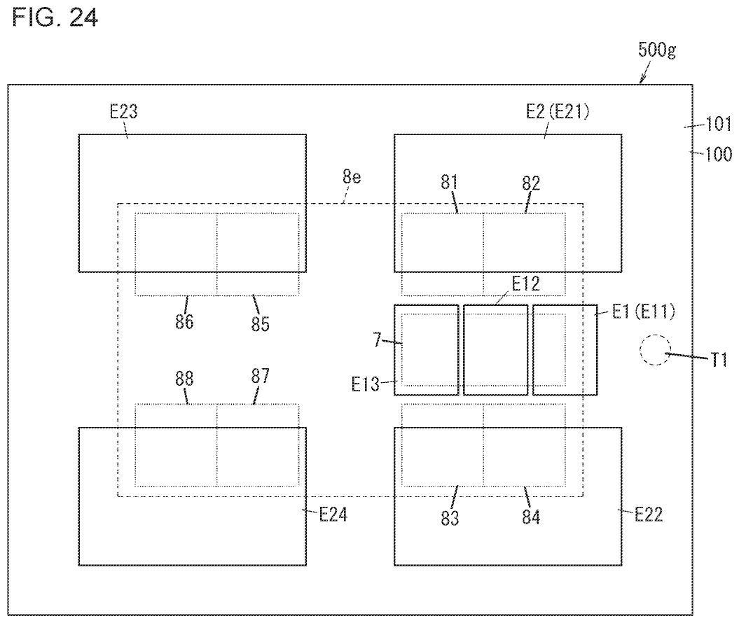

A description will be given of a high frequency module 500g according to Embodiment 8 with reference to FIGS. 23 and 24. With respect to the high frequency module 500g according to Embodiment 8, components similar to those of the high frequency module 500e according to Embodiment 6 are denoted by the same reference numerals, and a description thereof will be omitted.

The high frequency module 500g according to Embodiment 8 differs from the high frequency module 500e according to Embodiment 6 in that the first electronic component E1 includes only the first antenna end resonator 14A, the second antenna end resonator 24A, and the third antenna end resonator 34A among the plurality of antenna end resonators 14A, 24A, 34A, 44A, 54a, 164a, 174A, and 184A. In the high frequency module 500g, the electronic component E12 including the fourth antenna end resonator 44A, the fifth antenna end resonator 54A, and the sixth antenna end resonator 164A is mounted on the first principal surface 101 of the mounting substrate 100. In addition, in the high frequency module 500g, the electronic component E13 including the seventh antenna end resonator 174A and the eighth antenna end resonator 184A is mounted on the first principal surface 101 of the mounting substrate 100.

In the high frequency module 500g, in plan view from the thickness direction D1 (FIG. 3) of the mounting substrate 100, the first electronic component E1 and the electronic component E12 are adjacent to each other, and the electronic component E12 and the electronic component E13 are adjacent to each other. In addition, in the high frequency module 500g, the first electronic component E1, and electronic component E12, and the electronic component E13 are aligned in a straight line in plan view from the thickness direction D1 (FIG. 3) of the mounting substrate 100.

The high frequency module 500g according to Embodiment 8 allows the first electronic component E1, the electronic component E12, and the electronic component E13 to have different materials of the substrate 10, different configurations of the substrate 10, or the like. Thus, as compared with the high frequency module 500e according to Embodiment 6, a degree of freedom in designing each of the plurality of antenna end resonators 14A, 24A, 34A, 44A, 54A, 164A, 174A and 184A is increased.

### Embodiment 9

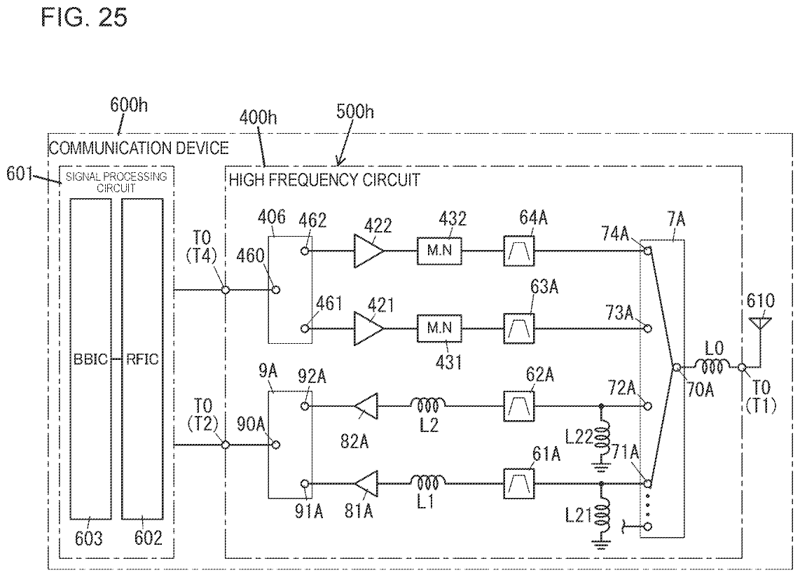

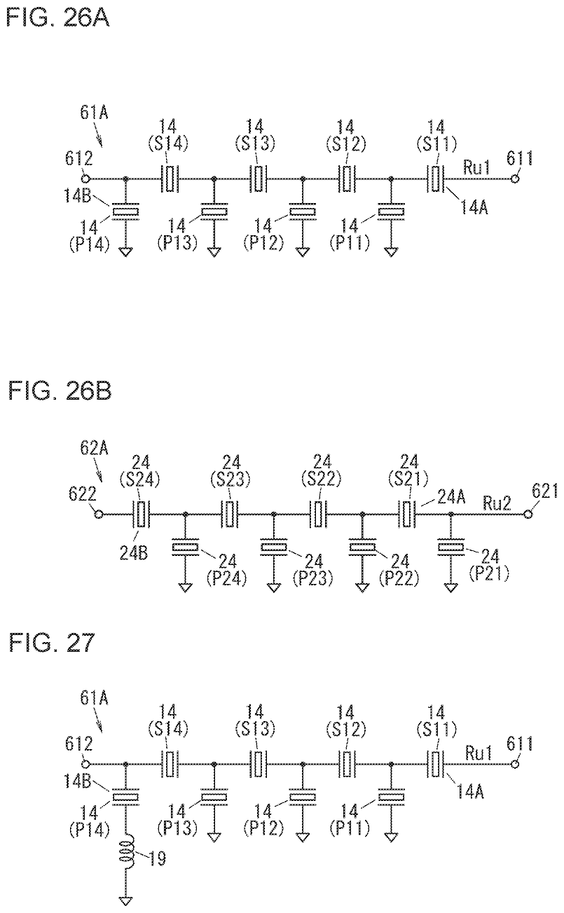

In the following, a description will be given of a high frequency circuit 400h, a high frequency module 500h, and a communication device 600h according to Embodiment 9 with reference to FIGS. 25, 26A, and 26B.

### (1) High Frequency Circuit

As illustrated in FIG. 25, the high frequency circuit 400h includes the plurality of external connection terminals TO (only three are illustrated in FIG. 25), a switch 7A (hereinafter also referred to as a first switch 7A), a plurality of (four, for example) filters 61A to 64A, and a plurality of (two, for example) low noise amplifiers 81A and 82A. The plurality of external connection terminals TO includes the antenna terminal T1, the signal output terminal T2, and a signal input terminal T4. In addition, the high frequency circuit 400h further includes an inductor L1 (hereinafter also referred to as a first inductor L1), an inductor L2 (hereinafter also referred to as a second inductor L2), a third inductor L21, a fourth inductor L22, a second switch 9A, a plurality of (two, for example) power amplifiers 421 and 422, a plurality of (two, for example) output matching circuits 431 and 432, and a third switch 406. The high frequency circuit 400h is used in the communication device 600h, for example. The communication device 600h is, for example, a cellular phone (such as a smartphone), but is not limited thereto and may be, for example, a wearable terminal (such as a smartwatch), or the like. The high frequency circuit 400h is, for example, a high frequency front end circuit that can support a 4G (fourth-generation mobile communication) standard or a 5G (fifth-generation mobile communication) standard, or the like. The 4G standard is, for example, 3GPP (registered trademark, Third Generation Partnership Project) LTE (registered trademark, Long Term Evolution) standard. The 5G standard is, for example, 5G NR (New Radio). The high frequency circuit 400h is, for example, a high frequency front end circuit that can support carrier aggregation and dual connectivity. Note that the high frequency circuit 400h may further include, for example, a controller that controls the plurality of power amplifiers 421 and 422 according to a control signal from the signal processing circuit 601 of the communication device 600h.

### (1.1) Antenna Terminal

The antenna terminal T1 is, for example, a terminal connected to the antenna 610 included in the communication device 600h.

### (1.2) Signal Output Terminal

The signal output terminal T2 is, for example, a terminal for outputting high frequency signals (reception signals) from the plurality of low noise amplifiers 81A and 82A to the external circuit (such as the signal processing circuit 601 of the communication device 600h).

### (1.3) Signal Input Terminal

The signal input terminal T4 is a terminal for inputting high frequency signals (transmission signals) from the external circuit (such as the signal processing circuit 601) to the high frequency circuit 400h.

### (1.4) First Switch

The first switch 7A is connected to the antenna terminal T1. More particularly, the first switch 7A is connected to the antenna terminal T1 with an impedance matching inductor L0 interposed, but is not limited thereto. The first switch 7A has a common terminal 70A connected to the antenna terminal T1 and a plurality of selection terminals that can be connected to the common terminal 70A. The plurality of selection terminals of the first switch 7A includes a first selection terminal 71A, a second selection terminal 72A, a third selection terminal 73A, and a fourth selection terminal 74A.

The first switch 7A is, for example, a switch that can connect one or more of the plurality of selection terminals to the common terminal 70A. Here, the first switch 7A is, for example, a switch integrated circuit (IC) capable of one-to-one connection and one-to-many connection. The first switch 7A is controlled by the signal processing circuit 601, for example. The first switch 7A switches a connection state between the common terminal 70A and the plurality of selection terminals, according to a control signal from the RF signal processing circuit 602 of the signal processing circuit 601.

### (1.5) Low Noise Amplifier

Each of the plurality of low noise amplifiers 81A and 82A has an input terminal and an output terminal. In the following, when the two low noise amplifiers 81A and 82B are individually described, they are referred to as a first low noise amplifier 81A and a second low noise amplifier 82A.

The first low noise amplifier 81A amplifies reception signals inputted to the input terminal and outputs the signals from the output terminal. The input terminal of the first low noise amplifier 81A is connected to the first filter 61A with the first impedance matching inductor L1 interposed, and is connected to the first selection terminal 71A of the first switch 7A with the first filter 61A interposed.

The second low noise amplifier 82A amplifies reception signals inputted to the input terminal and outputs the signals from the output terminal. The input terminal of the second low noise amplifier 82A is connected to the second filter 62A with the second impedance matching inductor L2 interposed, and is connected to the second selection terminal 72A of the first switch 7A with the second filter 62A interposed.

The output terminals of the plurality of low noise amplifiers 81A and 82A are connected to the signal output terminal T2 with the second switch 9A interposed. Therefore, the plurality of low noise amplifiers 81A and 82A is connected to the signal processing circuit 601 with the signal output terminal T2 interposed.

### (1.6) First Inductor

The first inductor L1 is connected between the first filter 61A and the first low noise amplifier 81A. The first inductor L1 is a circuit element of a first input matching circuit for achieving the impedance matching between the first filter 61A and the first low noise amplifier 81A. The first inductor L1 has a first end and a second end. The first end of the first inductor L1 is connected to the first filter 61A. The second end of the first inductor L1 is connected to the input terminal of the first low noise amplifier 81A.

### (1.7) Second Inductor

The second inductor L2 is connected between the second filter 62A and the second low noise amplifier 82A. The second inductor L2 is a circuit element of a second input matching circuit for achieving the impedance matching between the second filter 62A and the second low noise amplifier 82A. The second inductor L2 has a first end and a second end. The first end of the second inductor L2 is connected to the second filter 62A. The second end of the second inductor L2 is connected to the input terminal of the second low noise amplifier 82A.

### (1.8) Third Inductor

The third inductor L21 is connected between the ground and a path between the first filter 61A and the first switch 7A. The third inductor L21 is a circuit element of a first matching circuit for achieving the impedance matching between the first filter 61A and the first switch 7A.

### (1.9) Fourth Inductor

The fourth inductor L22 is connected between the ground and a path between the second filter 62A and the first switch 7A. The fourth inductor L22 is a circuit element of a second matching circuit for achieving the impedance matching between the second filter 62A and the first switch 7A.

### (1.10) Second Switch

The second switch 9A has a common terminal 90A and a plurality of (two in the illustrated example) selection terminals 91A and 92A. The common terminal 90A is connected to the signal output terminal T2. The selection terminal 91A is connected to the output terminal of the first low noise amplifier 81A. The selection terminal 92A is connected to the output terminal of the second low noise amplifier 82A.

The second switch 9A is, for example, a switch that can connect one or more of the plurality of selection terminals 91A and 92A to the common terminal 90A. Here, the second switch 9A is, for example, a switch integrated circuit (IC) capable of one-to-one connection and one-to-many connection.

The second switch 9A is controlled by the signal processing circuit 601, for example. The second switch 9A switches a connection state between the common terminal 90A and the plurality of selection terminals 91A and 92A, according to a control signal from the RF signal processing circuit 602 of the signal processing circuit 601.

### (1.11) Power Amplifier

Each of the plurality of power amplifiers 421 and 422 has an input terminal and an output terminal. In the following, when the two power amplifiers 421 and 422 are individually described, they are referred to as a first power amplifier 421 and a second power amplifier 422.

The first power amplifier 421 power-amplifies the transmission signals inputted to the input terminal and outputs the signals from the output terminal. The input terminal of the first power amplifier 421 is connected to the signal input terminal T4 with the third switch 406 interposed. The input terminal of the first power amplifier 421 is connected to the signal processing circuit 601, for example, with the signal input terminal T4 interposed. The output terminal of the first power amplifier 421 is connected to the input terminal of a third filter 63A with the output matching circuit 431 interposed.

The second power amplifier 422 power-amplifies the transmission signals inputted to the input terminal and outputs the signals from the output terminal. The input terminal of the second power amplifier 422 is connected to the signal input terminal T4 with the third switch 406 interposed. The input terminal of the second power amplifier 422 is connected to the signal processing circuit 601, for example, with the signal input terminal T4 interposed. The output terminal of the second power amplifier 422 is connected to the input terminal of the fourth filter 64A with the output matching circuit 432 interposed.

### (1.12) Output Matching Circuit

In the following, when the two output matching circuits 431 and 432 are individually described, they are referred to as a first output matching circuit 431 and a second output matching circuit 432.

The first output matching circuit 431 is connected between the output terminal of the first power amplifier 421 and the input terminal of the third filter 63A. The first output matching circuit 431 is a circuit for achieving the impedance matching between the first power amplifier 421 and the third filter 63A and includes, for example, a plurality of inductors and a plurality of capacitors.

The second output matching circuit 432 is connected between the output terminal of the second power amplifier 422 and the input terminal of the fourth filter 64A. The second output matching circuit 432 is a circuit for achieving the impedance matching between the second power amplifier 422 and the fourth filter 64A and includes, for example, a plurality of inductors and a plurality of capacitors.

### (1.13) Third Switch

The third switch 406 has a common terminal 460 and a plurality of (two in the illustrated example) selection terminals 461 and 462. The common terminal 460 is connected to the signal input terminal T4. The selection terminal 461 is connected to the input terminal of the first power amplifier 421. The selection terminal 462 is connected to the input terminal of the second power amplifier 422.

The third switch 406 is, for example, a switch that can connect one or more of the plurality of selection terminals 461 and 462 to the common terminal 460. Here, the third switch 406 is, for example, a switch integrated circuit (IC) capable of one-to-one connection and one-to-many connection.

The third switch 406 is controlled by the signal processing circuit 601, for example. The third switch 406 switches a connection state between the common terminal 460 and the plurality of selection terminals 461 and 462, according to a control signal from the RF signal processing circuit 602 of the signal processing circuit 601.

### (1.14) Filter

The plurality of filters 61A to 64A is connected to the antenna terminal T1 with first switch 7A interposed. The plurality of filters 61A to 64A includes the first filter 61A, the second filter 62A, the third filter 63A, and the fourth filter 64A.

The first filter 61A is connected between the first selection terminal 71A and the first low noise amplifier 81A. The first filter 61A is a first receiving filter that has a pass band including the frequency band of the first communication band. The second filter 62A is connected between the second selection terminal 72A and the second low noise amplifier 82A. The second filter 62A is a second receiving filter that has a pass band of the second communication band. The third filter 63A is connected between the third selection terminal 73A and the first power amplifier 421. The third filter 63A is a first transmitting filter that has a pass band including the frequency band of the first communication band. The fourth filter 64A is connected between the fourth selection terminal 74A and the second power amplifier 422. The fourth filter 64A is a second transmitting filter that has a pass band including the frequency band of the second communication band.

The first communication band is a first time division duplex (TDD) communication band, and the second communication band is a second TDD communication band in a frequency band higher than the first communication band. The second communication band and the first communication band are included in a combination of communication bands capable of simultaneous communication. The “capable of simultaneous communication” means that at least one of simultaneous reception, simultaneous transmission, or simultaneous transmission and reception is possible. In the high frequency circuit 400h, a combination of the first communication band and the second communication band is a combination in which simultaneous reception is performed in the high frequency circuit 400h. For example, TDD allows the high frequency circuit 400h to realize simultaneous reception of reception signals in the frequency band of the first communication band and the reception signals in the frequency band of the second communication band. The combination of the first communication band and the second communication band capable of simultaneous communication is included in, for example, a combination of communication bands applicable to communications by ENDC (Evolved-Universal Terrestrial Radio Access New Radio Dual Connectivity) specified by the 3GPP (registered trademark, Third Generation Partnership Project)—Rel17 standard or a combination of communication bands applicable to communications by carrier aggregation specified by the 3GPP (registered trademark, Third Generation Partnership Project)—Rel17 standard. The first communication band is, for example, n40 of the 5G NR standard. In this case, the frequency band of the first communication band is 2300 to 2400 MHz. The frequency band of n40 of the 5G NR standard is the same as the frequency band of Band40 of the 3GPP LTE standard. In addition, the second communication band is, for example, n41 of the 5G NR standard. In this case, the frequency band of the second communication band is 2496 to 2690 MHz. Note that the frequency band of n41 of the 5G NR standard is the same as the frequency band of Band41 of the 3GPP LTE standard.

### (1.14.1) First Filter

As illustrated in FIG. 26A, the first filter 61A has a first input terminal 611 and a first output terminal 612. In the first filter 61A, the first input terminal 611 is connected to the first selection terminal 71A of the first switch 7A (see FIG. 25), and the first output terminal 612 is connected to the first low noise amplifier 81A (see FIG. 25) with the first inductor L1 (see FIG. 25) interposed. The first filter 61A has the plurality of (eight, for example) first acoustic wave resonators 14. The first filter 61A is, for example, a ladder filter and includes a plurality of (four, for example) first series arm resonators S11 to S14 and a plurality of (four, for example) first parallel arm resonators P11 to P14. The first filter 61A has the first input terminal 611 and the first output terminal 612. In the first filter 61A, the first input terminal 611 is connected to the first selection terminal 71A of the first switch 7A (see FIG. 25), and the first output terminal 612 is connected to the first low noise amplifier 81A (see FIG. 25) with the first inductor L1 (see FIG. 25) interposed. The four first series arm resonators S11 to S14 are provided on the first signal path Ru1 connected to the first switch 7A. The four first parallel arm resonators P11 to P14 are provided between the first signal path Ru1 and the ground. The four first series arm resonators S11 to S14 are connected in series on the first signal path Ru1. In the first filter 61A, in the first signal path Ru1, the four first series arm resonators S11 to S14 are arranged, from the side of the first switch 7A, in the order of the first series arm resonator S11, the first series arm resonator S12, the first series arm resonator S13, and the first h series arm resonator S14. The first parallel arm resonator P11 is connected between the ground and a section between the two first series arm resonators S11 and S12 in the first signal path Ru1. The first parallel arm resonator P12 is connected between the ground and a section between the two first series arm resonators S12 and S13 in the first signal path Ru1. The first parallel arm resonator P13 is connected between the ground and a section between the two first series arm resonators S13 and S14 in the first signal path Ru1. The first parallel arm resonator P14 is connected between the ground and a section between the first series arm resonator S14 and the first output terminal 612 in the first signal path Ru1.

Each of the plurality of first series arm resonators S11 to S14 and the plurality of first parallel arm resonators P11 to P14 is, for example, a surface acoustic wave (SAW) resonator including an interdigital transducer (IDT) electrode.

In the first filter 61A, the plurality of first acoustic wave resonators 14 includes the first antenna end resonator 14A. Among the plurality of first acoustic wave resonators 14, the first antenna end resonator 14A is the first acoustic wave resonator 14 that is provided on the first signal path Ru1 and that is closest to the antenna terminal T1. The “first acoustic wave resonator 14 that is closest to the antenna terminal T1” is the first acoustic wave resonator 14 that is connected to the antenna terminal T1 with no other first acoustic wave resonators 14 interposed. Therefore, the “first acoustic wave resonator 14 that is closest to the antenna terminal T1” is the first acoustic wave resonator 14 having the shortest physical distance between the first acoustic wave resonator 14 among the plurality of first acoustic wave resonators 14 and the antenna terminal T1. In the first filter 61A, the first series arm resonator S11 that is closest to the first switch 7A among the four first series arm resonators S11 to S14 is the first antenna end resonator 14A.

In addition, in the first filter 61A, the plurality of first acoustic wave resonators 14 includes a first acoustic wave resonator 14B that is farthest from the antenna terminal T1. The “first acoustic wave resonator 14B that is farthest from the antenna terminal T1” is the first acoustic wave resonator 14 that is connected to the first output terminal 612 with no other first acoustic wave resonators 14 interposed and that is not connected to other first acoustic wave resonators 14 in a path to the first output terminal 612. In the first filter 61A, the first acoustic wave resonator 14B that is farthest from the antenna terminal T1 is one of the plurality of first parallel arm resonators P11 to P14 (first parallel arm resonator P14).

### (1.14.2) Second Filter

As illustrated in FIG. 26B, the second filter 62A has a second input terminal 621 and a second output terminal 622. In the second filter 62A, the second input terminal 621 is connected to the second selection terminal 72A of the first switch 7A (see FIG. 25), and the second output terminal 622 is connected to the second low noise amplifier 82A (see FIG. 25) with the second inductor L2 (see FIG. 25) interposed. The second filter 62A has the plurality of (eight, for example) second acoustic wave resonators 24. The second filter 62A is, for example, a ladder filter and includes a plurality of (four, for example) second series arm resonators S21 to S24 and a plurality of (four, for example) second parallel arm resonators P21 to P24. The four first series arm resonators S11 to S14 are provided on the second signal path Ru2 connected to the first switch 7A. The four second parallel arm resonators P21 to P24 are provided between the second signal path Ru2 and the ground. The four second series arm resonators S21 to S24 are connected in series on the second signal path Ru2. In the second filter 62A, on the second signal path Ru2, the four second series arm resonators S21 to S24 are arranged, from the side of the first switch 7A, in the order of the second series arm resonator S21, the second series arm resonator S22, the second series arm resonator S23, and the second series arm resonator S24. The second parallel arm resonator P21 is connected between the ground and a section between the input terminal 621 and the second series arm resonator S21 in the second signal path Ru2. The second parallel arm resonator P22 is connected between the ground and a section between the two second series arm resonators S21 and S21 in the second signal path Ru2. The second parallel arm resonator P23 is connected between the ground and a section between the two second series arm resonators S22 and S23 in the second signal path Ru2. The second parallel arm resonator P24 is connected between the ground and a section between the two second series arm resonator S23 and S24 in the second signal path Ru2.

Each of the plurality of second series arm resonators S21 to S24 and the plurality of second parallel arm resonators P21 to P24 is, for example, a SAW resonator including an interdigital transducer (IDT) electrode.

In the second filter 62A, the plurality of second acoustic wave resonators 24 includes the second antenna end resonator 24A. Among the plurality of second acoustic wave resonators 24, the second antenna end resonator 24A is the second acoustic wave resonator 24 that is provided on the second signal path Ru2 and that is closest to the antenna terminal T1. The “second acoustic wave resonator 24 that is closest to the antenna terminal T1” is the second acoustic wave resonator 24 that is connected to the antenna terminal T1 with no other second acoustic wave resonators 24 interposed. Therefore, the “second acoustic wave resonator 24 that is closest to the antenna terminal T1” is the second acoustic wave resonator 24 having the shortest physical distance between the second acoustic wave resonator 24 among the plurality of second acoustic wave resonators 24 and the antenna terminal T1.

In addition, in the second filter 62A, the plurality of second acoustic wave resonators 24 includes a second acoustic wave resonator 24B that is farthest from the antenna terminal T1. The “second acoustic wave resonator 24B that is farthest from the antenna terminal T1” is the second acoustic wave resonator 24 that is connected to the second output terminal 622 with no other second acoustic wave resonators 24 interposed and that is not connected to other second acoustic wave resonators 24 in a path to the second output terminal 622. In the second filter 62A, the second acoustic wave resonator 24 that is farthest from the antenna terminal T1 is one of the plurality of second series arm resonators S21 to S24 (second series arm resonator S24).

### (2) Operation of High Frequency Circuit

The high frequency circuit 400h is configured to amplify transmission signals (high frequency signals) inputted from the signal processing circuit 601 and output the signals to the antenna 610, for example. The high frequency circuit 400h is also configured to amplify reception signals (high frequency signals) inputted from the antenna 610 and output the signals to the signal processing circuit 601. The signal processing circuit 601 is not a component of the high frequency circuit 400h but a component of the communication device 600h including the high frequency circuit 400h. The high frequency circuit 400h is controlled by, for example, the signal processing circuit 601 included in the communication device 600h.

When the high frequency circuit 400h receives a reception signal in the frequency band of the first communication band using a TDD communication method, the common terminal 70A of the first switch 7A is connected to the first selection terminal 71A. In addition, when the high frequency circuit 400h receives a reception signal in the frequency band of the second communication band using the TDD communication method, the common terminal 70A of the first switch 7A is connected to the second selection terminal 72A. Furthermore, when the high frequency circuit 400h transmits a transmission signal in the frequency band of the first communication band using the TDD communication method, the common terminal 70A of the first switch 7A is connected to the third selection terminal 73A. In addition, when the high frequency circuit 400h transmits a transmission signal in the frequency band of the second communication band using the TDD communication method, the common terminal 70A of the first switch 7A is connected to the fourth selection terminal 74A.

### (3) Effects

The high frequency circuit 400h according to Embodiment 9 includes the antenna terminal T1, the switch 7A, the first filter 61A (hereinafter also referred to a first receiving filter 61A), the second filter 62A (hereinafter also referred to as a second receiving filter 62A), the third filter 63A (hereinafter also referred to as a first transmitting filter 63A), the fourth filter 64A (hereinafter also referred to as the second transmitting filter 64A), the first low noise amplifier 81A, and the second low noise amplifier 82A. The switch 7A has the common terminal 70A connected to the antenna terminal T1, and the first selection terminal 71A, the second selection terminal 72A, the third selection terminal 73A, and the fourth selection terminal 74A that are connectable to the common terminal 70A. The first receiving filter 61A is connected to the first selection terminal 71A and has a pass band including a frequency band of a first TDD communication band. The second receiving filter 62A is connected to the second selection terminal 72A and has a pass band including the frequency band of the second TDD communication band that is capable of simultaneous communication with the first communication band. The first transmitting filter 63A is connected to the third selection terminal 73A and has a pass band including the frequency band of the first communication band. The second transmitting filter 64A is connected to the fourth selection terminal 74A and has a pass band including the frequency band of the second communication band. The first low noise amplifier 81A is connected to the first receiving filter 61A. The second low noise amplifier 82A is connected to the second receiving filter 62A. The frequency band of the second communication band is on the higher frequency side than the frequency band of the first communication band. The first receiving filter 61A has the plurality of first acoustic wave resonators 14. The second receiving filter 62A has the plurality of second acoustic wave resonators 24. In the first receiving filter 61A, the plurality of first acoustic wave resonators 14 includes the plurality of first series arm resonators S11 to S14 and the plurality of first parallel arm resonators P11 to P14. In the first receiving filter 61A, the first acoustic wave resonator 14B that is farthest from the antenna terminal T1 among the plurality of first acoustic wave resonators 14 is one of the plurality of first parallel arm resonators P11 to P14 (first parallel arm resonator P14). In the second receiving filter 62A, the plurality of second acoustic wave resonators 24 includes the plurality of second series arm resonators S21 to S24 and the plurality of second parallel arm resonators P21 to P24. In the second receiving filter 62A, the second acoustic wave resonator 24B that is farthest from the antenna terminal T1 among the plurality of second acoustic wave resonators 24 is one of the plurality of second series arm resonators S21 to S24 (first series arm resonator S24).

According to the high frequency circuit 400h according to Embodiment 9, it is possible to suppress the degradation of the characteristics during simultaneous communication. More particularly, in the high frequency circuit 400h according to Embodiment 9, it is possible to improve the attenuation characteristics of the frequency band of the second communication band in the first receiving filter 61A and the attenuation characteristics of the frequency band of the first communication band in the second receiving filter 62A, while reducing the loss in each of the first receiving filter 61A and the second receiving filter 62A. Incidentally, in a high frequency circuit, a transmitting and receiving filter that has a function of a transmitting filter and a function of a receiving filter may be used, as a filter that has a pass band including the frequency band of the TDD communication band. In contrast, a high frequency circuit is considered that includes a TDD transmitting filter and a TDD receiving filter, separate from the TDD transmitting filter, for each of two TDD communication bands, in order to place emphasis on the characteristics of each of the transmitting filter and the receiving filter. In this case, in the high frequency circuit, with respect to the transmitting filter, emphasis is placed on, for example, the attenuation characteristics, and, with respect to the receiving filter, emphasis is placed on, for example, the reduction of the loss in the receiving filter to reduce the noise in the reception signals entering the RF signal processing circuit from the high frequency circuit. However, in general, there is a trade-off relationship between reducing the loss and improving the attenuation characteristics, and it may be difficult to ensure attenuation when an attempt is made to reduce the loss. On the other hand, the high frequency circuit 400h according to Embodiment 9 not only includes the first receiving filter 61A and the first transmitting filter 63A, but also includes the second receiving filter 62A and the second transmitting filter 64A. Moreover, in the high frequency circuit 400h according to Embodiment 9, the first acoustic wave resonator 14B that is farthest from the antenna terminal T1 among the plurality of first acoustic wave resonators 14 of the first receiving filter 61A is the first parallel arm resonator P14. As a result, the impedance on the side of the output terminal 612 in the frequency band of the second communication band of the first receiving filter 61A will have a large mismatch with a gain matching point of the first receiving filter 61A and the first low noise amplifier 81A. As such, in the high frequency circuit 400h, the attenuation characteristics in the frequency band of the second communication band is improved in the first receiving filter 61A. Furthermore, in the high frequency circuit 400h, the second acoustic wave resonator 24B that is farthest from the antenna terminal T1 among the plurality of second acoustic wave resonators 24 of the second receiving filter 62A is the series arm resonator S24. As a result, in the high frequency circuit 400h, the impedance on the side of the output terminal 612 in the frequency band of the second communication band of the first receiving filter 61A will have a large mismatch with a gain matching point of the second receiving filter 62A and the second low noise amplifier 82A. As such, in the high frequency circuit 400h, the attenuation characteristics in the frequency band of the first communication band is improved in the second receiving filter 62A. With the above, in the high frequency circuit 400h, it is possible to improve the attenuation characteristics of the frequency band of the second communication band in the first receiving filter 61A and the attenuation characteristics of the frequency band of the first communication band in the second receiving filter 62A, while reducing the loss in each of the first receiving filter 61A and the second receiving filter 62A. Therefore, the high frequency circuit 400h can improve the isolation between the first receiving filter 61A and the second receiving filter 62A.

In addition, the high frequency circuit 400h according to Embodiment 9 further includes the first inductor L1 connected between the first receiving filter 61A and the first low noise amplifier 81A. This allows the high frequency circuit 400h to improve the attenuation characteristics of the first receiving filter 61A in a configuration in which only one first inductor L1 is adopted for the impedance matching between the first receiving filter 61A and the first low noise amplifier 81A. In addition, the high frequency circuit 400h according to Embodiment 9 further includes the second inductor L2 connected between the second receiving filter 62A and the second low noise amplifier 82A. This allows the high frequency circuit 400h to improve the attenuation characteristics of the second receiving filter 62A in a configuration in which only one second inductor L2 is adopted for the impedance matching between the second receiving filter 62A and the second low noise amplifier 82A.

### (4) Communication Device

The communication device 600h according to Embodiment 9 includes the high frequency circuit 400h and the signal processing circuit 601. The high frequency circuit 400h is connected to the signal processing circuit 601. This allows the communication device 600h according to Embodiment 9 to suppress the degradation of the characteristics during simultaneous communication.

The signal processing circuit 601 includes, for example, the RF signal processing circuit 602 and the baseband signal processing circuit 603. The RF signal processing circuit 602 is, for example, a radio frequency integrated circuit (RFIC) and performs signal processing for high frequency signals. The RF signal processing circuit 602 performs, for example, signal processing such as up-conversion on high frequency signals (transmission signals) outputted from the baseband signal processing circuit 603 and outputs the signal-processed high frequency signals. The RF signal processing circuit 602 also performs, for example, signal processing such as down-conversion on high frequency signals (reception signals) outputted from the high frequency circuit 400h and outputs the signal-processed high frequency signals to the baseband signal processing circuit 603. The baseband signal processing circuit 603 is, for example, a baseband integrated circuit (BBIC). The baseband signal processing circuit 603 generates an I-phase signal and a Q-phase signal from a baseband signal. The baseband signal is, for example, an audio signal, an image signal, or the like, inputted from the outside. The baseband signal processing circuit 603 performs IQ modulation processing by synthesizing the I-phase signal and the Q-phase signal and outputs a transmission signal. At this time, the transmission signal is generated as a modulated signal (IQ signal) obtained by subjecting a carrier wave signal with a predetermined frequency to amplitude modulation in a period longer than a period of the carrier wave signal. The reception signal processed by the baseband signal processing circuit 603 is used as an image signal for displaying an image or as an audio signal for a call by a user of the communication device 600h. The high frequency circuit 400h transmits the high frequency signals (reception signals and transmission signals) between the antenna 610 and the RF signal processing circuit 602 of the signal processing circuit 601.

### (5) Other Examples of First Receiving Filter and Second Receiving Filter

As illustrated in FIG. 27, for example, in the first receiving filter 61A, the first receiving filter 61A may further include a phase adjusting element 19. The phase adjusting element 19 is an inductor, for example. An inductor that constitutes the phase adjusting element 19 may be a chip inductor or may be an inner layer inductor built into a mounting substrate. In the example illustrated in FIG. 27, the phase adjusting element 19 is connected between the ground and the first acoustic wave resonator 14B (first parallel arm resonator P14) that is farthest from the antenna terminal T1, in the first receiving filter 61A. This allows the high frequency circuit 400h to further improve the attenuation characteristics of the first receiving filter 61A.

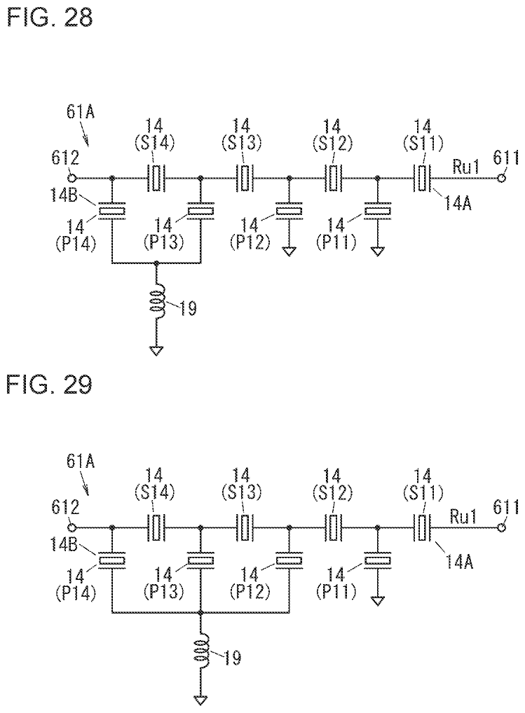

In addition, as illustrated in FIG. 28, for example, the phase adjusting element 19 may be connected between the ground and a connecting point between the first parallel arm resonator P14 that is farthest from the antenna terminal T1 and the first parallel arm resonator P13 that is the second farthest from the antenna terminal T1.

In addition, as illustrated in FIG. 29, for example, the first receiving filter 61A may be connected between the ground and a connecting point between the first parallel arm resonator P14 that is farthest from the antenna terminal T1 and the first parallel arm resonator P13 that is the second farthest from the antenna terminal T1 and the first parallel arm resonator P12 that is the third farthest from the antenna terminal T1.

In addition, the plurality of first acoustic wave resonators 14 of the first receiving filter 61A is not limited to a SAW resonator and may be, for example, a bulk acoustic wave (BAW) resonator. The BAW resonator is, for example, a film bulk acoustic resonator (FBAR), but is not limited to this and may be a solidly mounted resonator (SMR).

In addition, the plurality of second acoustic wave resonators 24 of the second receiving filter 62A is not limited to a SAW resonator and may be, for example, a BAW resonator. The BAW resonator is, for example, an FBAR, but is not limited to this and may be SMR.

### (6) High Frequency Module

The high frequency module 500h (see FIG. 25) according to Embodiment 9 includes the high frequency circuit 400h (see FIG. 25) and a mounting substrate having a first principal surface and a second principal surface that face each other. As the mounting substrate has a similar configuration to the configuration of the mounting substrate 100 in the high frequency module 500 (see FIGS. 1 to 3) according to Embodiment 1, illustration and description thereof are omitted. In addition, the high frequency module 500h according to Embodiment 9 includes the switch 7A instead of the switch 7 of the high frequency module 500 according to Embodiment 1. In addition, the plurality of power amplifiers 421 and 422 is disposed on the first principal surface of the mounting substrate. In addition, the third switch 406 is disposed on the second principal surface of the mounting substrate.

In addition, the high frequency module 500h according to Embodiment 9 includes the IC chip having the first low noise amplifier 81A, the second low noise amplifier 82A, and the second switch 9A instead of the IC chip 8 of the high frequency module 500 according to Embodiment 1.

In the high frequency module 500h according to Embodiment 9, a first electronic component having the first filter 61A and the second antenna end resonator 24A of the second filter 62A is disposed on the first principal surface of the mounting substrate. In addition, a second electronic component having at least one second acoustic wave resonator 24 other than the second antenna end resonator 24A among the plurality of second acoustic wave resonators 24 of the second filter 62A is disposed on the first principal surface of the mounting substrate. In plan view from a thickness direction of the mounting substrate, a distance between the first electronic component and the switch 7A is shorter than a distance between the second electronic component and the switch 7A. This allows the high frequency module 500h according to Embodiment 9 to suppress the degradation of the characteristics during simultaneous communication.

### Embodiment 10

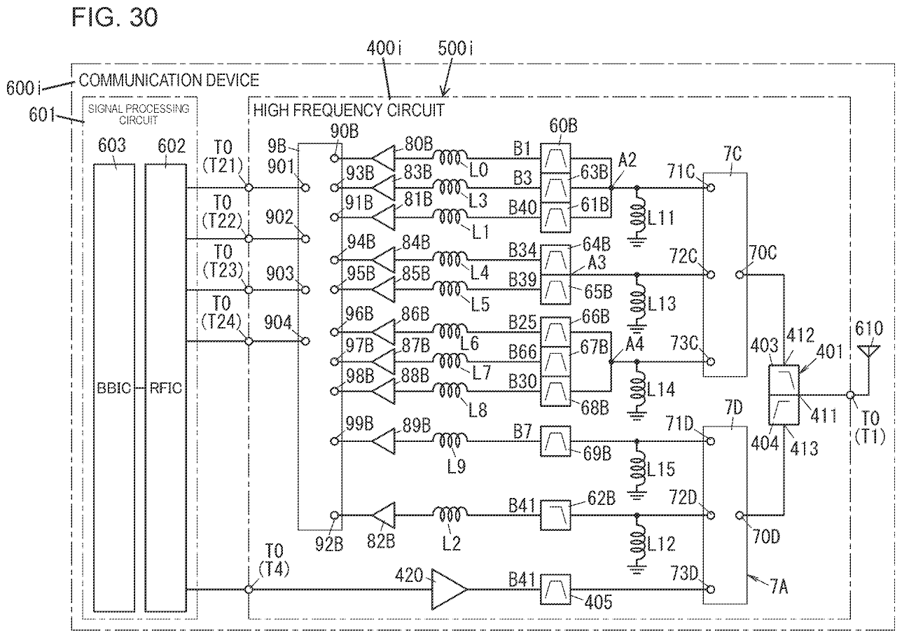

In the following, a description will be given of a high frequency circuit 400i, a high frequency module 500i, and a communication device 600i according to Embodiment 10 with reference to FIGS. 30 to 32.

### (1) High Frequency Circuit

As illustrated in FIG. 30, the high frequency circuit 400i includes the plurality of external connection terminals TO, a first switch circuit 7C, a second switch circuit 7D, and a plurality of (eleven, for example) filters 60B to 69B and 405, a plurality of (ten, for example) low noise amplifiers 80B to 89B, and a power amplifier 420. The plurality of external connection terminals TO includes the antenna terminal T1, a plurality of (four, for example) signal output terminals T21 to T24, and the signal input terminal T4. In the high frequency circuit 400i, the first switch circuit (first switching unit) 7C and the second switch circuit (second switching unit) 7D constitute the switch 7A. The high frequency circuit 400i also includes the plurality of (ten, for example) inductors L0 to L9, a plurality of (five, for example) inductors L11 to L15, a third switch circuit 9B, and a multiplexer 401. The high frequency circuit 400i is used in the communication device 600i, for example. The communication device 600i is, for example, a cellular phone (such as a smartphone), but is not limited thereto and may be, for example, a wearable terminal (such as a smartwatch), or the like. The high frequency circuit 400i is, for example, a high frequency front end circuit that can support a 4G (fourth-generation mobile communication) standard or a 5G (fifth-generation mobile communication) standard, or the like. The 4G standard is, for example, 3GPP (registered trademark, Third Generation Partnership Project) LTE (registered trademark, Long Term Evolution) standard. The 5G standard is, for example, 5G NR (New Radio). The high frequency circuit 400i is, for example, a high frequency front end circuit that can support carrier aggregation and dual connectivity.

### (1.1) Antenna Terminal

The antenna terminal T1 is, for example, a terminal connected to the antenna 610 included in the communication device 600i.

### (1.2) Signal Output Terminal

The plurality of signal output terminal T21 to T24 is, for example, a terminal for outputting high frequency signals (reception signals) from the plurality of low noise amplifiers 80B to 89B to the external circuit (such as the signal processing circuit 601 of the communication device 600i).

### (1.3) Signal Input Terminal

The signal input terminal T4 is a terminal for inputting high frequency signals (transmission signals) from the external circuit (such as the signal processing circuit 601) to the high frequency circuit 400i.

### (1.4) First Switch Circuit

The first switch circuit 7C is connected to the antenna terminal T1. More particularly, the first switch circuit 7C is connected to the antenna terminal T1 with the multiplexer 401 interposed. The first switch circuit 7C has a common terminal 70C connected to the multiplexer 401 and a plurality of (three, for example) selection terminals 71C to 73C that can be connected to the common terminal 70C.

The first switch circuit 7C is, for example, a switch that can connect one or more of the plurality of selection terminals 71C to 73C to the common terminal 70C. Here, the first switch circuit 7C is, for example, a switch integrated circuit (IC) capable of one-to-one connection and one-to-many connection.

The first switch circuit 7C is controlled by the signal processing circuit 601, for example. The first switch circuit 7C switches a connection state between the common terminal 70C and the plurality of selection terminals 71C to 73C, according to a control signal from the RF signal processing circuit 602 of the signal processing circuit 601.

### (1.5) Second Switch Circuit

The second switch circuit 7D is connected to the antenna terminal T1. More particularly, the second switch circuit 7D is connected to the antenna terminal T1 with the multiplexer 401 interposed. The second switch circuit 7D has a common terminal 70D that is connectable to the multiplexer 401 and a plurality of (three, for example) selection terminals 71D to 73D that are connectable to the common terminal 70D.

The second switch circuit 7D is, for example, a switch that can connect one or more of the plurality of selection terminals 71D to 73D to the common terminal 70D. Here, the second switch circuit 7D is, for example, a switch integrated circuit (IC) capable of one-to-one connection and one-to-many connection.

The second switch circuit 7D is controlled by the signal processing circuit 601, for example. The second switch circuit 7D switches a connection state between the common terminal 70D and the plurality of selection terminals 71D to 73D, according to a control signal from the RF signal processing circuit 602 of the signal processing circuit 601.

### (1.6) Filters

The filters 60B to 69B of the plurality of filters 60B to 69B and 405 are receiving filters having pass bands including frequency bands of the mutually different communication bands. The filter 405 is a transmitting filter. In FIG. 30, Band of the 3GPP LTE standard is written, as the letter “B” with a number, to the left of the figure symbol of each of the filters 60B to 69B and 405. For example, “B1” represents Band 1 of the 3GPP LTE standard. Each of the plurality of filters 60B to 69B and 405 has an input terminal and an output terminal.

The filter 60B has, for example, the pass band including the frequency band of Band1 of the 3GPP LTE standard. A filter 61B (hereinafter referred to as a first filter 61B) has, for example, the pass band including the frequency band of Band40 of the 3GPP LTE standard. A filter 62B (hereinafter referred to as a second filter 62B) has, for example, the pass band including the frequency band of Band41 of the 3GPP LTE standard. A filter 63B has, for example, the pass band including the frequency band of Band3 of the 3GPP LTE standard. A filter 64B has, for example, the pass band including the frequency band of Band34 of the 3GPP LTE standard. A filter 65B has, for example, the pass band including the frequency band of Band39 of the 3GPP LTE standard. A filter 66B has, for example, the pass band including the frequency band of Band25 of the 3GPP LTE standard. A filter 67B has, for example, the pass band including the frequency band of Band66 of the 3GPP LTE standard. A filter 68B has, for example, the pass band including the frequency band of Band30 of the 3GPP LTE standard. A filter 69B has, for example, the pass band including the frequency band of Band1 of the 3GPP LTE standard. Among the filters 60B to 69B, the filters 60B, 61B, and 63B to 69B are band pass filters, and the remaining filter 62B is a low pass filter. Each of the plurality of filters 60B to 69B and 405 is, for example, an acoustic wave filter. The first filter 61b is a ladder filter and has the plurality of first acoustic wave resonators 14, as with the first filter 61A (see FIG. 26A) described in Embodiment 9. The plurality of first acoustic wave resonators 14 includes the plurality of first series arm resonators S11 to S14 and the plurality of first parallel arm resonators P11 to P14. The second filter 62B is a ladder filter and includes the plurality of second acoustic wave resonators 24, as with the second filter 62A (see FIG. 26B) described in Embodiment 9. The plurality of second acoustic wave resonators 24 includes the plurality of second series arm resonators S21 to S24 and the plurality of second parallel arm resonators P21 to P24.

The filter 405 has the pass band including the frequency band of Band 41 of the 3GPP LTE standard. The filter 405 is an acoustic wave filter, for example. The filter 405 is a ladder filter and has an input terminal, an output terminal, and a plurality of acoustic wave resonators. The plurality of acoustic wave resonators includes a plurality of series arm resonators and a plurality of parallel arm resonators.

The plurality of filters 60B to 69B and 405 is connected to the multiplexer 401 with the first switch circuit 7C or the second switch circuit 7D interposed. More particularly, the filters 60B, 61B, and 63B to 68B are connected to the multiplexer 401 with the first switch circuit 7C interposed, and the filters 62B, 69B, and 405 are connected to the multiplexer 401 with the second switch circuit 7D interposed.

In the high frequency circuit 400i, the first filter 61B has the pass band including the frequency band of the first communication band (for example, Band40), and the second filter 62B and the filter 405 have the pass band including the frequency band of the second communication band (for example, Band41).

The first communication band is a first time division duplex (TDD) communication band and the second communication band is a second TDD communication band in a frequency band higher than the first communication band. The second communication band and the first communication band are included in a combination of communication bands capable of simultaneous communication. The “capable of simultaneous communication” means that at least one of simultaneous reception, simultaneous transmission, or simultaneous transmission and reception is possible. In the high frequency circuit 400i, a combination of the first communication band and the second communication band is a combination in which simultaneous reception is performed in the high frequency circuit 400i. For example, TDD allows the high frequency circuit 400i to realize simultaneous reception of reception signals in the frequency band of the first communication band and the reception signals in the frequency band of the second communication band. The combination of the first communication band and the second communication band capable of simultaneous communication is included in, for example, a combination of communication bands applicable to communications by ENDC (Evolved-Universal Terrestrial Radio Access New Radio Dual Connectivity) specified by the 3GPP (registered trademark, Third Generation Partnership Project)—Rel17 standard or a combination of communication bands applicable to communications by carrier aggregation specified by the 3GPP (registered trademark, Third Generation Partnership Project)—Rel17 standard. The first communication band is, for example, n40 of the 5G NR standard. In this case, the frequency band of the first communication band is 2300 to 2400 MHz. The frequency band of n40 of the 5G NR standard is the same as the frequency band of Band40 of the 3GPP LTE standard. In addition, the second communication band is, for example, n41 of the 5G NR standard. In this case, the frequency band of the second communication band is 2496 to 2690 MHz. Note that the frequency band of n41 of the 5G NR standard is the same as the frequency band of Band41 of the 3GPP LTE standard.

A connecting point A2 between the input terminal of the filter 60B, the input terminal of the filter 61B, and the input terminal of the filter 63B is connected to the selection terminal 71C of the first switch circuit 7C. In addition, a connecting point A3 between the input terminal of the filter 64B and the input terminal of the filter 65B is connected to the selection terminal 72C of the first switch circuit 7C. In addition, a connecting point A4 between the input terminal of the filter 66B, the input terminal of the filter 67B, and the input terminal of the filter 68B is connected to the selection terminal 73C of the first switch circuit 7C. The input terminal of the filter 69B is connected to the selection terminal 71D of the second switch circuit 7D. The input terminal of the filter 62B is connected to the selection terminal 72D of the second switch circuit 7D. The output terminal of the filter 405 is connected to the selection terminal 73D of the second switch circuit 7D.

The output terminal of the filter 60B is connected to an input terminal of the low noise amplifier 80B with the inductor L0 interposed. The output terminal of the filter 61B is connected to an input terminal of the low noise amplifier 81B with the inductor L1 interposed. The output terminal of the filter 62B is connected to an input terminal of the low noise amplifier 82B with the inductor L2 interposed. The output terminal of the filter 63B is connected to an input terminal of the low noise amplifier 83B with the inductor L3 interposed. The output terminal of the filter 64B is connected to an input terminal of the low noise amplifier 84B with the inductor L4 interposed. The output terminal of the filter 65B is connected to an input terminal of the low noise amplifier 85B with the inductor L5 interposed. The output terminal of the filter 66B is connected to an input terminal of the low noise amplifier 86B with the inductor L6 interposed. The output terminal of the filter 67B is connected to an input terminal of the low noise amplifier 87B with the inductor L7 interposed. The output terminal of the filter 68B is connected to an input terminal of the low noise amplifier 88B with the inductor L8 interposed. The output terminal of the filter 69B is connected to an input terminal of the low noise amplifier 89B with the inductor L9 interposed.

The input terminal of the filter 405 is connected to the output terminal of the power amplifier 420.

### (1.7) Low Noise Amplifier

Each of the plurality of low noise amplifiers 80B to 89B has an input terminal and an output terminal. Each of the plurality of low noise amplifiers 80B to 89B amplifies a reception signal inputted to the input terminal and outputs the signal from the output terminal.

The output terminals of the plurality of low noise amplifiers 80B to 89B can be connected to the signal output terminals T21 to T24 with the third switch circuit 9B interposed. The signal output terminals T21 to T24 are terminals for outputting high frequency signals (reception signals) from the plurality of low noise amplifier 80B to 89B to the external circuit (for example, the signal processing circuit 601).

### (1.8) Third Switch Circuit

The third switch circuit 9B has a plurality of (four, for example) common terminals 901 to 904 and a plurality of (ten, for example) selection terminals 90B to 99B. The four common terminals 901 are connected in a one-to-one manner to the four signal output terminals T21 to T24. The ten selection terminals 90B to 99B are connected in a one-to-one manner to the output terminals of the ten low noise amplifiers 80B to 89B. The third switch circuit 9B is, for example, a switch that can connect one or more of the ten selection terminals 90B to 99B to each of the four common terminals 901 to 904. Here, the third switch circuit 9B is, for example, a switch integrated circuit (IC) capable of one-to-one connection and one-to-many connection, in each of a plurality of common terminals 901 to 904.

The third switch circuit 9B is controlled by the signal processing circuit 601, for example. The third switch circuit 9B switches a connection state between the four common terminal 901 to 904 and the ten selection terminals 90B to 99B, according to a control signal from the RF signal processing circuit 602 of the signal processing circuit 601.

### (1.9) Power Amplifier

The power amplifier 420 has an input terminal and an output terminal. The power amplifier 420 power-amplifies the transmission signals inputted to the input terminal and outputs the signals from the output terminal. The input terminal of the power amplifier 420 is connected to the signal input terminal T4. The input terminal of the power amplifier 420 is, for example, connected to the signal processing circuit 601 with the signal input terminal T4 interposed. The output terminal of the power amplifier 420 is connected to the input terminal of the filter 405.

### (1.10) Inductors

The inductors L0 to L9 are circuit elements for impedance matching. In addition, the inductor L11 is connected between the ground and a path between the connecting point A2 and the selection terminal 71C. The inductor L12 is connected between the ground and a path between the input terminal of the filter 62B and the selection terminal 72D. The inductor L13 is connected between the ground and a path between the connecting point A3 and the selection terminal 72C. The inductor L14 is connected between the ground and a path between the connecting point A4 and the selection terminal 73C. The inductor L15 is connected between the ground and a path between the input terminal of the filter 69B and the selection terminal 71D. The inductors L11 to L15 are circuit elements for impedance matching.

### (1.11) Multiplexer

The multiplexer 401 is connected between the antenna terminal T1, the first switch circuit 7C, and the second switch circuit 7D. The multiplexer 401 has a first signal terminal 411, a second signal terminal 412, a third signal terminal 413, a third filter 403, and a fourth filter 404. The first signal terminal 411 is connected to the antenna terminal T1. In the high frequency circuit 400i, an inductor L51 for impedance matching is connected between the ground and a path between the first signal terminal 411 and the antenna terminal T1. For example, the second signal terminal 412 is connected to the common terminal 70C of the first switch circuit 7C. The third signal terminal 413 is connected to the common terminal 70D of the second switch circuit 7D. The third filter 403 is connected between the first signal terminal 411 and the second signal terminal 412. The third filter 403 has the pass band including the frequency band of the first communication band. The fourth filter 404 is connected between the first signal terminal 411 and the third signal terminal 413. The fourth filter 404 has the pass band including the frequency band of the second communication band. The multiplexer 401 is a diplexer, for example.

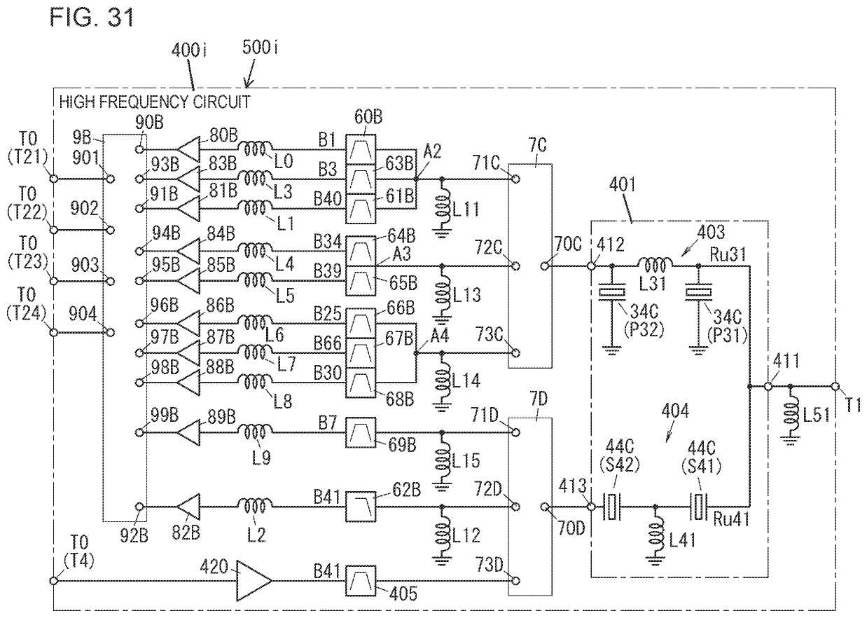

The third filter 403 is a low pass filter. As illustrated in FIG. 31, for example, the third filter 403 is a filter (hereinafter also referred to as a first hybrid filter) including two third acoustic wave resonators 34C and a first inductor L31, as a plurality of first circuit elements. The first inductor L31 is provided on a first signal path Ru31 between the first signal terminal 411 and the second signal terminal 412. The two third acoustic wave resonators 34 are SAW resonators, but are not limited thereto and may be BAW resonators. The two third acoustic wave resonators 34C include the two parallel arm resonators P31 and P32. The parallel arm resonator P31 is connected between the ground and a path between the first signal terminal 411 and the first inductor L31. The parallel arm resonator P32 is connected between the ground and a path between the first inductor L31 and the second signal terminal 412. The first inductor L31 constitutes a low pass filter together with a capacitor component of the parallel arm resonator P31 and a capacitor component of the parallel arm resonator P32. A pass band width of the first hybrid filter is larger than a pass band width of the third acoustic wave resonator 34C. The pass band width of the third acoustic wave resonator 34C is a fractional bandwidth of the third acoustic wave resonator 34C and is a difference between anti-resonant frequency and resonant frequency of the third acoustic wave resonator 34C. A number of the first inductors L31 (number of series connections) included in the first hybrid filter is not limited to one and may be two or more. In addition, the number of the third acoustic wave resonators 34C (number of parallel connections) included in the first hybrid filter is not limited to two and may be one or three or more. In addition, the first hybrid filter may include one or more capacitors.

The fourth filter 404 is a high pass filter. As illustrated in FIG. 31, for example, the fourth filter 404 is a filter (hereinafter also referred to as a second hybrid filter) including two fourth acoustic wave resonators 44C and a second inductor L41, as a plurality of second circuit elements. The two fourth acoustic wave resonators 44C are SAW resonators but are not limited thereto and may be BAW resonators. The two fourth acoustic wave resonators 44C include the two series arm resonators S41 and S42. The two series arm resonators S41 and S42 are provided on a second signal path Ru41 between the first signal terminal 411 and the third signal terminal 413. The second inductor L41 is connected between the ground and a path between the two series arm resonators S41 and S42. The second inductor L41 constitutes a high pass filter together with a capacitor component of the series arm resonator S41 and a capacitor component of the series arm resonator S42. A pass band width of the second hybrid filter is larger than a pass band width of the fourth acoustic wave resonator 44C. The pass band width of the fourth acoustic wave resonator 44C is a fractional bandwidth of the fourth acoustic wave resonator 44C and is a difference between anti-resonant frequency and resonant frequency of the fourth acoustic wave resonator 44C. A number of the second inductors L41 (number of parallel connections) included in the second hybrid filter is not limited to one and may be two or more. In addition, the number of the fourth acoustic wave resonators 44C (number of series connections) included in the second hybrid filter is not limited to two and may be one or three or more. In addition, the second hybrid filter may include one or more capacitors. In addition, the fourth filter 404 is not limited to a high pass filter and may be a band pass filter.

### (2) Characteristics of First Filter and Third Filter

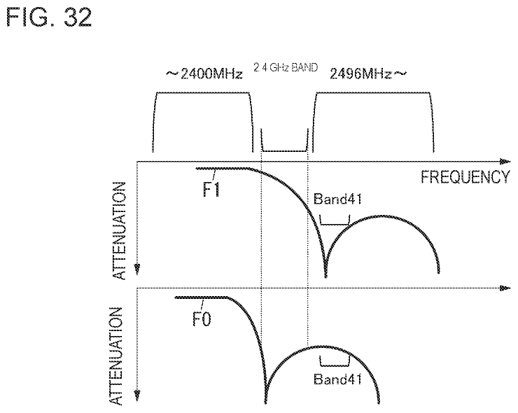

When the first communication band is Band40 and the second communication band is Band41, as illustrated in the upper column of FIG. 32, there is 2.4 GHz band of WiFi (registered trademark) between the frequency band of the first communication band and the frequency band of the second communication band. In the high frequency circuit 400i, the attenuation pole of the attenuation characteristics F0 of the third filter 403 is in 2.4 GHz band, and the attenuation pole of the attenuation characteristics F1 of the first filter 61b is in the frequency band of Band41.

### (3) Effects

The high frequency circuit 400i according to Embodiment 10 includes the antenna terminal T1, the multiplexer 401, the first switch circuit 7C, the second switch circuit 7D, the first filter 61B, and the second filter 62B. The multiplexer 401 has the first signal terminal 411, the second signal terminal 412, and the third signal terminal 413. In the multiplexer 401, the first signal terminal 411 is connected to the antenna terminal T1. The first switch circuit 7C is connected to the second signal terminal 412. The second switch circuit 7D is connected to the third signal terminal 413. The first filter 61B is connected to the second signal terminal 412 with the first switch circuit 7C interposed. The first filter 61B has the pass band including the frequency band of the TDD first communication band. The second filter 62B is connected to the third signal terminal 413 with the second switch circuit 7D interposed. The second filter 62B has the pass band including the frequency band of the second TDD communication band that is capable of simultaneous communication with the first communication band. The frequency band of the second communication band is on the higher frequency side than the frequency band of the first communication band. The multiplexer 401 further has the third filter 403 and the fourth filter 404. The third filter 403 is connected between the first signal terminal 411 and the second signal terminal 412. The third filter 403 has the pass band including the frequency band of the first communication band. The fourth filter 404 is connected between the first signal terminal 411 and the third signal terminal 413. The fourth filter 404 has the pass band including the frequency band of the second communication band.

According to the high frequency circuit 400i according to Embodiment 10, it is possible to suppress the degradation of the characteristics during simultaneous communication. More particularly, as the first switch circuit 7C, the multiplexer 401, and the second switch circuit 7D are disposed between the first filter 61B and the second filter 62B, the high frequency circuit 400i according to Embodiment 10 can improve the isolation between the first filter 61B and the second filter 62B. As a result, in the high frequency circuit 400i according to Embodiment 10, the attenuation characteristics of the frequency band of the second filter 62B can be improved in the first filter 61B, when simultaneous communication is performed in the first communication band and the second communication band, and the attenuation characteristics of the frequency band of the first filter 61B can also be improved in the second filter 62B.

In addition, the high frequency circuit 400i according to Embodiment 10 further includes the filter 405 (hereinafter also referred to a fifth filter 405) connectable to the fourth filter 404 with the second switch circuit 7D interposed and the power amplifier 420 connected to the fifth filter. The first filter 61B is a receiving filter that has the pass band including the frequency band of the first TDD communication band. The second filter 62B is a receiving filter that has the pass band including the frequency band of the second TDD communication band. The fifth filter (filter 405) is a transmitting filter that has the pass band including the frequency band of the second TDD communication band. The third filter 403 is the first hybrid filter that includes at least one third acoustic wave resonator 34C and the first inductor L31, as the plurality of first circuit elements. The pass band width of the first hybrid filter is larger than the pass band width of the third acoustic wave resonator 34C. The fourth filter 404 is the second hybrid filter including at least one fourth acoustic wave resonator 44C and the second inductor L41, as the plurality of second circuit elements. The pass band width of the second hybrid filter is larger than the pass band width of the fourth acoustic wave resonator 44C. As such, the high frequency circuit 400i according to Embodiment 10 can improve the attenuation characteristics of the frequency bands between the first communication band and the second communication band in each of the third filter 403 and the fourth filter 404.

In addition, in the first hybrid filter in the high frequency circuit 400i according to Embodiment 10, in the first hybrid filter, the first circuit element that is farthest from the antenna terminal T1 among the plurality of the first circuit elements is one of at least one third acoustic wave resonator 34C. In the second hybrid filter, the second circuit element that is farthest from the antenna terminal T1 among the plurality of the second circuit elements is one of at least one fourth acoustic wave resonator 44C. As a result, the high frequency circuit 400i according to Embodiment 10 can suppress a distortion signal in the third acoustic wave resonator 34C that is farthest from the antenna terminal T1, and can also suppress a distortion signal in the fourth acoustic wave resonator 44C that is farthest from the antenna terminal T1. Note that in the first hybrid filter, the first circuit element that is farthest from the antenna terminal T1 among the plurality of first circuit elements may be other than the third acoustic wave resonator 34C. In addition, in the second hybrid filter, the second circuit element that is farthest from the antenna terminal T1 among the plurality of second circuit elements may be other than the fourth acoustic wave resonator 44C.

### (4) Communication Device

The communication device 600i according to Embodiment 10 includes the high frequency circuit 400i and the signal processing circuit 601. The high frequency circuit 400i is connected to the signal processing circuit 601. This allows the communication device 600i according to Embodiment 10 to suppress the degradation of the characteristics during simultaneous communication.

The signal processing circuit 601 includes, for example, the RF signal processing circuit 602 and the baseband signal processing circuit 603. The RF signal processing circuit 602 is, for example, a radio frequency integrated circuit (RFIC) and performs signal processing for high frequency signals. The RF signal processing circuit 602 performs, for example, signal processing such as up-conversion on high frequency signals (transmission signals) outputted from the baseband signal processing circuit 603 and outputs the signal-processed high frequency signals. The RF signal processing circuit 602 also performs, for example, signal processing such as down-conversion on high frequency signals (reception signals) outputted from the high frequency circuit 400i and outputs the signal-processed high frequency signals to the baseband signal processing circuit 603. The baseband signal processing circuit 603 is, for example, a baseband integrated circuit (BBIC). The baseband signal processing circuit 603 generates an I-phase signal and a Q-phase signal from a baseband signal. The baseband signal is, for example, an audio signal, an image signal, or the like, inputted from the outside. The baseband signal processing circuit 603 performs IQ modulation processing by synthesizing the I-phase signal and the Q-phase signal and outputs a transmission signal. At this time, the transmission signal is generated as a modulated signal (IQ signal) obtained by subjecting a carrier wave signal with a predetermined frequency to amplitude modulation in a period longer than a period of the carrier wave signal. The reception signal processed by the baseband signal processing circuit 603 is used as an image signal for displaying an image or as an audio signal for a call by a user of the communication device 600i. The high frequency circuit 400i transmits the high frequency signals (reception signals and transmission signals) between the antenna 610 and the RF signal processing circuit 602 of the signal processing circuit 601.

### (5) Modification Examples of Embodiment 10

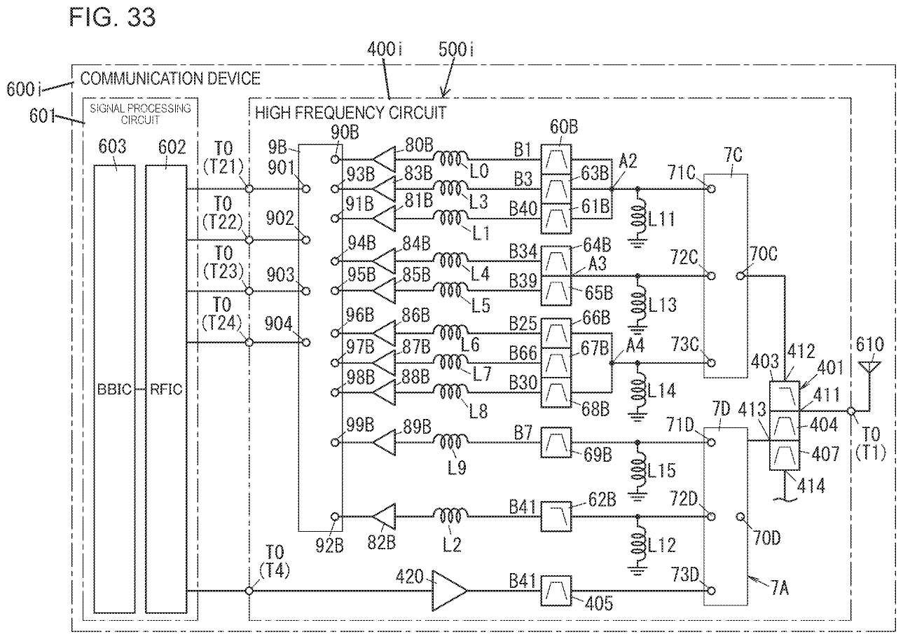

In the high frequency circuit 400i, the multiplexer 401 may be a triplexer that further has a sixth filter 407 in addition to the third filter 403 and the fourth filter 404, as illustrated in FIG. 33. The multiplexer 401 further has a fourth signal terminal 414, and the sixth filter 407 is connected between the first signal terminal 411 and the fourth signal terminal 414. The sixth filter 407 is, for example, a band pass filter having a pass band in UHB band (3.5 GHz band).

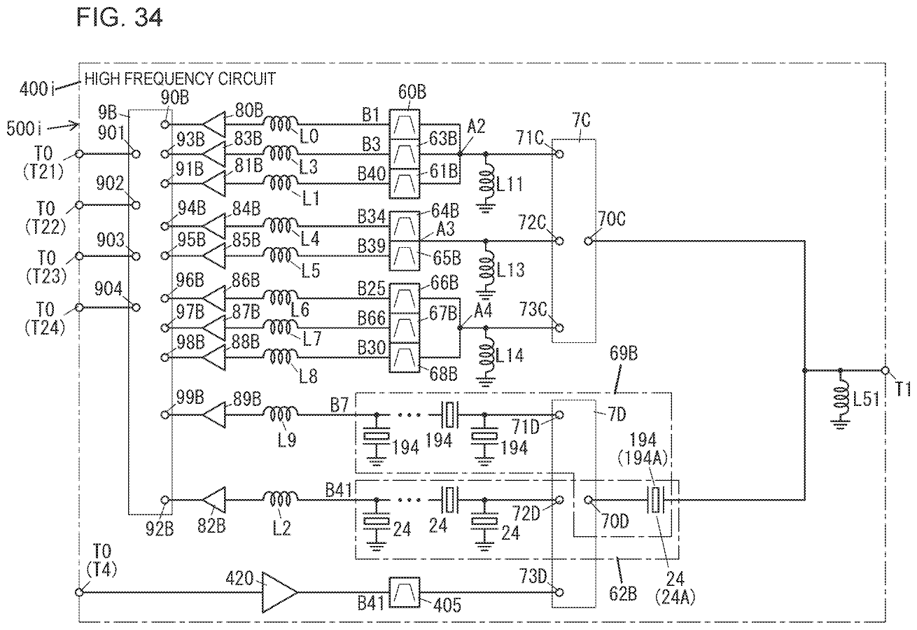

The reception band of Band1 is 2620 to 2690 MHz, the reception band of Band41 is 2496 to 2690 MHz, and the upper limit frequency of those reception bands is the same at 2690 MHz. Therefore, as illustrated in FIG. 34, for example, the high frequency circuit 400i can make common the series arm resonator, which is the antenna end resonator 24A of the second filter 62B, and the series arm resonator, which is an antenna end resonator 194A of the filter 69B, when the second filter 62B is a ladder filter having the plurality of acoustic wave resonators 24 and the filter 69B is a ladder filter having the plurality of acoustic wave resonators 194. Therefore, for example, it is possible to make the antenna end resonator 24A of the second filter 62B and antenna end resonator 194A of the filter 69B common as a series arm resonator, and provide it between the common terminal 70D of the second switch circuit 7D and the antenna terminal T1. With such a configuration, the high frequency circuit 400i can further suppress the degradation of the characteristics during simultaneous communication. In addition, as the transmission band of Band41 is 2496 to 2690 MHz, and the upper limit frequency is 2690 MHz, with respect to the series arm resonator which is the antenna end resonator of the filter 405, the high frequency circuit 400i can also make common the series arm resonator, which is the antenna end resonator 24A of the second filter 62B, and the series arm resonator, which is the antenna end resonator 194A of the filter 69B. Note that the high frequency circuit 400i illustrated in FIG. 34 may include the multiplexer 401, as with the high frequency circuit 400i (see FIG. 31) according to Embodiment 10.

In addition, the first acoustic wave resonator 14 of the first filter 61B is not limited to a SAW resonator and may be, for example, a bulk acoustic wave (BAW) resonator. The BAW resonator is, for example, a film bulk acoustic resonator (FBAR), but is not limited to this and may be a solidly mounted resonator (SMR).

In addition, the plurality of second acoustic wave resonators 24 of the second filter 62B is not limited to a SAW resonator and may be, for example, a bulk acoustic wave (BAW) resonator. The BAW resonator is, for example, a film bulk acoustic resonator (FBAR), but is not limited to this and may be a solidly mounted resonator (SMR).

### (6) High Frequency Module

The high frequency module 500i (see FIG. 30) according to Embodiment 10 includes the high frequency circuit 400i (see FIG. 30) and a mounting substrate having a first principal surface and a second principal surface that face each other. As the mounting substrate has a similar configuration to the configuration of the mounting substrate 100 (see FIGS. 1 to 3) in the high frequency module 500 according to Embodiment 1, illustration and description thereof are omitted. In addition, the high frequency module 500i according to Embodiment 10 includes the switch 7A instead of the switch 7 of the high frequency module 500 according to Embodiment 1. In addition, the power amplifier 420 is disposed on the first principal surface of the mounting substrate. In addition, the multiplexer 401 is disposed on the first principal surface of the mounting substrate.

In addition, the high frequency module 500i according to Embodiment 10 includes the IC chip having the plurality of low noise amplifier 80B to 89B and the third switch circuit 9B instead of the IC chip 8 of the high frequency module 500 according to Embodiment 1.

In the high frequency module 500i according to Embodiment 10, a first electronic component having the first filter 61B and the second antenna end resonator 24A of the second filter 62B is disposed on the first principal surface of the mounting substrate. In addition, a second electronic component having at least one second acoustic wave resonator 24 other than the second antenna end resonator 24A among the plurality of second acoustic wave resonators 24 of the second filter 62B is disposed on the first principal surface of the mounting substrate. In plan view from a thickness direction of the mounting substrate, a distance between the first electronic component and the switch 7A is shorter than a distance between the second electronic component and the switch 7A. This allows the high frequency module 500i according to Embodiment 10 to suppress the degradation of the characteristics during simultaneous communication.

### Modification Examples

The embodiments 1 to 10 described above are merely one of various embodiments of the present disclosure. The embodiments 1 to 10 described above can be modified in various ways depending on the designs or the like, as far as the possible benefits of the present disclosure can be achieved, and mutually different components of the mutually different embodiments can be combined appropriately.

For example, in the high frequency modules 500, 500a, 500c, 500d, 500e, 500f, 500g, 500h, and 500i, the at least one first acoustic wave resonator 14 of the plurality of first acoustic wave resonators 14 may include, for example, a plurality of (two or three, for example) divided resonators. The plurality of divided resonators is resonators resulting from the division of the one first acoustic wave resonator 14. The plurality of divided resonators is connected in series without any other first acoustic wave resonators 14 interposed in between and without a connection node with a path including other first acoustic wave resonators 14 interposed.

In addition, in the high frequency modules 500, 500a, 500b, 500c, 500d, 500e, 500f, 500g, 500h, and 500i, the at least one second acoustic wave resonator 24 of the plurality of second acoustic wave resonators 24 may include, for example, a plurality of (two or three, for example) divided resonators. The plurality of divided resonators is resonators resulting from the division of the one second acoustic wave resonator 24. The plurality of divided resonators is connected in series without any other second acoustic wave resonators 24 interposed in between and without any connection node with a path including other second acoustic wave resonators 24 interposed.

In addition, in the high frequency modules 500, 500h, and 500i, the plurality of first acoustic wave resonators 14 in the first filter 1 may include two longitudinally coupled resonators. In this case, for example, a parallel circuit of the two longitudinally coupled resonators may be connected between the first antenna end resonator 14A (series arm resonator S11) and the other first acoustic wave resonator 14 (series arm resonator S12) in the first signal path Ru1.

In addition, in the high frequency modules 500, 500a, 500b, 500c, 500d, 500e, 500f, 500g, 500h, and 500i, the plurality of second acoustic wave resonators 24 in the second filter 2 may include two longitudinally coupled resonators. In this case, for example, a parallel circuit of the two longitudinally coupled resonators may be connected between the second antenna end resonator 24A (series arm resonator S21) and the other second acoustic wave resonator 24 (series arm resonator S22) in the second signal path Ru2.

In addition, in the high frequency modules 500, 500a, 500b, 500c, 500d, 500e, 500f, 500g, 500h, and 500i, the second filter 2 is not limited to a configuration in which only the second antenna end resonator 24A among the plurality of second acoustic wave resonators 24 is included in the first electronic component E1. The second antenna end resonator 24A and the parallel arm resonator P21 may also be included in the first electronic component E1, however.

In addition, the high frequency modules 500, 500a, 500b, 500c, 500d, 500e, 500f, and 500g may include matching circuits between the plurality of filters 61 to 68 and the plurality of low noise amplifiers 81 to 88, the matching circuits being for achieving the impedance matching between filters and low noise amplifiers that correspond one-to-one. The matching circuit includes, for example, an inductor and a capacitor.

In addition, in the high frequency module 500, at least one of the first switch 7 or the IC chip 8 may be disposed on the first principal surface 101 of the mounting substrate 100. The high frequency module 500 may also include a first IC chip including the plurality of low noise amplifiers 81 to 88 and a second IC chip that is different from the first IC chip and includes the second switch 9 instead of the IC chip 8.

In addition, in the high frequency modules 500, 500a, 500b, 500c, 500d, 500e, 500f, and 500g, the plurality of filters 61 to 68 may only include at least the first filter 1 or the second filter 2.

The communication device 600 according to Embodiment 1 may include any of the high frequency modules 500a to 500g, instead of the high frequency module 500.

In addition, the high frequency modules 500, 500a, 500b, 500c, 500d, 500e, 500f, and 500g are not limited to a reception module including the receiving filters (filters 61 to 68) and the low noise amplifiers 81 to 88, but may be, for example, a transmission module including a transmitting filter and a power amplifier or may be a transmission/reception module including a transmitting filter, a power amplifier, a receiving filter, and a low noise amplifier.

In addition, the high frequency modules 500, 500a, 500b, 500c, 500d, 500e, 500f, 500g, 500h, and 500i may have a configuration in which the plurality of external connection terminals TO is a ball bump and the second resin layer 5 is not included. In this case, the high frequency module 500 may include an underfill portion provided in a gap between the switch 7 mounted on the second principal surface 102 of the mounting substrate 100 and the second principal surface 102 of the mounting substrate 100. A material of the ball bump that constitutes each of the plurality of external connection terminals TO is, for example, gold, copper, solder, or the like. In the plurality of external connection terminals TO, the external connection terminals TO including the ball bumps and the external connection terminals TO including columnar electrodes may be mixed.

### Aspects

The specification discloses the following aspects.

The high frequency module (500; 500a; 500c; 500d; 500h; 500i) according to a first aspect includes the mounting substrate (100), the antenna terminal (T1), the switch (7), and the plurality of filters (61 to 68; 61A to 64A). The mounting substrate (100) has the first principal surface (101) and the second principal surface (102) that face each other. The antenna terminal (T1) is disposed on or in the mounting substrate (100). The switch (7; 7A) is disposed on or in the mounting substrate (100). The switch (7; 7A) is connected to the antenna terminal (T1). The plurality of filters (61 to 68; 61A to 64A; 60b to 69B) is connected to the antenna terminal (T1) with the switch (7; 7A) interposed. The plurality of filters (61 to 68; 61A to 64A; 60B to 69B) includes the first filter (1; 61A; 61B) that has the pass band including the frequency band of the first communication band and the second filter (2; 62A; 62B) that has the pass band including the frequency band of the second communication band that is capable of simultaneous communication with the first communication band. The first filter (1; 61A; 61B) has the plurality of first acoustic wave resonators (14). The second filter (2; 62A; 62B) has the plurality of second acoustic wave resonators (24). The plurality of first acoustic wave resonators (14) includes the first antenna end resonator (14A). Among the plurality of first acoustic wave resonators (14), the first antenna end resonator (14A) is the first acoustic wave resonator that is provided on the first signal path (Ru1) connected to the switch (7; 7A) and that is closest to the antenna terminal (T1). The plurality of second acoustic wave resonators (24) includes the second antenna end resonator (24A). Among the plurality of second acoustic wave resonators (24), the second antenna end resonator (24A) is the second acoustic wave resonator (24) that is provided on the second signal path (Ru2) connected to the switch (7; 7A) and that is closest to the antenna terminal (T1). The first electronic component (E1) having the first filter (1; 61A; 61B) and the second antenna end resonator (24A) of the second filter (2; 62A; 62B) is disposed on the first principal surface (101) of the mounting substrate (100). The second electronic component (E2) having at least one second acoustic wave resonator (24) other than the second antenna end resonator (24A) among the plurality of second acoustic wave resonators (24) of the second filter (2; 62A; 62b) is disposed on the first principal surface (101) of the mounting substrate (100). In plan view from the thickness direction (D1) of the mounting substrate (100), the distance between the first electronic component (E1) and the switch (7; 7A) is shorter than the distance between the second electronic component (E2) and the switch (7; 7A).

The high frequency module (500; 500a; 500c; 500d; 500h; 500i) according to the first aspect can suppress the degradation of the characteristics during simultaneous communication.

The high frequency module (500b) according to a second aspect includes the mounting substrate (100), the antenna terminal (T1), the switch (7), and the plurality of filters (61 to 68). The mounting substrate (100) has the first principal surface (101) and the second principal surface (102) that face each other. The antenna terminal (T1) is disposed on or in the mounting substrate (100). The switch (7) is disposed on or in the mounting substrate (100). The switch (7) is connected to the antenna terminal (T1). The plurality of filters (61 to 68) is connected to the antenna terminal (T1) with the switch (7) interposed. The plurality of filters (61 to 68) includes the first filter (1) that has the pass band including the frequency band of the first communication band and the second filter (2) that has the pass band including the frequency band of the second communication band that is capable of simultaneous communication with the first communication band. The first filter (1) has the plurality of first acoustic wave resonators (44). The second filter (2) has the plurality of second acoustic wave resonators (24). The plurality of first acoustic wave resonators (44) includes the first antenna end resonator (44A). Among the plurality of first acoustic wave resonators (44), the first antenna end resonator (44A) is the first acoustic wave resonator (44) that is provided on the first signal path (Ru4) connected to the switch (7) and that is closest to the antenna terminal (T1). The plurality of second acoustic wave resonators (24) includes the second antenna end resonator (24A). Among the plurality of second acoustic wave resonators (24), the second antenna end resonator (24A) is the second acoustic wave resonator (24) that is provided on the second signal path (Ru2) connected to the switch (7) and that is closest to the antenna terminal (T1). The first electronic component (E1) having the second antenna end resonator (24A) of the second filter (2) is disposed on the first principal surface (101) of the mounting substrate (100). The second electronic component (E2) having at least one second acoustic wave resonator (24) other than the second antenna end resonator (24A) among the plurality of second acoustic wave resonators (24) of the second filter (2) is disposed on the first principal surface (101) of the mounting substrate (100). The third electronic component (E3) having the first filter (1) is disposed on the first principal surface (101) of the mounting substrate (100). In plan view from the thickness direction (D1) of the mounting substrate (100), the first electronic component (E1) and the third electronic component (E3) are adjacent to each other. In plan view from the thickness direction (D1) of the mounting substrate (100), the distance between the first electronic component (E1) and the switch (7) as well as the distance between the third electronic component (E3) and the switch (7) are shorter than the distance between the second electronic component (E2) and the switch (7).

The high frequency module (500b) according to the second aspect can suppress the degradation of the characteristics during simultaneous communication.

The high frequency module (500e; 500f; 500g) according to a third aspect includes the mounting substrate (100), the antenna terminal (T1), the switch (7), and the plurality of filters (61 to 68). The mounting substrate (100) has the first principal surface (101) and the second principal surface (102) that face each other. The antenna terminal (T1) is disposed on or in the mounting substrate (100). The switch (7) is disposed on or in the mounting substrate (100). The switch (7) is connected to the antenna terminal (T1). The plurality of filters (61 to 68) is connected to the antenna terminal (T1) with the switch (7) interposed. The plurality of filters (61 to 68) includes the first filter (1) that has the pass band including the frequency band of the first communication band and the second filter (2) that has the pass band including the frequency band of the second communication band that is capable of simultaneous communication with the first communication band. The first filter (1) has the plurality of first acoustic wave resonators (14). The second filter (2) has the plurality of second acoustic wave resonators (24). The plurality of first acoustic wave resonators (14) includes the first antenna end resonator (14A). Among the plurality of first acoustic wave resonators (14), the first antenna end resonator (14A) is the first acoustic wave resonator (14) that is provided on the first signal path (Ru1) connected to the switch (7) and that is closest to the antenna terminal (T1). The plurality of second acoustic wave resonators (24) includes the second antenna end resonator (24A). Among the plurality of second acoustic wave resonators (24), the second antenna end resonator (24A) is the second acoustic wave resonator (24) that is provided on the second signal path (Ru2) connected to the switch (7) and that is closest to the antenna terminal (T1). The first electronic component (E1) having the first antenna end resonator (14A) of the first filter (1) and the second antenna end resonator (24A) of the second filter (2) is disposed on the first principal surface (101) or the second principal surface (102) of the mounting substrate (100). The second electronic component (E2) having at least one second acoustic wave resonator (24) other than the second antenna end resonator (24A) among the plurality of second acoustic wave resonators (24) of the second filter (2) is disposed on the first principal surface (101) of the mounting substrate (100). In plan view from the thickness direction (D1) of the mounting substrate (100), the distance between the first electronic component (E1) and the switch (7) is shorter than the distance between the second electronic component (E2) and the switch (7).

The high frequency module (500e; 500f; 500g) according to the third aspect can suppress the degradation of the characteristics during simultaneous communication.

In the high frequency module (500; 500b; 500c; 500d; 500e; 500g) according to a fourth aspect, in any one of the first to third aspects, the antenna terminal (T1) and the switch (7) are disposed on the second principal surface (102) of the mounting substrate (100). In plan view from the thickness direction (D1) of the mounting substrate (100), the first electronic component (E1) and the switch (7) overlap.

The high frequency module (500; 500b; 500c; 500d; 500e; 500g) according to a fourth aspect can reduce each of the loss due to the wiring section between the first antenna end resonator (14A; 44A) and the switch (7) and the loss due to the wiring section between the second antenna end resonator (24A) and the switch (7).

In the high frequency module (500; 500b; 500c; 500d; 500e; 500f; 500g) according to a fifth aspect, in any one of the first to fourth aspects, the mounting substrate (100) has the first ground conductor part (105) and the second ground conductor part (106). The first ground conductor part (105) at least partially overlaps the first electronic component (E1) in plan view from the thickness direction (D1) of the mounting substrate (100). The second ground conductor part (106) at least partially overlaps the second electronic component (E2) in plan view from the thickness direction (D1) of the mounting substrate (100). In plan view from the thickness direction (D1) of the mounting substrate (100), the ratio of the area of the part overlapping the second ground conductor part (106) to the area of the second electronic component (E2) is higher than the ratio of the area of the part overlapping the first ground conductor part (105) to the area of the first electronic component (E1).

With the high frequency module (500; 500b; 500c; 500d; 500e; 500f; 500g) according to the fifth aspect, the heat generated in the second electronic component (E2) is easily dissipated.

In the high frequency module (500; 500b; 500c; 500d; 500e; 500f; 500g) according to a sixth aspect, in any one of the first to fourth aspects, the mounting substrate (100) has the first ground conductor part (105) and the second ground conductor part (106). The first ground conductor part (105) at least partially overlaps the first electronic component (E1) in plan view from the thickness direction (D1) of the mounting substrate (100). The second ground conductor part (106) at least partially overlaps the second electronic component (E2) in plan view from the thickness direction (D1) of the mounting substrate (100). In plan view from the thickness direction (D1) of the mounting substrate (100), the area of the part of the second ground conductor part (106) that overlaps the second electronic component (E2) is larger than the area of the part of the first ground conductor part (105) that overlaps the first electronic component (E1).

With the high frequency module (500; 500b; 500c; 500d; 500e; 500f; 500g) according to the sixth aspect, the heat generated in the second electronic component (E2) is easily dissipated.

In the high frequency module (500c) according to a seventh aspect, in any one of the first to sixth aspects, the second filter (2) further has a resonator (28). The resonator (28) is disposed on or in the mounting substrate (100). The resonator (28) is connected between the second antenna end resonator (24A) and at least one second acoustic wave resonators (24) among the plurality of second acoustic wave resonators (24) in the second signal path (Ru2).

The high frequency module (500c) according to the seventh aspect can improve the characteristics of the second filter (2).

In the high frequency module (500d) according to an eighth aspect, in any one of the first to sixth aspects, the second filter (2) further has a resonator (29). The resonator (29) is disposed on or in the mounting substrate (100). The resonator (29) is connected to the second acoustic wave resonator (24) among the plurality of plurality of second acoustic wave resonators (24) that is farthest from the antenna terminal (T1), in the second signal path (Ru2).

The high frequency module (500d) according to the eighth aspect can improve the characteristics of the second filter (2).

In the high frequency module (500; 500a; 500b; 500c; 500d; 500e; 500f; 500g) according to a ninth aspect, in any one of the first to eighth aspects, the second antenna end resonator (24A) includes the IDT electrode (27), the piezoelectric layer (204), and the high acoustic velocity member (201). The high acoustic velocity member (201) is located on a side opposite from the IDT electrode (27) of the second antenna end resonator (24A) with the piezoelectric layer (204) in between. In the high acoustic velocity member (201), the acoustic velocity of a propagating bulk wave is higher than the acoustic velocity of an acoustic wave propagating through the piezoelectric layer (204). At least one second acoustic wave resonator (24) includes the IDT electrode (37) and a lithium tantalate substrate or a lithium niobate substrate.

The high frequency module (500; 500a; 500b; 500c; 500d; 500e; 500f; 500g) according to the ninth aspect makes it possible to improve the performance of the first filter (1) and reduce the cost of the second electronic component (E2).

In the high frequency module (500; 500a; 500b; 500c; 500d; 500e; 500f; 500g) according to a tenth aspect, in any one of the first to eighth aspects, the second antenna end resonator (24A) includes the IDT electrode (27) and a lithium tantalate substrate or a lithium niobate substrate. At least one second acoustic wave resonator (24) includes the IDT electrode (37), the piezoelectric layer (304), and the high acoustic velocity member (301). The high acoustic velocity member (301) is located on a side opposite from the IDT electrode (37) of the at least one second acoustic wave resonator (24) with the piezoelectric layer (304) in between. In the high acoustic velocity member (301), the acoustic velocity of a propagating bulk wave is higher than the acoustic velocity of an acoustic wave propagating through the piezoelectric layer (304).

The high frequency module (500; 500a; 500b; 500c; 500d; 500e; 500f; 500g) according to the tenth aspect makes it possible to reduce the cost of the first electronic component (E1) and improve the performance of the second filter (2).

In the high frequency module (500; 500a; 500b; 500c; 500d; 500e; 500f; 500g) according to an eleventh aspect, in any one of the first to eighth aspects, the second antenna end resonator (24A) is a BAW resonator. At least one second acoustic wave resonator (24) is a SAW resonator.

In the high frequency module (500; 500a; 500b; 500c; 500d; 500e; 500f; 500g) according to a twelfth aspect, in any one of the first to eighth aspects, the second antenna end resonator (24A) is a SAW resonator. At least one second acoustic wave resonator (24) is a BAW resonator.

In the high frequency module (500; 500a; 500b; 500c; 500d; 500e; 500f; 500g) according to a thirteenth aspect, in any one of the first to eighth aspects, the second antenna end resonator (24A) includes the IDT electrode (27), the first piezoelectric layer (204), and the first high acoustic velocity member (201). The first high acoustic velocity member (201) is located on a side opposite from the IDT electrode (27) of the second antenna end resonator (24A) with the first piezoelectric layer (204) in between. In the first high acoustic velocity member (201), the acoustic velocity of the propagating bulk wave is higher than the acoustic velocity of the acoustic wave propagating through the first piezoelectric layer (204). At least one second acoustic wave resonator (24) includes the IDT electrode (37), the second piezoelectric layer (304), and the second high acoustic velocity member (301). The second high acoustic velocity member (301) is located on a side opposite from the IDT electrode (37) of the at least one second acoustic wave resonator (24) with the second piezoelectric layer (304) in between. In the second high acoustic velocity member (301), the acoustic velocity of the propagating bulk wave is higher than the acoustic velocity of the acoustic wave propagating through the second piezoelectric layer (304). The thickness of the first piezoelectric layer (204) differs from the thickness of the second piezoelectric layer (304).

The high frequency module (500h) according to a fourteenth aspect, in the first aspect, further includes the first low noise amplifier (81A) and the second low noise amplifier (82A). The first low noise amplifier (81A) is connected to the first filter (61A). The second low noise amplifier (82A) is connected to the second filter (62A). The switch (7A) further has the common terminal (70A) connected to the antenna terminal (T1), and the first selection terminal (71A), the second selection terminal (72A), the third selection terminal (73A), and the fourth selection terminal (74A) that are connectable to the common terminal (70A). The first communication band is a first TDD communication band. The second communication band is a second TDD communication band in a frequency band higher than the first communication band. The plurality of filters (61A to 64A) further includes the third filter (63A) and the fourth filter (64A). The first filter (61A) is connected between the first selection terminal (71A) and the first low noise amplifier (81A). The first filter (61A) is a first receiving filter that has the pass band including the frequency band of the first TDD communication band. The second filter (2A) is connected between the second selection terminal (72A) and the second low noise amplifier (82A). The second filter (62A) is a second receiving filter having the pass band for the second TDD communication band. The third filter (63A) is connected to the third selection terminal (73A). The third filter (63A) is a first transmitting filter that has the pass band including the frequency band of the first TDD communication band. The fourth filter (64A) is connected to the fourth selection terminal (74A). The fourth filter (64) is a second transmitting filter that has the pass band including the frequency band of the second TDD communication band. In the first filter (61A), the plurality of first acoustic wave resonators (14) includes the plurality of first series arm resonators (S11 to S14) and the plurality of first parallel arm resonators (P11 to P14). The first acoustic wave resonator (14B) that is farthest from the antenna terminal (T1) among the plurality of first acoustic wave resonators (14) is one of the plurality of first parallel arm resonators (P11 to P14). In the second filter (62A), the plurality of second acoustic wave resonators (24) includes the plurality of second series arm resonators (S21 to S24) and the plurality of second parallel arm resonators (P21 to P24). The second acoustic wave resonator (24) that is farthest from the antenna terminal (T1) among the plurality of second acoustic wave resonators (24) is one of the plurality of second series arm resonators (S21 to S24).

The high frequency module (500h) according to the fourteenth aspect can improve the attenuation characteristics of the frequency band of the second communication band in the first filter (61A) and the attenuation characteristics of the frequency band of the first communication band in the second filter (62A) while reducing the loss of each of the first filter (61A) and the second filter (62A).

The high frequency module (500h) according to a fifteenth aspect, in the fourteenth aspect, further includes the phase adjusting element (19). The phase adjusting element (19) is connected between the ground and the first acoustic wave resonator (14B) that is farthest from the antenna terminal (T1).

The high frequency module (500h) according to the fifteenth aspect can further improve the attenuation characteristics of the first filter (61A).

The high frequency module (500h) according to a sixteenth aspect, in the fourteenth or fifteenth aspect, further includes the first inductor (L1) and the second inductor (L2). The first inductor (L1) is connected between the first filter (61A) and the first low noise amplifier (81A). The second inductor (L2) is connected between the second filter (62A) and the second low noise amplifier (82A).

The high frequency module (500h) according to the sixteenth aspect can improve the attenuation characteristics of the first filter (61A) in a configuration in which only one first inductor (L1 is adopted for the impedance matching between the first filter (61A) and the first low noise amplifier (81A). The high frequency module (500h) according to the sixteenth aspect can also improve the attenuation characteristics of the second filter (62A) in a configuration in which only one second inductor (L2) is adopted for the impedance matching between the second filter (62A) and the second low noise amplifier (82A).

The high frequency module (500i) according to a seventeenth aspect, in the first aspect, further includes the multiplexer (401). The multiplexer (401) is connected between the antenna terminal (T1) and the switch (7A). The first communication band is a first TDD communication band. The second communication band is a second TDD communication band in a frequency band higher than the first communication band. The multiplexer (401) has the first signal terminal (411), the second signal terminal (412), the third signal terminal (413), the third filter (403), and the fourth filter (404). The first signal terminal (411) is connected to the antenna terminal (T1). The third filter (403) is connected between the first signal terminal (411) and the second signal terminal (412). The third filter (403) has the pass band including the frequency band of the first communication band. The fourth filter (404) is connected between the first signal terminal (411) and the third signal terminal (413). The fourth filter (404) has the pass band including the frequency band of the second communication band. The switch (7A) includes the first switching unit (first switch circuit 7C) and the second switching unit (second switch circuit 7D) that is separate from the first switching unit (first switch circuit 7C). The first switching unit (first switch circuit 7C) is connected between the second signal terminal (412) and the first filter (61B). The second switching unit (second switch circuit 7D) is connected between the third signal terminal (413) and the second filter (62B).

According to the high frequency module (500i) according to the seventeenth aspect, as the first switching unit (first switch circuit 7C), the multiplexer (401), and the second switching unit (second switch circuit 7D) are disposed between the first filter (61B) and the second filter (62B), it is possible to improve the isolation between the first filter (61B) and the second filter (62B).

The high frequency module (500i) according to an eighteenth aspect, in the seventeenth aspect, further includes the fifth filter (405) connectable to the fourth filter (404) with the second switching unit (second switch circuit 7D) interposed and the power amplifier (420) connected to the fifth filter (405). The first filter (61A) is a receiving filter that has the pass band including the frequency band of the first TDD communication band. The second filter (62A) is a receiving filter that has the pass band including the frequency band of the second TDD communication band. The fifth filter (405) is a transmitting filter that has the pass band including the frequency band of the second TDD communication band. The third filter (403) is the first hybrid filter that includes at least one third acoustic wave resonator (34C) and the first inductor (L31), as the plurality of first circuit element. The pass band width of the first hybrid filter is larger than the pass band width of the third acoustic wave resonator (34C). The fourth filter (404) is the second hybrid filter including at least one fourth acoustic wave resonator (44C) and the second inductor (L41), as the plurality of second circuit elements. The pass band width of the second hybrid filter is larger than the pass band width of the fourth acoustic wave resonator 44C.

According to the high frequency module (500i) according to the eighteenth aspect, it is possible to improve the attenuation characteristics of the frequency band between the first communication band and the second communication band in each of the third filter (403) and the fourth filter (404).

The high frequency module (500i) according to a nineteenth aspect is based on the seventeenth aspect. The third filter (403) is the first hybrid filter that includes at least one third acoustic wave resonator (34C) and the first inductor (L31), as the plurality of first circuit element. The pass band width of the first hybrid filter is larger than the pass band width of the third acoustic wave resonator (34C). The fourth filter (404) is the second hybrid filter including at least one fourth acoustic wave resonator (44C) and the second inductor (L41), as the plurality of second circuit elements. The pass band width of the second hybrid filter is larger than the pass band width of the fourth acoustic wave resonator (44C). In the first hybrid filter, the first circuit element that is farthest from the antenna terminal (T1) among the plurality of first circuit elements is one of at least one third acoustic wave resonator (34C). In the second hybrid filter, the second circuit element that is farthest from the antenna terminal (T1) among the plurality of second circuit elements is one of at least one fourth acoustic wave resonator (44C).

According to the high frequency module (500i) according to the nineteenth aspect, it is possible to suppress a distortion signal at the third acoustic wave resonator (34C) that is farthest from the antenna terminal (T1) and to suppress a distortion signal at the fourth acoustic wave resonator (44C) that is farthest from the antenna terminal (T1).

The communication device (600) according to a twentieth aspect includes the high frequency module (500; 500a; 500b; 500c; 500d; 500e; 500f; 500g; 500h; 500i) of any one of the first to nineteenth aspects and the signal processing circuit (601). The signal processing circuit (601) is connected to the high frequency module (500; 500a; 500b; 500c; 500d; 500e; 500f; 500g; 500h; 500i).

The communication device (600; 600h; 600i) according to the twentieth aspect can suppress the degradation of the characteristics of the high frequency module (500; 500a; 500b; 500c; 500d; 500e; 500f; 500g; 500h; 500i) during simultaneous communication.

The high frequency circuit (400h) according to a twenty-first aspect includes the antenna terminal (T1), the switch (7A), the first receiving filter (61A), the second receiving filter (62A), the first transmitting filter (63A), the second transmitting filter (64A), the first low noise amplifier (81A), and the second low noise amplifier (82A). The switch (7A) has the common terminal (70A) connected to the antenna terminal (T1), and the first selection terminal (71A), the second selection terminal (72A), the third selection terminal (73A), and the fourth selection terminal (74A) that are connectable to the common terminal (70A). The first receiving filter (61A) is connected to the first selection terminal (71A) and has the pass band including the frequency band of the first TDD communication band. The second receiving filter (62A) is connected to the second selection terminal (72A) and has the pass band including the frequency band of the second TDD communication band that is capable of simultaneous communication with the first communication band. The first transmitting filter (63A) is connected to the third selection terminal (73A) and has the pass band including the frequency band of the first communication band. The second transmitting filter (64A) is connected to the fourth selection terminal (74A) and has the pass band including the frequency band of the second communication band. The first low noise amplifier (81A) is connected to the first receiving filter (61A). The second low noise amplifier (82A) is connected to the second receiving filter (62A). The frequency band of the second communication band is on the higher frequency side than the frequency band of the first communication band. The first receiving filter (61A) has the plurality of first acoustic wave resonators (14). The second receiving filter (62A) has the plurality of second acoustic wave resonators (24). In the first receiving filter (61A), the plurality of first acoustic wave resonators (14) includes the plurality of first series arm resonators (S11 to S14) and the plurality of first parallel arm resonators (P11 to P14). In the first receiving filter (61A), the first acoustic wave resonator (14B) that is farthest from the antenna terminal (T1) among the plurality of first acoustic wave resonators (14) is one of the plurality of first parallel arm resonators P11 to (P14) (first parallel arm resonator P14). In the second receiving filter (62A), the plurality of second acoustic wave resonators (24) includes the plurality of second series arm resonators (S21 to S24) and the plurality of second parallel arm resonators (P21 to P24). In the second receiving filter (62A), the second acoustic wave resonator (24B) that is farthest from the antenna terminal (T1) among the plurality of second acoustic wave resonators (24) is one of the plurality of second series arm resonators (S21 to S24) (first series arm resonator S24).

According to the high frequency circuit (400h) according to the twenty-first aspect, it is possible to suppress the degradation of the characteristics during simultaneous communication. More particularly, according to the high frequency circuit (400h) according to the twenty-first aspect, it is possible to improve the attenuation characteristics of the frequency band of the second communication band in the first receiving filter (61A) and the attenuation characteristics of the frequency band of the first communication band in the second receiving filter (62A) while reducing loss of each of the first receiving filter (61A) and the second receiving filter (62A).

The high frequency circuit (400i) according to the twenty-second aspect includes the antenna terminal (T1), the multiplexer (401), the first switch circuit (7C), the second switch circuit (7D), the first filter (61B), and the second filter (62B). The multiplexer (401) has the first signal terminal (411), the second signal terminal (412), and the third signal terminal (413). In the multiplexer (401), the first signal terminal (411) is connected to the antenna terminal (T1). The first switch circuit (7C) is connected to the second signal terminal (412). The second switch circuit (7D) is connected to the third signal terminal (413). The first filter (61B) is connected to the second signal terminal (412) with the first switch circuit (7C) interposed. The first filter (61B) has the pass band including the frequency band of the first TDD communication band. The second filter (62b) is connected to the third signal terminal (413) with the second switch circuit (7D) interposed. The second filter (62B) has the pass band including the frequency band of the second TDD communication band that is capable of simultaneous communication with the first communication band. The frequency band of the second communication band is on the higher frequency side than the frequency band of the first communication band. The multiplexer (401) further has the third filter (403) and the fourth filter (404). The third filter (403) is connected between the first signal terminal (411) and the second signal terminal (412). The third filter (403) has the pass band including the frequency band of the first communication band. The fourth filter (404) s connected between the first signal terminal (411) and the third signal terminal (413). The fourth filter (404) has the pass band including the frequency band of the second communication band.

According to the high frequency circuit (400i) according to the twenty-second aspect, it is possible to suppress the degradation of the characteristics during simultaneous communication. More particularly, according to the high frequency circuit (400i) according to the twenty-second aspect, as the first switch circuit (7C), the multiplexer (401), and the second switch circuit (7D) are disposed between the first filter (61B) and the second filter (62B), it is possible to improve the isolation between the first filter (61B) and the second filter (62B). As a result, according to the high frequency circuit (400i) according to the twenty-second aspect, the attenuation characteristics of the frequency band of the second filter (62B) can be improved in the first filter (61B), when simultaneous communication is performed in the first communication band and the second communication band, and the attenuation characteristics of the frequency band of the first filter (61B) can also be improved in the second filter (62B).
1 First filter
2 Second Filter
3 First resin layer
3001 Principal surface
3003 Outer peripheral surface
4 Metal electrode layer
5 Second resin layer
5001 Principal surface
5003 Outer peripheral surface
7 Switch (first switch)
70 Common terminal
71 to 75 Selection terminal
7A Switch
7C First switch circuit (first switching unit)
70C Common terminal
71C to 73C Selection terminal
7D Second switch circuit (second switching unit)
70D Common terminal
71D to 73D Selection terminal
8 IC chip
8e IC chip
81 to 88 Low noise amplifier
9 Second switch
90 Common terminal
91 to 98 Selection terminal
9A Second switch
90A Common terminal
91A,92A Selection terminal
9B Third switch circuit
901 to 904 Common terminal
90B to 99B Selection terminal
10 Substrate
10A First principal surface
10B Second principal surface
11 First functional electrode
12 Piezoelectric film
13 Upper electrode
14 Acoustic wave resonator (first acoustic wave
15 resonator, fourth acoustic wave resonator)
14A Antenna end resonator (first antenna end resonator, fourth antenna end resonator)
14B First acoustic wave resonator farthest from an antenna end
16 Cavity
17 IDT electrode
171 First electrode finger
172 Second electrode finger
19 Phase adjusting element
21 Second functional electrode
22 Piezoelectric film
23 Upper electrode
200 Support substrate
201 High acoustic velocity member (first high acoustic velocity member)
202 Low acoustic velocity film
203 High acoustic velocity film
204 Piezoelectric layer (first piezoelectric layer)
207 Piezoelectric substrate
24 Acoustic wave resonator (second acoustic wave resonator)
24A Antenna end resonator (second antenna end resonator)
24B Second acoustic wave resonator farthest from an antenna terminal
26 Cavity
27 IDT electrode
271 First electrode finger
272 Second electrode finger
28 Resonator
281 Inductor
282 Capacitor
29 Resonator
291 Inductor
292 Capacitor
30 Third substrate
30A First principal surface
30B Second principal surface
31 Third functional electrode
32 Piezoelectric film
33 Upper electrode
34 Acoustic wave resonator (third acoustic wave resonator)
34A Antenna end resonator (third antenna end resonator)
34C Third acoustic wave resonator
36 Cavity
37 IDT electrode
371 First electrode finger
372 Second electrode finger
301 High acoustic velocity member (second high acoustic velocity member)
302 Low acoustic velocity film
303 High acoustic velocity film
304 Piezoelectric layer (second piezoelectric layer)
307 Piezoelectric substrate
44 Acoustic wave resonator (fourth acoustic wave resonator, first acoustic wave resonator)
44A Antenna end resonator (fourth antenna end resonator, first antenna end resonator)
44C Fourth acoustic wave resonator
54 Acoustic wave resonator (fifth acoustic wave resonator)
54A Antenna end resonator (fifth antenna end resonator)
61 to 68 Filter
61A Filter (first filter, first receiving filter)
611 Input terminal
612 Output terminal
62A Filter (second filter, second receiving filter)
621 Input terminal
622 Output terminal
63A Filter (third filter, first transmitting filter)
64A Filter (fourth filter, second transmitting filter)
100 Mounting substrate
101 First principal surface
102 Second principal surface
103 Outer peripheral surface
105 First ground conductor part
106 Second ground conductor part
110 First external terminal
111 Common terminal
112 Input/output terminal
113 Connection terminal
114 Input/output terminal
116 Ground terminal
120 Second external terminal
123 Connection terminal
124 Input/output terminal
126 Ground terminal
130 Third external terminal
131 Input/output terminal
132 Input/output terminal
133 Input/output terminal
134 Input/output terminal
136 Ground terminal
140 Fourth external terminal
141 Input/output terminal
142 Input/output terminal
146 Ground terminal
150 Fifth external terminal
151 Input/output terminal
152 Input/output terminal
156 Ground terminal
164 Acoustic wave resonator (sixth acoustic wave resonator)
164A Antenna end resonator (sixth antenna end resonator)
174 Acoustic wave resonator (seventh acoustic wave resonator)
174A Antenna end resonator (seventh antenna end resonator)
184 Acoustic wave resonator (eighth acoustic wave resonator)
184A Antenna end resonator (eighth antenna end resonator)
400h, 400i High frequency circuit
401 Multiplexer
411 First signal terminal
412 Second signal terminal
413 Third signal terminal
414 Fourth signal terminal
403 Third filter
404 Fourth filter
405 Filter (fifth filter)
406 Third switch
460 Common terminal
461 Selection terminal
462 Selection terminal
407 Sixth filter
420 Power amplifier
421 Power amplifier (first power amplifier)
422 Power amplifier (second power amplifier)
431 Output matching circuit (first output matching circuit)
432 Output matching circuit (second output matching circuit)
500, 500a, 500b, 500c, 500d, 500e, 500f, 500g, 500h,
500i High frequency module
600, 600h, 600i Communication device
601 Signal processing circuit
602 RF signal processing circuit
603 Baseband signal processing circuit
610 Antenna
A1 Connecting point
A2 Connecting point
A3 Connecting point
A4 Connecting point
D1 Thickness direction
E1 First electronic component
E2 Second electronic component
E3 Third electronic component
E4 Fourth electronic component
E5 Fifth electronic component
E11, E12, E13 Electronic component
E21, E22, E23, E24 Electronic component
L0 Inductor
L1 Inductor (first inductor)
L2 Inductor (second inductor)
L3 to L9 Inductor
L11 to L15 Inductor
L21 Third inductor
L22 Fourth inductor
L31 First inductor
L41 Second inductor
Ru1 Signal path (first signal path, fourth signal path)
Ru2 Signal path (second signal path)
Ru3 Signal path (third signal path)
Ru4 Signal path (fourth signal path, first signal path)
Ru5 Signal path (fifth signal path)
Ru6 Signal path (sixth signal path)
Ru7 Signal path (seventh signal path)
Ru8 Signal path (eighth signal path)
Ru31 First path
Ru41 Second path
S11 to S15 Series arm resonator
S21 to S25 Series arm resonator
S31 to S35 Series arm resonator
S41 to S45 Series arm resonator
S51 to S55 Series arm resonator
P11 to P14 Parallel arm resonator (first parallel arm resonator)
P21 to P24 Parallel arm resonator (second parallel arm resonator)
P31 to P34 Parallel arm resonator
P41 to P44 Parallel arm resonator
P51 to P54 Parallel arm resonator
T0 External connection terminal
T1 Antenna terminal
T2 Signal output terminal
T3 External ground terminal
T4 Signal input terminal
W2 Wiring section
W3 Wiring section

1. A high frequency module comprising:
a mounting substrate having a first principal surface and a second principal surface that face each other;
an antenna terminal on or in the mounting substrate;
a switch on or in the mounting substrate and connected to the antenna terminal;
a plurality of filters connected to the antenna terminal with the switch interposed between the plurality of filters and the antenna terminal;
a first electronic component on the first principal surface of the mounting substrate; and
a second electronic component on the first principal surface of the mounting substrate,
wherein the plurality of filters comprises:
a first filter that has a pass band comprising a frequency band of a first communication band; and
a second filter that has a pass band comprising a frequency band of a second communication band that is capable of simultaneous communication with the first communication band,
wherein the first filter comprises a plurality of first acoustic wave resonators,
wherein the second filter comprises a plurality of second acoustic wave resonators,
wherein the plurality of first acoustic wave resonators comprises a first antenna end resonator in a first signal path connected to the switch, the first antenna end resonator being the first acoustic wave resonator closest to the antenna terminal,
wherein the plurality of second acoustic wave resonators comprises a second antenna end resonator in a second signal path connected to the switch, the second antenna end resonator being the second acoustic wave resonator closest to the antenna terminal,
wherein the first electronic component comprises the first filter and the second antenna end resonator of the second filter,
wherein the second electronic component comprises at least one second acoustic wave resonator other than the second antenna end resonator of the second filter, and
wherein in a plan view from a thickness direction of the mounting substrate, a distance between the first electronic component and the switch is shorter than a distance between the second electronic component and the switch.

2. A high frequency module comprising:
a mounting substrate having a first principal surface and a second principal surface that face each other;
an antenna terminal on or in the mounting substrate;
a switch on or in the mounting substrate and connected to the antenna terminal;
a plurality of filters connected to the antenna terminal with the switch interposed between the plurality of filters and the antenna terminal;
a first electronic component on the first principal surface of the mounting substrate;
a second electronic component on the first principal surface of the mounting substrate; and
a third electronic component on the first principal surface of the mounting substrate,
wherein the plurality of filters comprises:
a first filter that has a pass band comprising a frequency band of a first communication band; and
a second filter that has a pass band comprising a frequency band of a second communication band that is capable of simultaneous communication with the first communication band,
wherein the first filter comprises a plurality of first acoustic wave resonators,
wherein the second filter comprises a plurality of second acoustic wave resonators,
wherein the plurality of first acoustic wave resonators comprises a first antenna end resonator in a first signal path connected to the switch, the first antenna end resonator being the first acoustic wave resonator closest to the antenna terminal,
wherein the plurality of second acoustic wave resonators comprises a second antenna end resonator in a second signal path connected to the switch, the second antenna end resonator being the second acoustic wave resonator closest to the antenna terminal,
wherein the first electronic component comprises the second antenna end resonator of the second filter,
wherein the second electronic component comprising at least one second acoustic wave resonator other than the second antenna end resonator,
wherein the third electronic component comprises the first filter,
wherein in a plan view from a thickness direction of the mounting substrate, the first electronic component and the third electronic component are adjacent to each other, and
wherein in the plan view, a distance between the first electronic component and the switch, and a distance between the third electronic component and the switch, are shorter than a distance between the second electronic component and the switch.

3. A high frequency module comprising:
a mounting substrate having a first principal surface and a second principal surface that face each other;
an antenna terminal on or in the mounting substrate;
a switch on or in the mounting substrate and connected to the antenna terminal;
a plurality of filters connected to the antenna terminal with the switch interposed between the plurality of filters and the antenna terminal;
a first electronic component on the first principal surface or the second principal surface of the mounting substrate; and
a second electronic component on the first principal surface of the mounting substrate,
wherein the plurality of filters comprises:
a first filter that has a pass band comprising a frequency band of a first communication band; and
a second filter that has a pass band comprising a frequency band of a second communication band that is capable of simultaneous communication with the first communication band,
wherein the first filter comprises a plurality of first acoustic wave resonators,
wherein the second filter comprises a plurality of second acoustic wave resonators,
wherein the plurality of first acoustic wave resonators comprises a first antenna end resonator in a first signal path connected to the switch, the first antenna end resonator being the first acoustic wave resonator closest to the antenna terminal,
wherein the plurality of second acoustic wave resonators comprises a second antenna end resonator in a second signal path connected to the switch, the second antenna end resonator being the second acoustic wave resonator closest to the antenna terminal,
wherein the first electronic component comprises the first antenna end resonator of the first filter and the second antenna end resonator of the second filter,
wherein the second electronic component comprises at least one second acoustic wave resonator other than the second antenna end resonator, and
wherein in a plan view from a thickness direction of the mounting substrate, a distance between the first electronic component and the switch is shorter than a distance between the second electronic component and the switch.

4. The high frequency module according to claim 1,
wherein the antenna terminal and the switch are on the second principal surface of the mounting substrate, and
wherein the first electronic component and the switch overlap in the plan view.

5. The high frequency module according to claim 1,
wherein the mounting substrate comprises:
a first ground conductor part at least partially overlapping the first electronic component in the plan view; and
a second ground conductor part at least partially overlapping the second electronic component in the plan view, and
wherein in the plan view, a ratio of an area of an overlapping portion of the second ground conductor part to an area of the second electronic component is greater than a ratio of an area of an overlapping portion of the first ground conductor part to an area of the first electronic component.

6. The high frequency module according to claim 1,
wherein the mounting substrate comprises:
a first ground conductor part at least partially overlapping the first electronic component in the plan view; and
a second ground conductor part at least partially overlapping the second electronic component in the plan view, and
wherein in the plan view, an area of the second ground conductor part that overlaps the second electronic component is larger than an area of the first ground conductor part that overlaps the first electronic component.

7. The high frequency module according to claim 1, wherein the second filter further comprises a resonator on or in the mounting substrate and connected between the second antenna end resonator and at least one second acoustic wave resonator in the second signal path.

8. The high frequency module according to claim 1, wherein the second filter further comprises a resonator on or in the mounting substrate and connected to a second acoustic wave resonator that is farthest from the antenna terminal in the second signal path.

9. The high frequency module according to claim 1,
wherein the second antenna end resonator comprises:
a first interdigital transducer (IDT) electrode;
a piezoelectric layer; and
a high acoustic velocity member that is located on a side opposite from the first IDT electrode of the second antenna end resonator with the piezoelectric layer in between, and in which an acoustic velocity of a propagating bulk wave is higher than an acoustic velocity of an acoustic wave propagating through the piezoelectric layer, and
wherein the at least one second acoustic wave resonator comprises:
a second IDT electrode; and
a lithium tantalate substrate or a lithium niobate substrate.

10. The high frequency module according to claim 1,
wherein the second antenna end resonator comprises:
a first interdigital transducer (IDT) electrode; and
a lithium tantalate substrate or a lithium niobate substrate, and
wherein the at least one second acoustic wave resonator comprises:
a second IDT electrode;
a piezoelectric layer; and
a high acoustic velocity member that is located on a side opposite from the second IDT electrode of the at least one second acoustic wave resonator with the piezoelectric layer in between, and in which an acoustic velocity of a propagating bulk wave is greater than an acoustic velocity of an acoustic wave propagating through the piezoelectric layer.

11. The high frequency module according to claim 1,
wherein the second antenna end resonator is a bulk acoustic wave (BAW) resonator, and
wherein the at least one second acoustic wave resonator is a surface acoustic wave (SAW) resonator.

12. The high frequency module according to claim 1,
wherein the second antenna end resonator is a surface acoustic wave (SAW) resonator, and
wherein the at least one second acoustic wave resonator is a bulk acoustic wave (BAW) resonator.

13. The high frequency module according to claim 1,
wherein the second antenna end resonator comprises:
a first interdigital transducer (IDT) electrode;
a first piezoelectric layer; and
a first high acoustic velocity member that is located on a side opposite from the first IDT electrode of the second antenna end resonator with the first piezoelectric layer in between, and in which an acoustic velocity of a propagating bulk wave is greater than an acoustic velocity of an acoustic wave propagating through the first piezoelectric layer,
wherein the at least one second acoustic wave resonator comprises:
a second IDT electrode;
a second piezoelectric layer; and
a second high acoustic velocity member that is located on a side opposite from the second IDT electrode of the at least one second acoustic wave resonator with the second piezoelectric layer in between, and in which an acoustic velocity of a propagating bulk wave is greater than an acoustic velocity of an acoustic wave propagating through the second piezoelectric layer, and
wherein a thickness of the first piezoelectric layer is different than a thickness of the second piezoelectric layer.

14. The high frequency module according to claim 1, further comprising:
a first low noise amplifier connected to the first filter; and
a second low noise amplifier connected to the second filter,
wherein the switch further comprises:
a common terminal connected to the antenna terminal; and
a first selection terminal, a second selection terminal, a third selection terminal, and a fourth selection terminal that are configured to selectively connect to the common terminal,
wherein the first communication band is a first time division duplex (TDD) communication band,
wherein the second communication band is a second TDD communication band in a higher frequency band than the first communication band,
wherein the plurality of filters further comprises a third filter and a fourth filter,
wherein the first filter is connected between the first selection terminal and the first low noise amplifier, and is a first receiving filter that has a pass band comprising a frequency band of the first TDD communication band,
wherein the second filter is connected between the second selection terminal and the second low noise amplifier, and is a second receiving filter that has a pass band of the second TDD communication band,
wherein the third filter is connected to the third selection terminal, and is a first transmitting filter that has a pass band comprising a frequency band of the first TDD communication band,
wherein the fourth filter is connected to the fourth selection terminal, and is a second transmitting filter that has a pass band comprising a frequency band of the second TDD communication band,
wherein in the first filter:
the plurality of first acoustic wave resonators comprises a plurality of first series arm resonators and a plurality of first parallel arm resonators, and
a first acoustic wave resonator that is farthest from the antenna terminal is one of the plurality of first parallel arm resonators, and
wherein in the second filter:
the plurality of second acoustic wave resonators comprises a plurality of second series arm resonators and a plurality of second parallel arm resonators, and
a second acoustic wave resonator that is farthest from the antenna terminal is one of the plurality of second series arm resonators.

15. The high frequency module according to claim 14, further comprising:
a phase adjusting circuit element connected between ground and the first acoustic wave resonator that is farthest from the antenna terminal.

16. The high frequency module according to claim 14, further comprising:
a first inductor connected between the first filter and the first low noise amplifier; and
a second inductor connected between the second filter and the second low noise amplifier.

17. The high frequency module according to claim 1, further comprising:
a multiplexer connected between the antenna terminal and the switch,
wherein the first communication band is a first time division duplex (TDD) communication band,
wherein the second communication band is a second TDD communication band in a higher frequency band than the first communication band,
wherein the multiplexer comprises:
a first signal terminal connected to the antenna terminal;
a second signal terminal;
a third signal terminal;
a third filter that is connected between the first signal terminal and the second signal terminal, and that has a pass band comprising a frequency band of the first communication band; and
a fourth filter that is connected between the first signal terminal and the third signal terminal, and that has a pass band comprising a frequency band of the second communication band, and
wherein the switch comprises:
a first switching circuit connected between the second signal terminal and the first filter; and
a second switching circuit connected between the third signal terminal and the second filter, and that is separate from the first switching circuit.

18. The high frequency module according to claim 17, further comprising:
a fifth filter, the second switching circuit being configured to selectively connect the fifth filter to the fourth filter; and
a power amplifier connected to the fifth filter,
wherein the first filter is a receiving filter that has a pass band comprising a frequency band of the first TDD communication band,
wherein the second filter is a receiving filter that has a pass band comprising a frequency band of the second TDD communication band,
wherein the fifth filter is a transmitting filter that has a pass band comprising a frequency band of the second TDD communication band,
wherein the third filter is a first hybrid filter comprising at least one third acoustic wave resonator and a first inductor,
wherein a pass band width of the first hybrid filter is larger than a pass band width of the third acoustic wave resonator,
wherein the fourth filter is a second hybrid filter comprising at least one fourth acoustic wave resonator and a second inductor, and
wherein a pass band width of the second hybrid filter is larger than a pass band width of the fourth acoustic wave resonator.

19. The high frequency module according to claim 17,
wherein the third filter is a first hybrid filter comprising at least one third acoustic wave resonator and a first inductor,
wherein a pass band width of the first hybrid filter is larger than a pass band width of the third acoustic wave resonator,
wherein the fourth filter is a second hybrid filter comprising at least one fourth acoustic wave resonator and a second inductor,
wherein a pass band width of the second hybrid filter is larger than a pass band width of the fourth acoustic wave resonator,
wherein in the first hybrid filter, a first circuit element that is farthest from the antenna terminal is one of the at least one third acoustic wave resonators, and
wherein in the second hybrid filter, a second circuit element that is farthest from the antenna terminal is one of the at least one fourth acoustic wave resonators.

20. A communication device comprising:
a high frequency module according to claim 1; and
a signal processing circuit connected to the high frequency module.
